(19) United States
(12) Patent Application Publication
(10) Pub. No.: US 2026/0366193 A1
(43) Pub. Date: Nov. 19, 2026

(54) DEFECT-ENGINEERED MULTILAYER GRAPHENE INTERFACIAL LAYERS FOR MATERIAL GROWTH AND SUBSTRATE BONDING

(71) Applicant: DESTINATION 2D INC., San Jose, CA (US)

(72) Inventors: Kaustav BANERJEE, Goleta, CA (US); Dmitry VOYLOV, LATHROP, CA (US); Brian CRONQUIST, New Salisbury, IN (US); Ravi IYENGAR, Milpitas, CA (US)

(21) Appl. No.: 19/678,132

(22) Filed: May 14, 2026

Related U.S. Application Data
(60) Provisional application No. 63/807,491, filed on May 16, 2025.
(60) Provisional application No. 63/814,364, filed on May 29, 2025.

(51) Int. Cl. C30B 29/02; C30B 1/10; H10D 88/00; H10P 10/00

(52) U.S. Cl. CPC C30B 29/02; C30B 1/10; H10D 88/00; H10P 10/126

(57) ABSTRACT

A method for material growth and substrate bonding utilizes a defect-engineered graphene film as a reactive interfacial layer. The method includes forming a first graphene film on a first substrate and engineering defects within the film, including vacancies, Stone-Wales defects, controlled grain boundaries, nanopores, micropores, edge defects, or substitutional heteroatoms. In one application, a material is grown on the defect-engineered graphene film, nucleating at the engineered defects to form a continuous film. Alternatively, or additionally, the first substrate is bonded to a second substrate or chip via the first graphene film, or via a second defect-engineered graphene film. The bonding interface comprises symmetric or asymmetric configurations established face-to-face between non-horizontally oriented graphene films, grown materials, or bare surfaces. The engineered defects provide reactive chemical bonding sites across the interface, while the non-horizontal orientation channels heat out-of-plane and internal interlayer sliding minimizes stack warpage.

### CROSS REFERENCE TO RELATED APPLICATIONS

This application claims priority to U.S. Provisional Application No. 63/807,491, filed 16 May 2025, titled “SYNTHESIS AND APPLICATION OF SINGLE (SLG), FEW (FLG), OR MULTILAYER GRAPHENE (MLG) FILMS ON BATTERY SEPARATOR MATERIALS,” and to U.S. Provisional Application No. 63/814,364, filed 29 May 2025, titled “METHODS OF LOW-TEMPERATURE/BEOL-COMPATIBLE GRAPHENE SYNTHESIS TO CONTROL GRAPHENE IONIC POROSITY AND OVERALL DEFECT DENSITY,” the disclosures of which are incorporated by reference herein.

This application is related to U.S. application Ser. No. 19/669,896, filed on 06 May 2026, titled “MULTI-LAYER GRAPHENE SYNTHESIS WITH CARBON ASHING,” the disclosure of which is incorporated by reference herein.

### TECHNICAL FIELD

The present disclosure relates generally to semiconductor fabrication and advanced electronic packaging. More particularly, the disclosure relates to methods of forming and processing defect-engineered multilayer graphene (MLG) films configured as high-affinity, reactive, and thermally anisotropic interfacial layers. These specialized interlayers are utilized alternatively or cumulatively to enable or enhance the low-temperature deposition, nucleation, and epitaxy of semiconductor and dielectric materials, and to facilitate high-strength, low-temperature substrate-to-substrate heterogeneous bonding across mismatched material systems. The disclosure further relates to the utilization of non-horizontally oriented MLG structures to provide directed, anisotropic thermal dissipation pathways and atomic-scale mechanical strain-relief to eliminate compute hot spots and minimize structural warpage in high-power, heterogeneous packaging architectures.

### BACKGROUND ART

Modern semiconductor manufacturing is increasingly moving toward heterogeneous integration, three-dimensional (3D) integrated circuits (ICs), and advanced chiplet architectures to bypass the physical limits of traditional Moore's Law scaling. Integrating disparate materials-such as high-performance compound semiconductors, high-k dielectrics, advanced optical substrates, and flexible materials—onto a single platform requires innovative interfacial solutions. These architectures are particularly prevalent in the development of high-density hardware platforms optimized for Artificial Intelligence (AI) accelerators, high-performance computing (HPC), and dense memory stacks (e.g., High Bandwidth Memory).

Typically, these architectures require two primary engineering operations: (1) the direct growth or deposition of thin crystalline or dielectric films onto a base substrate, and (2) the permanent bonding of pre-fabricated chips, dies, or wafers together. Both operations face severe physical, chemical, thermomechanical, and thermal bottlenecks when dealing with dissimilar material systems.

For film deposition, growing high-quality semiconductor films (e.g., group-IV semiconductors, III-V materials, and III-nitrides like GaN and AIN or uniform dielectric layers (e.g., SiO2, HfO2) requires compatible nucleation surfaces. Many desirable target substrates—including silicon, glass, sapphire, alternative compound semiconductors, organic packaging materials, and various polymers—lack the necessary atomic registry or surface chemistry to promote uniform, pinhole-free film nucleation.

Similarly, for substrate-to-substrate bonding, traditional direct fusion bonding typically requires atomically smooth surfaces and high-temperature thermal annealing steps (often exceeding 600 °C to 1000 °C) to convert weak surface contact into robust covalent bonds. Such high thermal budgets are entirely incompatible with Back-End-of-Line (BEOL) processing constraints, as excessive heat will degrade, melt, or destroy pre-fabricated copper interconnects and active Complementary Metal-Oxide-Semiconductor (CMOS) circuitry featuring active circuitry.

Furthermore, joining materials with vastly different Coefficients of Thermal Expansion (CTE) introduces devastating interfacial shear stresses during thermal cycling. This thermomechanical stress accumulated during cooling induces severe macroscopic wafer or die warpage, which compromises subsequent lithographic depth-of-focus, interferes with precision automated handling tools, and causes micro-cracking, void formation, or catastrophic interfacial delamination. Existing approaches to mitigate warpage rely on thick, thermally insulating polymer adhesive layers or costly, complex back-side compensation layers that undesirably increase package thickness and thermal resistance.

Compounding these mechanical challenges is the critical issue of severe localized thermal dissipation in AI-era devices. High-performance AI logic dies and accelerator chiplets experience extreme localized power densities (thermal hot spots). Traditional thermal interface materials (TIMs) and standard bonding layers cannot adequately dissipate this heat due to bulk thermal resistance limits and high interfacial thermal resistance or thermal boundary resistance (TBR) (a. ka. Kapitza resistance). The profound physics, integration status, and immense potential benefits of low-dimensional carbon nanomaterials to alleviate these parasitic effects and advanced IC thermal bottlenecks (including 3D ICs) have been extensively established in the art (see, e.g., H. Li, C. Xu, N. Srivastava, and K. Banerjee, “Carbon Nanomaterials for Next-Generation Interconnects and Passives: Physics, Status and Prospects,” IEEE Transactions on Electron Devices, Vol. 56, No. 9, pp. 1799-1821, Sep 2009). However, as noted in the article, successfully implementing horizontal or custom-oriented carbon networks remains a severe fabrication challenge that has historically limited wide-scale practical integration.

While pristine two-dimensional (2D) materials like graphene possess excellent intrinsic thermal conductivity, they are chemically inert and inherently possess an atomically smooth, hydrophobic basal plane lacking dangling bonds. Consequently, pristine graphene exhibits exceptionally poor adhesion to deposited films and acts as an anti-adhesion “lubricant” that severely degrades wafer bonding strength. Furthermore, when pristine graphene is deposited as a standard flat, horizontal film parallel to the substrate surface, its thermal conductivity is highly anisotropic; the exceptionally high thermal conductivity is confined strictly in-plane (parallel to the substrate), while its cross-plane (out-of-plane) thermal conductivity remains extremely low, making it ineffective at channeling heat vertically away from an underlying or overlying die.

There exists a critical need in the art for an atomic-scale interfacial layer and associated low-temperature processing methods that can simultaneously activate an inert 2D structure to provide dense, chemically reactive nucleation sites for uniform material growth, while concurrently acting as a high-strength, low-temperature, stress-compliant adhesive bridge for heterogeneous substrate integration. There is a further critical need for such an interfacial layer to feature controllable, non-horizontal atomic orientations capable of redirecting graphene's massive in-plane thermal conductivity along an angled or out-of-plane trajectory to cool active AI chiplets, while simultaneously acting as an atomic-scale strain-relief buffer that absorbs CTE mismatches via internal interlayer sliding to dramatically reduce final stack warpage.

### SUMMARY OF THE INVENTION

The following is a summary of certain exemplary implementations of the disclosure, provided by way of example without limitation. Many other implementations will be apparent to those skilled in the art upon a full understanding of the scope and content of the present disclosure.

In some implementations, a method is provided, comprising: forming a graphene film on a substrate; engineering defects in the graphene film, the engineered defects comprising at least one of vacancies, Stone-Wales defects, grain boundaries having an engineered grain size, nanopores, micropores, edge defects, and substitutional heteroatoms; and growing a second material on the graphene film, wherein the second material nucleates on the graphene film at locations defined by the engineered defects and forms a substantially continuous film on the graphene film.

In some implementations, engineering defects in the graphene film comprises tuning the formation of the graphene film, and wherein tuning the formation of the graphene film comprises at least one of: selecting a catalyst metal composition; selecting a catalyst grain size; selecting a catalyst deposition method; pre-patterning a catalyst layer; selecting a type, thickness, or heteroatom content of a carbon source film; pre-patterning the carbon source film; selecting a temperature, time, ramp profile, cool profile, or ambient of a heating step; and selecting an applied mechanical pressure of a heating step.

In some implementations, engineering defects in the graphene film comprises a post-growth treatment of the graphene film, the post-growth treatment comprising at least one of: a plasma treatment; an oxidation; a chemical etching; an electrochemical etching; a covalent functionalization with a reactive species; an ion or electron beam irradiation; a thermal annealing in a reactive atmosphere; a laser ablation; a lithography followed by an etching; a template-assisted etching; an intercalation followed by a removal of an intercalant; and a strain engineering.

In some implementations, each step of forming the graphene film, engineering the defects, and growing the second material is performed at a process temperature of less than or equal to about 450 degrees Celsius such that the method is compatible with a back-end-of-line thermal budget of a previously processed CMOS wafer.

In some implementations, forming the graphene film comprises: depositing a catalyst metal layer comprising nickel on the substrate; depositing a carbon source film; heating the substrate, the catalyst metal layer, and the carbon source film to a temperature of less than or equal to about 450 degrees Celsius such that carbon diffuses through the catalyst metal layer, the catalyst metal layer dewets during the heating, and carbon segregates as graphene at an interface between the catalyst metal layer and the substrate; and removing the catalyst metal layer to leave the graphene film on the substrate, wherein the heating is performed without applying a mechanical pressure to the substrate, the catalyst metal layer, and the carbon source film.

In some implementations, the dewetting of the catalyst metal layer during the heating tunes at least one of a population, a size, and a spatial distribution of pores or islands in the graphene film, and wherein the engineering of defects in the graphene film comprises selecting a grain size of the catalyst metal layer, prior to the heating, to lie within a range selected from: about 50 to 100 nanometers; about 100 to 150 nanometers; about 150 to 200 nanometers; about 200 to 250 nanometers; about 250 to 300 nanometers; about 300 to 350 nanometers; about 350 to 400 nanometers; about 400 to 450 nanometers; about 450 to 500 nanometers; about 500 to 600 nanometers; about 600 to 800 nanometers; about 800 to 1000 nanometers; about 1000 to 1500 nanometers; about 1500 to 2000 nanometers; about 2000 to 3000 nanometers; greater than about 3000 nanometers; about 50 to 150 nanometers; about 150 to 300 nanometers; about 300 to 450 nanometers; and about 450 to 600 nanometers.

In some implementations, the second material comprises at least one of a III-nitride semiconductor, a group-IV semiconductor, a III-V semiconductor, an oxide dielectric, a nitride dielectric, a metal, and a two-dimensional material; and wherein growing the second material comprises at least one of metal-organic chemical vapor deposition, chemical vapor deposition, plasma-enhanced chemical vapor deposition, molecular beam epitaxy, atomic layer deposition, sputtering, and evaporation.

In some implementations, the engineered defects comprise an array of nanopores having a pore diameter in a range of about 5 to 50 nanometers, a pore pitch in a range of about 50 to 500 nanometers, and a fill factor in a range of about 1 to 10 percent, and wherein the second material is grown on the graphene film at least in part by remote or pinhole epitaxy through the array of nanopores.

In some implementations, the substrate comprises a single-crystal underlayer at locations beneath the array of nanopores in the graphene film, and wherein the second material registers to the single-crystal underlayer through the array of nanopores while substantially residing on the graphene film, and wherein an inter-pore region of the graphene film between the nanopores is substantially pristine and provides at least one of a heat-spreading function, a buried-conductor function, and a mechanical-support function in a final device stack that comprises the substrate, the graphene film, and the second material.

In some implementations, a device is provided, comprising: a substrate; a graphene film on the substrate, the graphene film comprising engineered defects selected from at least one of vacancies, Stone-Wales defects, grain boundaries having a chosen grain size, nanopores having a chosen diameter and pitch, micropores, edge defects, and substitutional heteroatoms; and a second material on the graphene film, the second material being one of a III-nitride semiconductor, a group-IV semiconductor, a III-V semiconductor, an oxide dielectric, a nitride dielectric, a metal, and a two-dimensional material, the second material forming a substantially continuous film whose nucleation is defined by the engineered defects.

The disclosure also provides a bonded device stack, comprising a first substrate, a second substrate or die, and at least a first defect-engineered graphene film disposed at the interface between them, the engineered defects serving as reactive sites to form chemical bonds across the bonding interface. In implementations, a second defect-engineered graphene film is formed on the surface of the second substrate or die prior to bonding, and the two films are arranged in a face-to-face alignment. The bonding is performed at a process temperature of about 150 to 450 degrees Celsius. The bonding interface may be a symmetric configuration comprising a direct bond between the first graphene film and the second graphene film, or an asymmetric configuration comprising a direct bond between the first graphene film and a material grown on the second graphene film. The chemical bonds formed across the bonding interface may comprise covalent Si—C bonds, Si—O—C bonds, C—O—C ether bridges, or metal-carbide bonds. The graphene film may further comprise functional groups including hydroxyl (—OH), carboxyl (—COOH), and amine (—NH2) groups that form interfacial hydrogen bonds or covalent oxide bridges across the bonding interface.

In some implementations, the graphene film comprises a non-horizontally oriented multilayer graphene (MLG) morphology having graphene basal planes oriented at an angle relative to the horizontal plane of the first substrate surface. The non-horizontal orientation selectively channels the graphene's in-plane thermal conductivity out-of-plane, forming an anisotropic thermal dissipation path that preferentially conducts heat away from an overlying die or chiplet. This configuration mitigates localized hot spots in heterogeneous, three-dimensionally stacked architectures such as artificial intelligence (AI) accelerator chiplet packages.

In some implementations, the defect-engineered graphene film functions as an atomic-scale strain-relief buffer layer that accommodates lateral thermomechanical shear stresses arising from coefficient of thermal expansion (CTE) mismatches between the first substrate and the second substrate or die. Internal interlayer sliding within the graphene film absorbs interfacial shear during post-bonding thermal cycling, minimizing structural warpage of the bonded device stack. The grain size, grain boundary density, and porosity of the graphene film are selected to tune the CTE of the film toward that of adjacent materials, further reducing CTE-mismatch-driven warpage.

The disclosure also provides methods for forming ultra-thin graphene-based films (SLG, FLG, MLG or functionalized graphene) directly on or transferred to battery separator materials to act as an interfacial layer between the separator and at least one electrode. The graphene film improves interfacial contact, reduces interfacial resistance, mitigates dendrite formation, improves moisture resistance, enables thinner separators, and simplifies lamination and assembly at reduced temperature and pressure.

In various implementations, the separator includes garnet-type or NASICON-type oxide ceramics (e.g., LLZO, LATP, LAGP), halide solid electrolytes, sulfide glass or crystalline electrolytes, polymer electrolytes, or composite electrolytes. Graphene films are deposited or transferred by low-temperature BEOL-compatible synthesis, solution-based dispersion, RF-plasma polymerization, Langmuir-Blodgett or spin-coating, roll-to-roll transfer, CVD or PECVD, followed by thermal and/or chemical treatments that tune resistivity, adhesion, wettability, and roughness within a defined thickness window of about 0.3 nm to 1 μm.

Exemplary performance benefits include reduction of interfacial impedance by up to about 80%, reduced ASR growth and capacity fade linked to cathode/separator delamination, lower required stack pressure during assembly, and suppression of dendrite-induced short-circuiting in symmetric Li/LLZO cells over extended cycling.

The disclosure further provides a method of forming a separator assembly comprising a graphene-based film having a defined defect profile that enables nucleation and continuous deposition of at least one battery material layer directly on the graphene-based film. The method comprises providing a separator substrate; forming a graphene-based film on at least one major surface of the separator substrate; and subjecting the graphene-based film to at least one defect-engineering step, selected from plasma treatment, ion or electron beam irradiation, electrochemical etching, template-assisted etching, laser treatment, chemical oxidation, covalent functionalization, and in-situ generation of defects during solid-phase diffusion synthesis, to introduce vacancy sites, nanopores, substitutional dopants, grain boundary density, edge defects, or combinations thereof, at a density and spatial distribution sufficient to enable covalent, polar, or line nucleation of a subsequently deposited cathode material, solid electrolyte thin film, or lithium-ion-conductive adhesive layer on the graphene-based film, while retaining at least a portion of the in-plane barrier and mechanical function of the graphene-based film.

The disclosure further provides a separator assembly for a rechargeable battery comprising a solid separator substrate and a graphene-based film on at least one major surface of the separator substrate, the graphene-based film having a distribution of nanopores with a mean pore diameter of 0.3 nm to 20 nm and a pore area fill factor of 0.5% to 20%, wherein the pore density and pore spacing are selected so that lithium ions are transported through the graphene-based film at an ionic transport resistance lower than that of the separator substrate alone and so that the graphene-based film suppresses passage of lithium metal dendrites through the film. In implementations of the disclosure, the mean nanopore diameter is 0.3 nm to 5 nm, and the graphene-based film further restricts passage of water vapor and molecular oxygen at partial pressures encountered during battery cell assembly and storage while permitting lithium-ion transport.

The disclosure further provides a method of forming a battery separator assembly comprising: providing a graphene-based film on a separator substrate; functionalizing a surface of the graphene-based film with a sacrificial layer comprising polar functional groups selected from hydroxyl, carboxyl, amine, epoxide, aryl diazonium-derived aryl, and pyrene-based groups; depositing a cathode material layer or solid electrolyte layer on the functionalized graphene-based film surface, the polar functional groups serving as nucleation sites for continuous film formation; and thermally treating the assembly at a temperature sufficient to drive off at least a portion of the sacrificial functional groups while retaining a continuous and adherent cathode material layer or solid electrolyte layer on the graphene-based film, such that the graphene-based film recovers a substantial portion of its native in-plane barrier and ionic transport properties following removal of the sacrificial functional groups.

The disclosure further provides a method of forming a separator assembly in which a grain size of the graphene-based film is selected so that an in-plane coefficient of thermal expansion of the graphene-based film is in the range of −5 ppm per degree Celsius to +2 ppm per degree Celsius, thereby reducing the coefficient of thermal expansion mismatch between the graphene-based film and an adjacent ceramic separator substrate having a positive in-plane coefficient of thermal expansion, and reducing area-specific resistance growth attributable to thermally driven delamination over repeated charge-discharge cycling relative to an otherwise identical assembly in which graphene grain size is not controlled for thermal expansion matching. In implementations of the disclosure, the grain size of the graphene-based film is controlled through selection of catalyst metal grain size, deposition method, and cooling profile in a solid-phase diffusion synthesis process, or through selection of growth temperature, catalyst composition, and gas-phase chemistry in a chemical vapor deposition process.

The disclosure further provides a separator assembly comprising: a dense inorganic separator substrate; a graphene-based film on at least one major surface of the separator substrate, the graphene-based film having a nanopore density of 108 to 1012 nanopores per square centimeter, a mean nanopore diameter of 1 nm to 20 nm, a substitutional nitrogen or oxygen dopant concentration of 0.1 to 5 atomic percent, and a mean graphene grain size of 100 nm to 50 micrometers; and at least one of a cathode composite layer, a solid electrolyte thin film, or a lithium-ion-conductive adhesive layer nucleated on and adhered to the graphene-based film. In implementations of the disclosure, the cathode composite layer or solid electrolyte thin film is formed by atomic layer deposition, chemical vapor deposition, physical vapor deposition, or solution-based coating on the graphene-based film having the defined defect profile, and the peel strength between the cathode composite layer and the separator substrate through the graphene-based film exceeds 1.0 joule per square meter.

The disclosure further provides a rechargeable battery cell comprising a separator assembly as described herein, wherein the graphene-based film has a defect profile characterized by a combined vacancy and nanopore areal density, a substitutional dopant concentration, and a grain boundary density, each within a range selected to satisfy simultaneously: a peel strength between the separator substrate and an adjacent cathode composite exceeding 1.0 joule per square meter; a reduction in area-specific interfacial resistance between the separator and the cathode composite of at least 60% relative to an otherwise identical cell lacking the graphene-based film; and absence of lithium dendrite-induced short-circuit in a symmetric lithium-lithium cell over at least 1000 hours of galvanostatic cycling at 0.5 mA cm⁻², wherein the defect profile is achieved by applying one or more of the defect-engineering techniques described herein to the graphene-based film before or after deposition on the separator substrate.

The disclosure provides a method of forming a separator assembly for a rechargeable battery. The method comprises providing a dense solid ceramic separator substrate selected from LATP, LAGP, LLZO, and LLTO; depositing on a cathode-side major surface of the separator substrate a sacrificial metal layer and, on the sacrificial metal layer, an ultra-thin carbon source layer comprising amorphous carbon; subjecting the separator substrate, sacrificial metal layer, and carbon source layer to a low-temperature, back-end-of-line-compatible thermal treatment at a temperature not exceeding 400 degrees Celsius and at a pressure sufficient to drive carbon atoms into and out of the sacrificial metal layer so that few-layer or multilayer graphene segregates as a conformal graphene film directly on the separator substrate; removing substantially all of the sacrificial metal layer and any residual carbon source layer by selective etching to expose the conformal graphene film on the separator substrate; and performing at least one thermal and chemical surface-modification treatment on the graphene film to adjust at least one of electrical resistivity, adhesion to a cathode composite, lithium wettability, and surface roughness. The graphene film has a thickness between 0.3 nm and 1 micrometer and, when assembled against a cathode in a solid-state lithium-ion cell, simultaneously reduces interfacial resistance between the separator and the cathode by at least 50% relative to an otherwise identical cell comprising the separator substrate without the graphene film, and enables lamination of the cathode to the separator at a stack pressure below a predetermined manufacturing limit selected to avoid fracture of the ceramic separator.

The disclosure further provides that the graphene film formed on the separator substrate may be covalently or non-covalently functionalized with at least one functional group selected from hydroxyl, carboxyl, epoxide, carbonyl, sulfonic acid, amine, aryl diazonium-derived aryl groups, and pyrene derivatives, to improve lithium wetting and adhesion of the graphene film to a cathode composite. In implementations of the disclosure, a symmetric lithium-lithium cell incorporating the separator assembly and a garnet-type LLZO separator exhibits no short-circuiting for at least 1000 hours at a current density of 0.5 mA per square centimeter.

The disclosure further provides a separator assembly stack architecture comprising a separator substrate, a graphene film formed on at least one surface of the separator substrate, a lithium-ion-conductive adhesive layer applied between the graphene film and a cathode composite, and the cathode composite. The adhesive layer comprises a lithium polyacrylate or other lithium-salt-containing polymer having an ionic conductivity of at least 10\hat{ }−5 S per centimeter at room temperature. In implementations of the disclosure, the lithium-ion-conductive adhesive layer has a thickness between 100 nm and 10 micrometers and provides an increase in peel strength between the separator and the cathode of at least 50% relative to a corresponding interface lacking the adhesive layer.

The disclosure further provides a method of forming a coated separator for a battery, comprising providing a separator comprising a dense oxide-based, sulfide-based, or halide-based inorganic solid electrolyte; forming on at least one major surface of the separator a graphene-based film having a thickness between 0.3 nm and 1 micrometer by a process selected from solvent dispersion coating, radio-frequency plasma polymerization, chemical vapor deposition, plasma-enhanced chemical vapor deposition, Langmuir-Blodgett coating, and spin-coating; and performing a thermal and chemical treatment configured to adjust at least one of resistivity, adhesion, wettability, and roughness of the graphene-based film such that area-specific interfacial resistance growth during cycling in a full cell is reduced relative to an otherwise identical cell using the separator without the graphene-based film. In one implementation, the graphene-based film is derived from a dilute multilayer graphene dispersion in water or alcohol that is spray-cast or dip-coated onto the separator and annealed at 200 to 250 degrees Celsius. In another implementation, the separator comprises a composite of LLZO particles dispersed in a polymer matrix and the graphene-based film is formed selectively on a polymer-rich surface region having a lower elastic modulus than a bulk of the composite, thereby enhancing mechanical compliance at an interface with a cathode.

The disclosure further provides a solid-state lithium-ion battery comprising an anode comprising lithium metal or a lithium-containing alloy, a separator assembly as described herein, and a cathode comprising an active material laminated onto the graphene film via the lithium-ion-conductive adhesive layer, wherein the battery exhibits reduced area-specific resistance growth and reduced capacity fade attributable to cathode-separator delamination compared to an otherwise identical battery lacking the graphene film. The disclosure also provides a hybrid battery comprising a separator assembly as described herein, a liquid or gel electrolyte in contact with the separator assembly, and electrodes on opposing sides of the separator assembly, wherein the graphene-based film is chemically stable in the presence of the liquid or gel electrolyte over at least 500 hours of operation without significant increase in cell impedance. Please provide a summary of the invention. This is usually separate from the Abstract section found later in the document.

### BRIEF DESCRIPTION OF DRAWINGS

FIG. 1 illustrates an example top-view of the graphene process and transfer chambers of a graphene synthesis tool 100, according to some embodiments.

FIG. 2 illustrates an example schematic view of the internal elements of a process chamber, according to some embodiments.

FIG. 3 illustrates an example high-level flowchart of a process 300 for migration of a deposition material across a diffusion couple deposited on a substrate, according to some embodiments.

FIG. 4 illustrates a detailed synthesis process including a plurality of step ranges, process parameters, and optional cleanup branches, according to some embodiments.

FIG. 5A illustrates an exemplary view of a source-up prepared substrate 508.

FIG. 5B illustrates an exemplary view of a source-down prepared substrate 528.

FIG. 5C illustrates an exemplary view of a dual-source prepared substrate 538.

FIG. 6 is a flowchart of an example process 600 according to implementations of the disclosure.

FIG. 7 is a schematic representation of a battery layout with MLG grown/transferred onto a separator (a list of possible separators is provided below).

FIG. 8 is a schematic representation of MLG with possible functional groups relative to the separator.

The Figures described above are a representative set and are not exhaustive with respect to embodying the invention.

### DETAILED DESCRIPTION

The following description is presented to enable a person of ordinary skill in the art to make and use the various embodiments. Descriptions of specific devices, techniques, and applications are provided only as examples. Various modifications to the examples described herein will be readily apparent to those of ordinary skill in the art, and the general principles defined herein may be applied to other examples and applications without departing from the spirit and scope of the various embodiments. Reference throughout this specification to “one embodiment,” “an embodiment,” “one example,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment. Furthermore, the described features, structures, or characteristics of the invention may be combined in any suitable manner in one or more embodiments.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

As used herein, the terms “about” and “approximately” when used in reference to a numerical value, are intended to mean the stated value plus or minus 10% of that value, or as a person of ordinary skill in the art would understand to be within a reasonable range of experimental error, unless otherwise specified.

### Definitions and Conventions

Where applicable, terms may be defined in accordance with their definitions in the SEMATECH dictionary, and as understood by one skilled in the art.

Back-End-Of-Line (BEOL) is the second portion of IC fabrication process where interconnects and other circuit elements are formed between and over the individual devices (primarily the transistors) on the wafer (e.g., the metallization layers) separated by intra-layer and/or inter-layer insulators.

Complementary metal-oxide semiconductor (CMOS) is a type of metal-oxide-semiconductor field-effect transistor (MOSFET) fabrication process that uses complementary and many times electrically symmetrical pairs of p-type and n-type MOSFETs for implementing at least logic functions.

Grain boundary (GB) is the interface between two grains and/or crystallites in a polycrystalline material.

Graphene is an allotrope of carbon consisting of a single layer of atoms arranged in a two-dimensional honeycomb lattice.

Graphene nanoribbons (GNRs) are strips of graphene with a width less than about one-hundred (100) nm.

Graphite is a layered crystalline form of the element carbon with its atoms arranged and covalently bonded forming a hexagonal structure within the layers.

Intercalation doping: Intercalation is when a molecule or ion inserts reversibly between the layers of a compound (such as potassium ions between graphite layers). Doping is adding impurities into a material. The dopant (impurity ion) will incorporate into the material's lattice. N-type dopants will donate electrons to the material. P-type dopants will accept electrons from the material. This will change the charge carrier density and consequently the electronic properties of the material.

Intercalation doping agents: There are many in the literature. Specific to graphene is recent work by Kaustav Banerjee, et al. ; for example, J. Jiang, Jae Hwan Chu, and Kaustav Banerjee, “CMOS-Compatible Doped-Multilayer-Graphene Interconnects for Next-Generation VLSI,” IEDM 2018, pp. 799-802, 34.5.1-4; and J. Jiang, et al., “Intercalation doped multilayer-graphene-nanoribbons for next-generation interconnects,” Nano Letters, vol. 17, no. 3, pp. 1482-1488, 2017.

Silicon dioxide is an oxide of silicon and an insulator with the chemical formula SiO2.

### Substrate and Prepared-Substrate Definitions

Substrate: A substrate on which one or more layers or levels of MLG may be formed can take many forms and comprise various materials and combinations thereof. The largest volume and most conventional would be mono crystal silicon wafers, with diameters from about 100 mm, about 125 mm, about 150 mm, about 175 mm, about 200 mm, about 250 mm, about 300 mm, about 325 mm, about 350 mm, about 375 mm, about 400 mm, about 450 mm, or to about 500 mm. Substrates could also have different shapes, for example, such as square, rectangular, circular, ribbon, and so on, and may have regions which may have a flat and/or a notch or some other small shape/removed or added region which may be used to indicate crystalline orientation.

The material used in a substrate may include semiconductor materials, for example, such as silicon, Gallium, GaAs, SiGe, Germanium, and may be doped with, generally, elements such as B, As, Sb, P, O, or N. The substrates may be engineered substrates, for example, such as SOI or GeOx and so on. Moreover, substrates may include glass(es) of diverse types and grades, which may be doped with elements and so on. Additionally, substrates may contain devices (device substrates), for example, such as transistors, resistors, capacitors, inductors, logic, memory, volatile memory, non-volatile memory, low-k Dielectrics, barrier metals such as Ti, TiN, TaN so so on, interconnect metals such as Al, AlCu, AlSi, AlCuSi, W, Cu, Co, Ru, MLG, and combinations of these. Interconnect may include subtractive and damascene (as applicable) lines and spaces, RF, optical, MLG, and traditional metals. Substrates may also contain 3D stacks, 2-D materials, and so on. Vertical connections/connectivity may include vias, local interconnect, TLVs, TSVs, and so on. Substrates may also include chip packaging structures such as, for example, interposers, organic and inorganic substrates, and the like, which may be prepared for MLG formation.

Wafer: A thin slice of semiconductor (e.g., crystalline silicon and/or germanium), typically in single-crystal (monocrystalline) form, though they may also be amorphous, are utilized in the fabrication of integrated circuits and related applications. A Substrate may include a Wafer.

It will be appreciated that the surface of a substrate or wafer may exhibit complex topography arising from the various fabrication processes used to build up interconnect structures, packaging structures, or other device features. By way of example without limitation, such topography may include recessed features, such as trenches, vias, cavities, and moats formed by etching processes, as well as protruding features, such as copper pillars, microbumps, solder bumps, and redistribution layer (RDL) traces formed by deposition, electroplating, and patterning processes. The surface may further include bond pads, passivation layer openings, and polymer mounds arising from dielectric and passivation patterning steps. At finer scales, the surface may exhibit step height discontinuities, dishing, and erosion artifacts introduced by chemical mechanical planarization (CMP), as well as sidewall profiles and rounding effects resulting from etch and reflow processes. Collectively, these features can produce a surface topography that may significantly vary across the substrate in terms of local height, slope, and curvature, reflecting the underlying pattern density, material stack, and process history of the substrate. It will be appreciated that in some implementations, the preparation and/or process operations applicable to a substrate disclosed herein can be (at least partially) conformally applied on such surface topography.

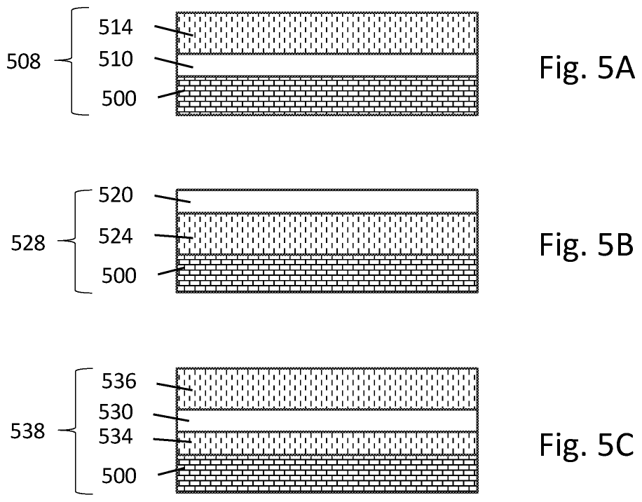

Prepared Substrate: A Prepared Substrate is a Substrate which may be prepared for 2D material formation and processing. The 2D formation processing may include those methods and schemes taught herein or not herein. A 2D material which may be formed includes graphene, which may be formed as a multi-layered graphene (MLG), few layer graphene (FLG), or single layer graphene film or layer. A prepared substrate may include a layer or layers of films which may then be processed to form the 2D material. A prepared substrate may include at least three different structures as illustrated in FIGS. 5A, 5B, and 5C.

Source-up prepared substrate: As illustrated in FIG. 5A, a source-up prepared substrate may include device substrate/wafer, sacrificial catalyst layer, and carbon source layer. Carbon source layer is located atop the sacrificial catalyst layer. Sacrificial catalyst layer is located atop device substrate/wafer.

Source-down prepared substrate: As illustrated in FIG. 5B, source-down prepared substrate may include device substrate/wafer, sacrificial catalyst layer, and carbon source layer. Sacrificial catalyst layer is located atop the carbon source layer. Carbon source layer is located atop device substrate/wafer.

Dual-source prepared substrate: As illustrated in FIG. 5C, dual-source prepared substrate may include device substrate/wafer, sacrificial catalyst layer, first carbon source layer, and second carbon source layer. Second carbon source layer is located atop the sacrificial catalyst layer. Sacrificial catalyst layer is located atop the first carbon source layer. First carbon source layer is located atop the device substrate/wafer. In general, the first carbon source layer may be thinner than the second carbon source layer.

A note on prepared substrates and this disclosure: Within this disclosure the source-up prepared substrate is utilized as the exemplary substrate when describing/teaching the various methods, process flows, and schemes for forming 2D materials, for example, such as multi-layer graphene (MLG), as well as how a disclosed apparatus may be employed for that formation. Wherever the source-up substrate is so utilized, the other two types of prepared substrates may also be employed. All three are capable to generate a 2D material, such as MLG. However, each type of prepared substrate may have a different process window and 2D material quality generated from the specific process and/or apparatus employed.

Sacrificial catalyst metal layer thicknesses: The sacrificial catalyst metal layer, such as nickel or cobalt, may be deposited to thicknesses from about 2 nm to about 100 nm or more. The nominal thicknesses include about 2 nm, about 3 nm, about 4 nm, about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 100 nm, about 150 nm, about 200 nm, about 250 nm, about 300 nm, about 350 nm, about 400 nm, about 450 nm, or about 500 nm.

Carbon source layer materials and thicknesses: The carbon source layer may comprise amorphous carbon, graphitic powder, or other carbon-carrying materials. The carbon source layer may be deposited to thicknesses from about 2 nm to about 500 nm. The nominal thicknesses include about 2 nm, about 3 nm, about 4 nm, about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 100 nm, about 150 nm, about 200 nm, about 250 nm, about 300 nm, about 350 nm, about 400 nm, about 450 nm, or about 500 nm.

Device substrate specifications: The device substrate may include at least one device layer, the device layer including transistors and other semiconductor devices, such as diodes, RF structures, capacitors, resistors, and so on, and possibly one or more layers of interconnect, the interconnect may include copper, cobalt, silver, ruthenium, MLG, low k dielectrics for isolation, and so on. A dielectric layer on top of the device layer may include Silicon Dioxide or other low-k dielectrics, with thicknesses from about 5 nm to about 500 nm or more. Device substrates may also include chip packaging structures such as, for example, interposers, organic and inorganic substrates, and the like, which may be prepared for MLG formation.

In some implementations, instead of SiO2, the substrate can be Si. In some implementations, the substrate can be copper or another metal (such as cobalt, ruthenium, molybdenum, tungsten, or an alloy metal, etc.), or a low dielectric constant (low-k) material such as porous silicon-dioxide or hydrogen silsesquioxane (HSQ), or black diamond, etc., or even any patterned substrate formed with metals and dielectrics, etc. In such embodiments, the modification can include a sacrificial layer of amorphous carbon between the catalyst layer (e.g. Ni) and the underlying substrate metal (e.g. Cu). In this way, for example, the Ni and the Cu can be prevented from forming an alloy. In other examples, other metals can include, inter alia: Co, Ni, Ru (as both a substrate and/or a catalyst), molybdenum, etc., or a metal compound.

### Dewetting Mechanism and References

Another atomic solid-state mechanism which may be important in some 2D-material, especially graphene and MLG, formation regimes is the ‘dewetting’ phenomena. When a sacrificial catalyst layer, for example, Ni, is deposited onto a substrate, the deposited film may be prone to “dewet”, meaning the natural tendency to reduce the surface area of itself to dwell to the lowest energy state, for which the film thickness and the temperature are crucial to the degree of dewetting. For example, a thinner Ni film (~20 nm) would tend to dewet at a lower temperature (for example, 380 °C) than it would require for a thicker film (~60 nm) which dewets at a higher temperature (for example, 400 °C).

Dewetting is the process of retraction of a fluid from a non-wettable surface on which it was forced to cover. Solid-state dewetting of the metal thin films describes the transformation of a thin film into an energetically favored set of droplets or particles at temperatures well below the metal's melting point. Thinner films beget a higher probability of dewetting as well as lower temperatures at which dewetting is observed. For example, Ni metal films with thickness from 3 nm to 30 nm are prone to show dewetting at temperatures at or under about 400 °C. Above about 400 °C to about 500 °C dewetting may occur up to about 100 nm Ni thicknesses. It is believed that a mechanism of multilayer graphene (MLG) formation involves segregation of carbon atoms at the edge/interface of dewetted droplets/particles which may be induced to form MLG at the interface between the previous metal (Ni) layer and the top surface of a dielectric, for example, SiO2, or the top surface of metals/alloy films. As the carbon diffuses thru the nickel droplets/particles, graphene may be formed at substantially all edges of the droplets/particles, even ‘underneath’ the droplets/particles.

References for this phenomenon: Barton, L., et al., “On the mechanisms of precipitation of graphene on nickel this films,” arXiv: 1106.383 2v2, 30 Jun. 2011. ; and Marchena, M., et al., “Low temperature direct growth of graphene patterns on flexible glass substrates catalysed by a sacrificial ultrathin Ni film,” Optical Materials Express, vol. 6, No. 8, pp. 2487-2507 (1 Aug 2016); the entire contents of all of the foregoing are incorporated by reference herein.

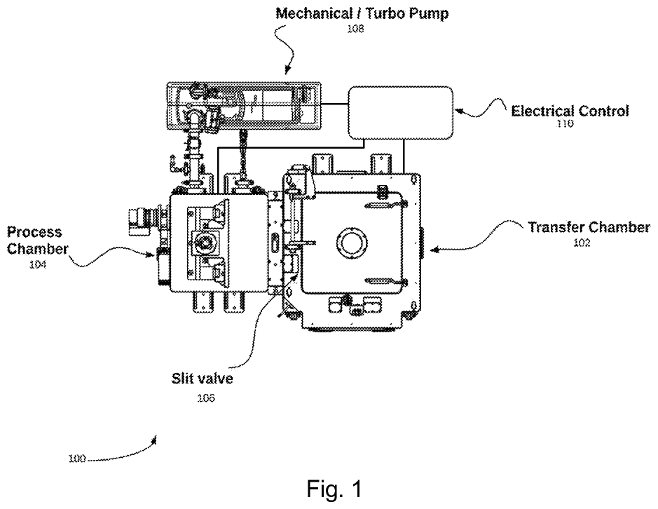

### Description of FIG. 1 (Tool Top View)

FIG. 1 illustrates an example top-view of the graphene process and transfer chambers of a carbon-source formation/synthesis tool 100, according to some embodiments. It is noted that in other example embodiments, other diffusion materials (other elements in the periodic table suitable for a specific diffusion metal and application) than carbon-sources can be utilized. The carbon-source formation/synthesis tool 100 includes a transfer chamber (or load lock chamber) 102, which is used to load the wafer/substrate. The wafer/substrate can be of various sizes (e.g. 300 mm, 200 mm, 150 mm, etc.). An operator/user can place the wafer/substrate in the transfer chamber 102. The transfer chamber 102 is then closed and sealed. The pressure of the transfer chamber 102 is equalized with the pressure of the process chamber 104. Once the pressure is equalized, the wafer/substrate is then pushed to the process chamber 104. It is noted that the wafer/substrate can be returned to the transfer chamber 102 after implementation of the deposition and other fabrication methods.

It is noted that some process schemes involve two or more wafers/substrates per position (i.e. one wafer/substrate on top of the other on top of another and so on, generally (but not necessarily) with the active ‘top’ of the wafer/substrate facing outwards, towards each platen/disk) in the apparatus, where the heat and sometimes compression acceleration can be applied to the two or more wafers/substrates simultaneously and thus synthesize the graphene on all of the wafers/substrates.

The process chamber 104 and the transfer chamber 102 are connected via a slit valve 106. Slit valve 106 may be opened once the pressures inside the two chambers are equalized.

The process chamber is the main chamber (or reactor) for growth of graphene (and/or other carbon material) on the wafer and/or the application of temperature and pressure to form the diffusion-couple and ultimately high-quality graphene at the desired surface.

Mechanical/turbo pump 108 can be used to control pressure in process chamber 104 and/or transfer chamber 102. Mechanical pump(s) 108 (e.g. a dry vacuum pump) can be used to lower pressure in process chamber 104 (e.g. 10-3 torr). The turbo pump 108 (e.g. a molecular turbo pump) can be a more powerful pump that is used to lower the pressure even further (e.g. 10-7 torr). Low pressure is desired to purge the chamber of any impurities during the operation of the graphene formation, for example, by a diffusion-couple method. In one embodiment, a dry vacuum pump can be connected to the load lock, as well as the process chamber. The dry vacuum pump may also be connected to a molecular turbo pump, which is directly connected to the main process chamber for the purpose of reaching a HV level condition, for example, such as about 1×10⁻³ torr, or about 1×10⁻⁴ torr, or about 1×10⁻⁵ torr, or about 1×10⁻⁶ torr, or about 1×10⁻⁷ torr, or about 1×10⁻⁸ torr, and so on.

Electrical control 110 can be used to operate carbon-source formation/synthesis tool 100. Electrical control 110 can include computer processor(s) and software systems. Users can input commands, view status of various operations of carbon-source formation/synthesis tool 100, etc. In one embodiment, electrical control 110 includes a control tower for electrical and pneumatic control and distribution, and a computer (e.g. personal computer (PC)) with custom control, display, and logger software for the machine. The control tower for electrical and pneumatic controls distribution may be utilized via remote control from the computer or equivalent. A screen may be utilized for graphical display of machine data (temperatures, positions, pressures, etc.), as well as for graphics showing the control connectivity and vacuum valve status.

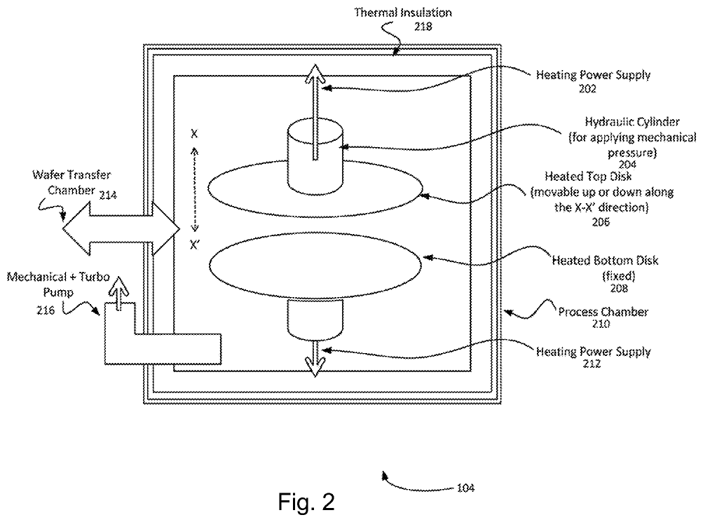

### Description of FIG. 2 (Process Chamber)

FIG. 2 illustrates an example schematic view of the internal elements of a process chamber, according to some embodiments.

A slightly larger than substrate-sized heated bottom disk (or plate/chuck/platen) 208 (e.g. bottom disk 208 can be slightly larger than 300 mm for a 300 mm substrate) is located in the process chamber 104. Process chamber 104 is equipped with a heater system. A heated top disk (or plate/chuck/platen) 206 is located in the process chamber 104 as well. The heated top disk 206 has its own heating mechanism as well (e.g. see heating power supply 202). In this way, both the lower disk on which the wafer is placed and the heated top disk can be heated independently or synchronously. For example, the lower disk can be heated and the top disk can be kept at approximately room temperature (or vice versa). The liner surfaces (covering the disks) can be made of graphite, though other materials such as aluminum nitride, quartz, silicon carbide coated graphite, etc. can be employed. Several such materials are possible-generally speaking materials which permit good heat transfer and distribution of pressure can be considered. Flatness and surface finish of the liner can be a key factor to ensure appropriate heat and pressure distribution.

Wafer transfer chamber 214 is provided showing transfer of the wafer back and forth. Heated bottom disk 208 can be fixed in position and can be heated to a specified temperature (e.g. 500 °C, etc.). Heat power supply 220 can maintain heat on the heated bottom disk 208. This can be done with a ±3 C uniformity (and/or near-zero non-uniformity) across the heated bottom disk 208. Heated top disk 206 can move up and down along an axis, for example, such as the two tips indicator arrow X and X′. Heated top disk 206 has an independent heating supply. Heated top disk 206 can be operated with hydraulic cylinder 204, a motor, and the like. Heated top disk 206 can be moved to provide mechanical pressure. By way of example, this pressure can be 50 to 125 psi, or more. The wafer is inserted on top of heated bottom disk 208. The heated top disk 206 may apply mechanical pressure to the diffusion-couple while the chamber pressure is maintained at a low value for methods and applications where mechanical pressure is employed. This chamber pressure can be, for example, 10-6 to 10-7 torr to prevent contamination of the growth process. Chamber pressure can be regulated by mechanical/turbo pump 216 and associated equipment, sensors, and software. At least one port (not shown) into the chamber may be provided to insert gas for a variety of purposes, such as for faster cooling of the substrate, or providing a pure and clean environment for atmospheric and slightly sub-atmospheric graphene formation methods. This may be applied, of course, to other machines, equipment, apparatuses, and chambers described herein.

A torque converter may be connected to the top heated platen/chuck for applying pressure directly to the wafers under processing. There can be resistance heating coils buried within the top and bottom platen/wafer-chuck for direct heating of the substrate, as well as coolant channels defined therein through which a coolant liquid can be circulated to enable rapid cooling of the top or bottom platens. Additionally, chilled water/coolant may be circulated around/within the chamber lid/top, side walls, and chamber base for temperature control and to preserve o-ring vacuum seals.

The process chamber can be used to deposit/grow a number of layers (e.g. monolayer or few-layer graphene (FLG) structures, or multi-layer graphene (MLG) structures). To grow graphene, a carbon/graphene source is deposited on a thin film of nickel (e.g., 5-500 nm in thickness). The graphene source (and/or other carbon-source) can be, inter alia: a graphite powder, a liquid/slurry form as a solvent with graphite, a layer of amorphous carbon deposited on nickel. Different deposition methods and tools can be utilized to deposit the thin film of nickel followed by the carbon source deposition on top of the nickel. The nickel, or other diffusion/catalyst layer, may include thicknesses as disclosed herein, from about 5 nm to about 500 nm. The applied mechanical pressure breaks up the carbon/graphene source into carbon atoms or small agglomerations thereof, which then diffuse through the nickel and then recombine on the other side of the nickel film on top of the target substrate (for example, such as a dielectric layer on a Si wafer). Once the formation of the desired number of graphene layers is completed, the nickel film and the remains of the carbon source are then removed.

### Process Chamber Features: Compliance, Heating, and Sensors

The reactor may be provided with sufficient clearance and play and compliance to the top heater mechanism, and by providing a layer of compliance to the application surfaces, so that the application surfaces are parallel to the substrate and sufficiently compliant so as to not damage the substrate.

The reactor may also be provided with the means to put the substrate under vacuum and expose it to other gases such as, inter alia, N2, Ar, He, and the like to optimize the process. Hence the reactor may be equipped with vacuum pumps as well as gas lines and a gas panel to ensure ability to put the substrate under various environments, including atmospheric and slightly sub-atmospheric conditions.

The reactor may be interfaced to equipment that can deliver the substrates to and from the reactor. For example in the case of wafer processing the reactor may be attached to the facet of a transfer chamber that is equipped with a wafer handling robot that can operate under high vacuum. In some examples, a slit valve can be provided to isolate the reactor from the rest of the system. A plurality of reactors may be attached to the transfer chamber to facilitate higher throughputs or production rates. There can also be reactors that deposit the diffusion couple including the source material attached to the transfer chamber, such as sputtering and CVD chambers, thereby permitting the creation of the layers on the substrate as well as the deposition of the final material on the same system, as discussed below.

The process chamber provides in situ sensors (e.g., in the reactor, etc.) to ensure that the pressure and temperature distributions in turn result in optimal migration of the deposition material across the diffusion couple. For example the pressure can be calibrated and monitored through the use of a pressure sensor on the step of the pedestal, through monitoring of the current drawn by the motor applying the pressure between the surfaces, through use of flexures configured as strain gauges embedded in the liner material and the like. Likewise the temperature can be monitored using thermocouples and RTDs mounted in the pedestals, use of IR sensors, phosphorus-based sensors, and the like.

Software controls can be provided to ensure appropriate application of the process parameters in the right sequence and duration.

### Process With Applied Pressure

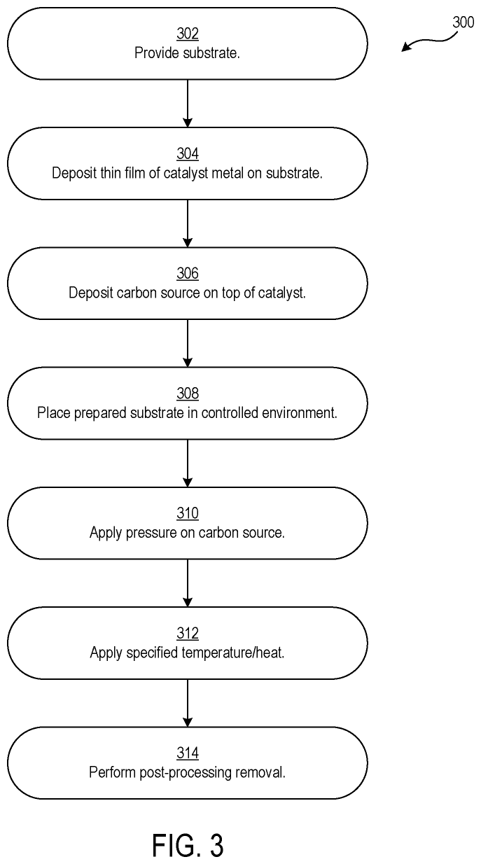

FIG. 3 illustrates an example graphene/2D material synthesis process 300, according to some embodiments. Process 300 can be used to operate carbon-source formation/synthesis tool 100 or any of the other equipment/apparatus disclosed or suggested herein. In some implementations, process 300 may be implemented on equipment described herein, as well as, inter alia, on a commercial bonding tool, an isostatic sintering apparatus, hot isostatic press (HIP) apparatus, and hot pressure vessel (HPV) apparatus, provided such tools are configured to accept a substrate for processing according to the described parameters.

Process 300 can grow graphene at relatively low temperatures (e.g., 300-450 °C, etc.). It is noted that when process chamber 104 is below ~450 C it can be compatible with a CMOS/BEOL thermal budget. BEOL are process steps that take place after front-end-of-line transistors are fabricated; once a fabrication process has built the transistors on the wafer, the subsequent processing steps should be within the ~450 C thermal budget to avoid damage to the transistors and various junctions that may lead to shorts and reliability issues, as well as potential damage to some of the low-k dielectrics utilized in modern BEOL isolation layers between interconnect lines/layers.

Process 300 can directly grow graphene (transfer-free) on top of any suitable substrate (e.g., dielectric/Si substrate, metallic substrate, etc.), and can synthesize graphene to a thin/few/multi-layer coating as well. Process 300 synthesizes graphene while the number of graphene layers can be controlled by adjusting process parameters, providing controlled thickness from monolayer to multilayer. More generally, process 300 provides for the migration of a deposition material across a diffusion couple deposited on a substrate to the substrate surface, and may be used to deposit a material that is not readily deposited directly using conventional methods (e.g., graphene is not known to be directly synthesized on silicon; process 300 permits this to be realized). The grain and other material structures of the deposited material may be tailored by appropriately varying the structure of the diffusion couple and/or the process conditions.

In step 302, process 300 provides a substrate (e.g., a wafer). The substrate can be Si/SiO2, or alternatively the substrate can be copper or another metal (such as cobalt, ruthenium, molybdenum, tungsten, nickel, or an alloy metal, etc.), or a low dielectric constant (low-k) material such as porous silicon-dioxide or hydrogen silsesquioxane (HSQ), or black diamond, etc., or even any patterned substrate formed with metals and dielectrics, etc. In other examples, other metals can include, inter alia: Co, Ni, Ru (as both a substrate and/or a catalyst), molybdenum, etc., or a metal compound. The substrate or wafer in various implementations can be 300 mm or 200 mm, or smaller/larger (e.g., 450 mm) in diameter.

In step 304, process 300 deposits a thin film of a catalyst metal (e.g., nickel) on the substrate. The thicknesses of the substrate and catalyst can be set (e.g., 100 nm, etc.). In some embodiments, where the underlying substrate is or includes a metal such as Cu, a sacrificial layer of amorphous carbon can be deposited between the catalyst (e.g., Ni) and the underlying metal (e.g., Cu). In this way, the Ni and the Cu can be prevented from forming an alloy.

The morphology of the catalyst film can be tuned during the deposition or after deposition (e.g., via annealing, etc.) to meet specific application needs.

In step 306, process 300 deposits a uniform distribution of a carbon-source on top of the catalyst (e.g., on top of Ni), thereby forming what may be referred to as a prepared substrate or layer substrate comprising a diffusion couple (e.g., carbon-source/Ni/SiO2/Si). In some implementations, the carbon source may be graphite powder that can be spread in a uniform or pre-patterned manner. In some implementations, other carbon-containing compounds can also be used, e.g. amorphous carbon.

In step 308, process 300 places the prepared substrate into a controlled environment, which can include high pressure and high temperature in some implementations, ranges of which are specified in this document and incorporated by reference citations, for a period of time. A single substrate or multiple substrates as batches can be processed at once. In some implementations, the process controls the processing environment by placing the substrate under vacuum and/or exposing it to one or more gases to optimize the process. The gas can be normal air or a specific gas such as Ar, N2, He, H2/N2, and the like, or a mixture of many such gases. The reactor may accordingly be equipped with vacuum pumps as well as gas lines and a gas panel to ensure the ability to put the substrate under various controlled environments.

In step 310, process 300 applies a specified pressure to facilitate the migration of one or more diffusion materials across the diffusion couple to the substrate. A pressure of 65 to 85 psi may be applied on the carbon-source. Pressure on the substrate forming the diffusion couple can be applied by mechanical means, for instance by employing an instrument such as a chuck (e.g., a disc with a diameter slightly larger than the 300 mm wafer can be used as the chuck/disk to press down on the uniformly distributed graphite), or via any non-contact means such as increasing the substrate environment pressure by, for instance, using a gas pressure (1 bar to several 1000s of bars). Pressure may also be applied through flexible membranes, through liquid pressure, and the like. The application surfaces of the top and bottom heaters/pedestals through which pressure is applied are parallel to the substrate and sufficiently compliant so as not to damage the substrate; this is accomplished by providing sufficient clearance and play and compliance to the top heater mechanism, as well as by providing a layer of compliance, if needed, to the application surfaces. The substrate may be placed on a pedestal (e.g., disk) through means of a handler typical to the equipment industry, and a top moving heater (embedded in a disk) may then move down and put the substrate under pressure while at the same time heating it.

In step 312, process 300 applies a specified temperature to facilitate the migration of the one or more diffusion materials across the diffusion couple to the substrate. The substrate (wafer) can be heated to 300 °C to 450 °C. More generally, a temperature controller can be used to maintain the temperature anywhere from room temperature (~25 C) to 500 °C, or higher as long as process compatibility is met. Application of heat can be from any source capable of generating a temperature on the substrate, including, inter alia, resistive heating, radiative heating, and gas heating. In some embodiments, both the top disk and/or the bottom disk can be heatable and heat the substrate through direct contact (note that the contact materials may be varied through use of appropriate liner materials). In other embodiments, the top substrate disk and/or the bottom substrate disk may not be heatable, and there can be another heat source such as, for example, the pressure chamber walls, etc. At temperatures below ~450 C, process 300 implements low-temperature graphene films compatible with a CMOS/BEOL thermal budget.

Once the pressure and temperature are applied, a portion of the carbon items diffuses through the catalyst (e.g., Ni) film. The carbon-source/Ni/SiO2/Si stack acts as a diffusion couple, and the carbon atoms recombine on the other side of the catalyst (e.g., facing the SiO2) to form a monolayer, few-layer, or multilayer graphene directly on the substrate surface (i.e., a direct, transfer-free graphene synthesis on various substrates). Depending on the catalyst film thickness, a dewetting mechanism may be the dominant graphene formation mechanism; in many process conditions and prepared substrate examples, a mixture of the mechanisms may be at play. The number of layer(s) of graphene (i.e., its thickness) can be controlled from monolayer to multilayer, and is a function of the thickness of the catalyst (e.g., Ni) along with other process parameters including time, temperature, pressure, and grain-size of the catalyst film.

In situ sensors (e.g., in the reactor, etc.) can be provided to ensure that the pressure and temperature distributions result in optimal migration of the deposition material across the diffusion couple. For example, the pressure can be calibrated and monitored through the use of a pressure sensor on the step of the pedestal, through monitoring of the current drawn by the motor applying the pressure between the surfaces, through use of flexures configured as strain gauges embedded in the liner material, and the like. Likewise, the temperature can be monitored using thermocouples and RTDs mounted in the pedestals, use of IR sensors, phosphorus-based sensors, and the like. Software controls can be provided to ensure appropriate application of the process parameters in the right sequence and duration.

In step 314, process 300 performs various post-processing steps, including, inter alia, removing any remaining carbon source material (e.g. graphite) and removing the metal catalyst (e.g., Ni) layer.

The reactor implementing process 300 may be interfaced to equipment that can deliver substrates to and from the reactor. For example, in the case of wafer processing, the reactor may be attached to a facet of a transfer chamber that is equipped with a wafer handling robot that operates under high vacuum. In some examples, a slit valve can be provided to isolate the reactor from the rest of the system. A plurality of reactors may be attached to the transfer chamber to facilitate higher throughputs or production rates. There can also be reactors that deposit the diffusion couple, including the source material, attached to the transfer chamber (such as sputtering and CVD chambers), thereby permitting the creation of the layers on the substrate as well as the deposition of the final material on the same system. When the process is completed, the substrate is returned out from the reactor (e.g., the process chamber).

### Process for Application of Direct/Indirect Heating to Form MLG via Diffusion/Dewetting

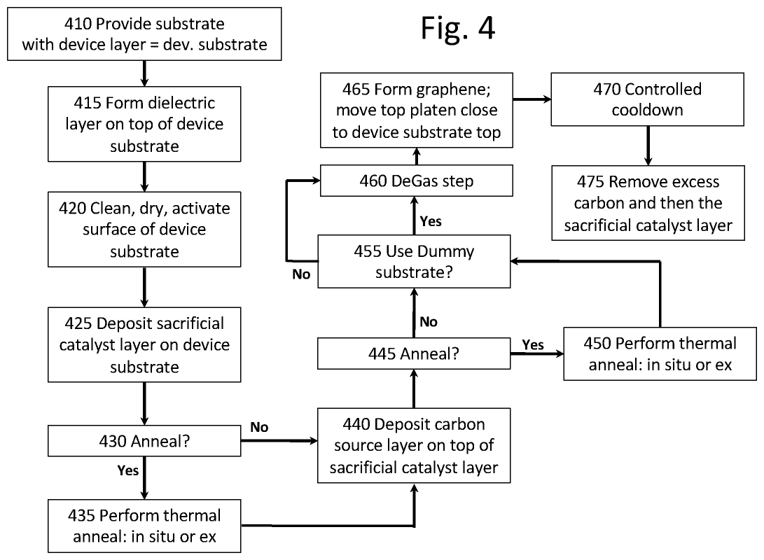

In at least exemplary illustration FIG. 4, the teaching herewith and an additional inventive embodiment, an MLG film may be formed/synthesized on a substrate using the following illustrative procedure, whether in full or in part. In some implementations, this exemplary process flow/method may be utilized when utilization of the ‘dewetting’ mechanism is an important consideration and/or no or minimum mechanical pressure is applied during the MLG/graphene formation step.
410 Begin with a substrate, for example, such as a monocrystalline silicon wafer of various diameters (range described herein) which may include at least one device layer, the device layer may include transistors and other semiconductor devices, such as diodes, RF structures, capacitors, resistors, and so on, and possibly one or more layers of interconnect, the interconnect may include copper, cobalt, silver, ruthenium, MLG, low k dielectrics for isolation, and so on. The substrate may also include memory elements, memory cells, stacking of transistor and/or memory elements whether monolithic or via other stacking technology. Substrate may include optical elements such as optical generation, transmission, and receiving elements and structures; as well as RF transmission waveguides, generation and receive elements and structures, and the like. Substrate may include cooling elements such as thermoelectric elements, cooling channels for liquid and/or gaseous cooling use, and so on. Additionally, substrate may simply be a test wafer for developing an MLG process at a wafer fab or other manufacturing facility.

For the purposes of this illustration and clarity, the substrate may include at least one device layer and therefore can also be called a device substrate.
415 The device substrate may be partially made ready for the MLG formation/synthesis by having a dielectric layer (e.g. an oxide layer in some implementations), for example, such as including Silicon Dioxide or other oxides, deposited, or grown at CMOS compatible temperatures, if applicable, the dielectric layer in some implementations having a nominal average across the device substrate thickness of about 5 nm to about 500 nm, or more, located on the topside of the device substrate. In some implementations, an MLG layer and/or interconnect layer may also be synthesized/formed on the backside of the device substrate to help form backside interconnects if required by engineering, design, or marketing considerations. The dielectric layer may include a low-k dielectric and other electrically isolative materials as well. Note: MLG formation may also take place on top of and/or in contact with a metal layer (covering a majority of the substrate/wafer) or regions, including, for example, Cu metal layer or regions, Co metal layer or regions, TiN layer or regions, W layer or regions, and so on. This level of regions may include lines and other shapes of metal or alloys.

The device substrate may be prepared further by forming the sacrificial diffusion/catalyst layer and the carbon source layer, such as in the following steps.
420 The top surface of the device substrate may be cleaned and dried. For example, a dry clean such as a short Ar or O2 or mixture plasma may be applied to the substrate top surface. This also helps form some dangling and energetic bond segments so that the sacrificial diffusion layer adheres better to the substrate top surface. A wet clean may also be employed, but care must be taken to not attack any exposed device structures by the cleaning chemistry. An evenly clean and chemically active surface is important to the interface of the sacrificial diffusion layer bottom, generally a metal such as Nickel as a diffusion/catalyst layer, as described herein, and the top of the device substrate, which is generally an oxide (dielectric), as this is where the graphene layer will be synthesized/formed.

For example, a directional plasma, such as an RIE O2 or Ar plasma at 200 W and about 300 mtorr for example, may be employed to condition the surface of the device substrate, generally an oxide. Graphene formation atop a metal or metal alloy may require a differing surface preparation, described in detail within incorporated references herein, for example, such as depositing a very thin (1 nm to 5 nm) layer of amorphous carbon, and so on. It is important to control the dewetting aspect of a diffusion such as, for example, nickel, so that the device substrate top surface energy resists and controls the dewetting phenomena such that a proper and even graphene layer/MLG is formed in later steps. Moreover, the surface may be controlled via alternative or combinational treatments, for example, such as a shallow and high dose ion implant of, for example, species such as Ar, As, and so on. Other network modifiers may be employed in modifying at least the surface of the device wafer topside, to modify the surface energy of the oxide or oxide-like material to resist and control the dewetting phenomena. A chemical-mechanical polish (CMP) may also be configured to provide a physically slightly rough surface to provide at least a portion of a modifying surface energy to resist and control the diffusion metal dewetting phenomena.

A dry surface is important to provide a clean and controlled surface to deposit the sacrificial diffusion layer atop the device wafer top surface. For example, a 250 °C hot plate bake in air may be a surface preparation described just above herein and may be utilized before and/or after the cleaning and surface modification steps, if any. Naturally, a vacuum oven bake at temperatures of 100-300 °C may be employed, as well as other ambient and heating styles depending upon engineering, production, cost, and location considerations
425 Then the substrate may be placed in a metal deposition machine, for example, such as a vacuum evaporator, and a pre-clean to remove a last residual surface contamination and moisture from the substrate top surface may be employed in situ.

Then the sacrificial diffusion/catalyst layer may be deposited. This may be a metal, for example, such as Ni, and may be deposited to a thickness between about 5 nm to about 500 nm at nominally room temperature. The nominal sacrificial diffusion layer thicknesses after deposition may be about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 100 nm, about 150 nm, about 200 nm, about 250 nm, about 300 nm, about 350 nm, about 400 nm, about 450 nm, or about 500 nm depending on device, engineering, and cost considerations.

The nominal deposition temperature may range from about 20 °C to about 500 °C

For example, the sacrificial diffusion/catalyst layer deposition temperature may be about 20°C, about 30 °C, about 40 °C, about 50 °C, about 60 °C, about 80 °C, about 100 °C, about 120 °C, about 140 °C, about 160 °C, about 180 °C, about 200 °C, about 220 °C, about 240°C, about 260 °C, about 280 °C, about 285 °C, about 290 °C, about 295 °C, about 300 °C, about 305 °C, about 310 °C, about 315 °C, about 320 °C, about 325 °C, about 330 °C, about 335 °C, about 340 °C, about 345 °C, about 350 °C, about 355 °C, about 360 °C, about 365°C, about 370 °C, about 375 °C, about 380 °C, about 385 °C, about 390 °C, about 395 °C, about 400 °C, about 405 °C, about 410 °C, about 415 °C, about 420 °C, about 425 °C, about 430 °C, about 435 °C, about 440 °C, about 445 °C, about 450 °C, about 455 °C, about 460 °C, about 480 °C, about 500 °C. It is preferred for CMOS compatibility to keep this temperature below 400 °C, certainly a hard stop at about 500 °C. The nominal deposition temperature includes the set point and/or initial/beginning temperature of the deposition machine or device substrate. The deposition machine or device substrate may warm somewhat during the deposition process. For some machines this may only be about 5 °C or 10 °C.

The sacrificial diffusion/catalyst layer deposition may be performed in vacuum pressures from about 10⁻⁷ torr to about 8×10² torr, or at about atmospheric (760 torr, about 1 bar, 1 atm) depending on which step is being performed at the time and processing/engineering considerations and details, as well as what type of deposition machine is being utilized. For example, the carbon source deposition may be performed in vacuum pressures at about 10⁻⁷ torr, about 5×10⁻⁷ torr, about 10⁻⁶ torr, about 5×10⁻⁶ torr, about 10⁻⁵ torr, about 5×10⁻⁵ torr, about 10⁻⁴ torr, about 3×10⁻⁴ torr, about 5×10⁻⁴ torr, about 8×10⁻⁴ torr, about 10⁻³ torr, about 3×10⁻³ torr, about 5×10⁻³ torr, about 8×10⁻³ torr, about 10⁻² torr, about 3×10⁻² torr, about 5×10⁻² torr, about 8×10⁻² torr, about 10⁻¹ torr, about 3×10⁻¹ torr, about 5×10⁻¹ torr, about 8×10⁻¹ torr, about 1 torr, about 3 torr, about 5 torr, about 8 torr, about 101 torr, about 3×10¹ torr, about 5×10¹ torr, about 8×10¹ torr, about 10² torr, about 3×10² torr, about 5×10² torr, about 8×10² torr, or about 10³ torr. In some implementations, a preferred vacuum pressure for the sacrificial diffusion layer deposition is the nominal lowest base pressure achieved by the specific equipment used: generally, for example, about 10⁻⁷ torr to 10⁻⁶ torr.

The sacrificial diffusion/catalyst deposition may be performed at deposition rates of about 10-2 Angstroms/second to about 102 Angstroms/second depending on production, engineering, Ni grain size, adhesion, and economic considerations. In some implementations, a preferred Ni dep rate is about 1 Angstrom/second.
430 The sacrificial diffusion/catalyst layer may now be annealed. This anneal may be performed for engineering and operational considerations; for example, such as, to improve adhesion to the dielectric layer, relive thin film stress and control the value, create the proper grain size for controlling the vertical and horizontal graphene formation/synthesis rates, and so on. This anneal may also be skipped.
435 The anneal may be performed in a process chamber or a separate anneal chamber. The anneal ambient may include for example, such as, vacuum (10¹ torr to 10⁻⁸ torr), Ar, H2, N2, or forming gas, or any combination of these. The gaseous anneal pressure in the anneal chamber or process chamber may be between about 10⁻⁸ torr and about 1000 psi (approx. 52,000 torr). Vacuum is the preferred anneal ambient to keep the substrate clean. If Nickel is used for the sacrificial diffusion layer, it is well known to very quickly absorb many different gases if given a chance. This anneal may be performed in the same machine as the previous deposition, which is called an in-situ anneal; and/or this anneal may be performed in a machine/equipment other than the deposition equipment used for the sacrificial diffusion layer deposition. This is called an ex-situ anneal.

The gaseous anneal pressure in the anneal chamber or process chamber may include about 10⁻⁸ torr, about 5×10⁻⁸ torr, about 10⁻⁷ torr, about 5×10⁻⁷ torr, about 10⁻⁶ torr, about 5×10⁻⁶ torr, about 10⁻⁵ torr, about 5×10⁻⁵ torr, about 10⁻⁴ torr, about 3×10⁻⁴ torr, about 5×10⁻⁴ torr, about 8×10⁴ torr, about 10⁻³ torr, about 3×10⁻³ torr, about 5×10⁻³ torr, about 8×10⁻³ torr, about 10⁻² torr, about 3×10⁻² torr, about 5×10⁻² torr, about 8×10⁻² torr, about 10⁻¹ torr, about 3×10⁻¹ torr, about 5×10⁻¹ torr, about 8×10⁻¹ torr, about 1 torr, about 3 torr, about 5 torr, about 8 torr, about 10¹ torr, about 3×10¹ torr, about 5×10¹ torr, about 8×10¹ torr, about 10² torr, about 3×10² torr, about 5×10² torr, about 8×10² torr, about 10³ torr, about 3×10³ torr, about 5×10³ torr, about 8×10³ torr, about 10⁴ torr, about 2×10⁴ torr, about 3×10⁴ torr, about 4×10⁴ torr, or about 5×10⁴ torr. Note, any pressures above 1 atm, the anneal chamber must be configured and adapted to contain the high pressure safely. Please see incorporated by reference U.S. application Ser. No. 19/221,427 and U.S. Pat. No. 12,368,061.

The anneal temperature may be between 20 °C and 500 °C. The nominal anneal temperature may range from about 20 °C to about 500 °C. For example, the anneal temperature may be about 20 °C, about 30 °C, about 40 °C, about 50 °C, about 60 °C, about 80 °C, about 100 °C, about 120 °C, about 140 °C, about 160 °C, about 180 °C, about 200 °C, about 220 °C, about 240 °C, about 260 °C, about 280 °C, about 285 °C, about 290 °C, about 295 °C, about 300 °C, about 305 °C, about 310 °C, about 315 °C, about 320 °C, about 325 °C, about 330 °C, about 335 °C, about 340 °C, about 345 °C, about 350 °C, about 355 °C, about 360 °C, about 365 °C, about 370 °C, about 375 °C, about 380 °C, about 385 °C, about 390 °C, about 395 °C, about 400 °C, about 405 °C, about 410 °C, about 415 °C, about 420 °C, about 425 °C, about 430 °C, about 435 °C, about 440 °C, about 445 °C, about 450 °C, about 455 °C, about 460 °C, about 480 °C, about 500 °C. It is preferred for CMOS compatibility to keep this temperature below 400 °C, certainly a hard stop at about 500 °C.

The anneal time may be 0 minutes (skipped or done after the carbon source deposition later in the process flow) or up to 24 hours, depending on the engineering and production issues identified previously herein. The anneal time may include about 0 minutes, about 5 minutes, about 10 minutes, about 15 minutes, about 20 minutes, about 25 minutes, about 30 minutes, about 40 minutes, about 45 minutes, about 50 minutes, about 60 minutes, about 1.2 hours, about 1.4 hours, about 1.6 hours, about 1.8 hours, about 2 hours, about 2.2 hours, about 2.4 hours, about 2.6 hours, about 2.8 hours, about 3 hours, about 3.2 hours, about 3.4 hours, about 3.6 hours, about 3.8 hours, about 4 hours, about 4.2 hours, about 4.4 hours, about 4.6 hours, about 4.8 hours, about 5 hours, about 5.5 hours, about 6.0 hours, about 6.5 hours, about 7.0 hours, about 7.5 hours, about 8 hours, about 8.5 hours, about 9.0 hours, about 9.5 hours, about 10.0 hours, about 10.5 hours, about 11.0 hours, about 11.5 hours, about 12.0 hours, about 12.5 hours, about 13.0 hours, about 13.5 hours, about 14.0 hours, about 14.5 hours, about 15.0 hours, about 15.5 hours, about 16.0 hours, about 16.5 hours, about 17.0 hours, about 17.5 hours, about 18.0 hours, about 18.5 hours, about 19.0 hours, about 19.5 hours, about 20.0 hours, about 20.5 hours, about 21.0 hours, about 21.5 hours, about 22.0 hours, about 22.5 hours, about 23.0 hours, about 23.5 hours, or about 24.0 hours.

In some implementations, it is preferred to not break vacuum to now deposit the carbon source material on top of the sacrificial diffusion layer. The carbon source material in this exemplary process flow is amorphous carbon, but as described elsewhere herein and in the incorporated by reference documents, there are alternatives for the phase and type of carbon source material.
440 Then the substrate may be kept under vacuum in a deposition machine, for example, such as a vacuum evaporator, and then the carbon source layer may be deposited.

This may be a sputtered or E-beam evaporated carbon from a solid source, for example, such as a carbon pellet/target, and may be deposited to a thickness between about 2 nm to about 500 nm. Carbon source layer thicknesses may be about 2 nm, about 3 nm, about 4 nm, about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 100 nm, about 150 nm, about 200 nm, about 250 nm, about 300 nm, about 350 nm, about 400 nm, about 450 nm, or about 500 nm. In some implementations, a preferred thickness is about 50 to 70 nm. This carbon source thickness can be related to the number of distinct graphene layers formed during the later formation/synthesis process: the MLG will be thicker and have more numerous graphene layers formed as the thicker a carbon source is deposited, and thinner and less numbers of distinct graphene layers in the resultant MLG formed if a thinner carbon source is utilized in the preparatory substrate stack, given a similar formation/synthesis temperature, pressure, and/or time at temperature. For example, about a 10 nm carbon source may produce about 10-40 distinct graphene layers after the formation/synthesis processing. This relationship will vary quite significantly depending on conditions and specific materials used in the processing.

In some implementations, the thickness of the carbon source layer is configured to be greater than an amount by which the carbon source layer will be consumed by the subsequent graphene formation/synthesis step. That is, the thickness of the carbon source layer is configured to provide sufficient carbon for the entirety of the graphene synthesis processing step, such that an excess amount of the carbon source layer remains after the graphene synthesis processing step is complete. In this manner, graphene formation is not limited by the amount of carbon present in the carbon source layer. By way of example without limitation, in some implementations, the thickness of the carbon source layer is configured so that approximately 5 to 10 nm of the carbon source layer remains after the graphene formation/synthesis processing step is performed.

The temperature of the device substrate during the carbon source deposition may range from about 20 °C to about 500 °C. This temperature is commonly measured with a thermocouple placed directly behind the device substrate when inside the deposition chamber. For example, the carbon source layer deposition temperature may be about 20 °C, about 25 °C, about 30 °C, about 40 °C, about 50 °C, about 60 °C, about 80 °C, about 100 °C, about 120 °C, about 140 °C, about 160 °C, about 180 °C, about 200 °C, about 220 °C, about 240 °C, about 260 °C, about 280 °C, about 285 °C, about 290 °C, about 295 °C, about 300 °C, about 305 °C, about 310 °C, about 315 °C, about 320 °C, about 325 °C, about 330 °C, about 335 °C, about 340 °C, about 345 °C, about 350 °C, about 355 °C, about 360 °C, about 365 °C, about 370 °C, about 375 °C, about 380 °C, about 385 °C, about 390 °C, about 395 °C, about 400 °C, about 405 °C, about 410 °C, about 415 °C, about 420 °C, about 425 °C, about 430 °C, about 435 °C, about 440 °C, about 445°C, about 450 °C, about 455 °C, about 460 °C, about 480 °C, about 500 °C. It is preferred for CMOS compatibility to keep this temperature below 400 °C, certainly a hard stop at about 500 °C. In some implementations, a preferred carbon source deposition temperature may be about 25 °C. The nominal deposition temperature includes the set point and/or initial/beginning temperature of the deposition machine or device substrate. The deposition machine or device substrate may warm somewhat during the deposition process. For some machines this may only be about 5 °C or 10 °C.

The carbon source deposition may be performed in vacuum pressures from about 10⁻⁷ torr to about 8×10² torr, or at about atmospheric (760 torr, about 1 bar, 1 atm) depending on which step is being performed at the time, equipment utilized (sputter vs evaporator, VS APCVD vs LPCVD vs PECVD), and processing/engineering considerations and details. For example, the carbon source layer deposition may be performed in vacuum pressures at about 10⁻⁷ torr, about 5×10⁻⁷ torr, about 10⁻⁶ torr, about 5×10⁻⁶ torr, about 10⁻⁵ torr, about 5×10⁻⁵ torr, about 10⁻⁴ torr, about 3×10⁻⁴ torr, about 5×10⁻⁴ torr, about 8×10⁻⁴ torr, about 10⁻³ torr, about 3×10⁻³ torr, about 5×10⁻³ torr, about 8×10⁻³ torr, about 10⁻² torr, about 3×10⁻² torr, about 5×10⁻² torr, about 8×10⁻² torr, about 10⁻¹ torr, about 3−10⁻¹ torr, about 5×10⁻¹ torr, about 8×10⁻¹ torr, about 1 torr, about 3 torr, about 5 torr, about 8 torr, about 10¹ torr, about 3×10¹ torr, about 5×10¹ torr, about 8×10¹ torr, about 10² torr, about 3×10² torr, about 5×10² torr, about 8×10² torr, or about 10³ torr.

The carbon source layer deposition may be performed at deposition rates of about 10⁻² Angstroms/second to about 10² Angstroms/second depending on production, engineering, chamber heating, adhesion, thin film stress, and economic considerations. In some implementations, a preferred C dep rate is about 1 Angstroms/second. The carbon source layer may be deposited atop the sacrificial diffusion layer, which is atop the device substrate.
445 The now prepared substrate, a device substrate with at least a sacrificial diffusion layer and a carbon source layer, may be annealed. This anneal may be performed for engineering and operational considerations; for example, such as, to improve adhesion to the dielectric layer, relieve thin film stress and control the value of both films, create the proper diffusion/catalyst grain size for controlling the vertical and horizontal graphene formation/synthesis rates, and so on. The anneal step may be skipped.
450 The anneal may be performed in a process chamber or a separate anneal chamber. The anneal ambient may include; for example, an ambient such as, vacuum (101 torr to 10-8 torr), Ar, H2, N2, or forming gas, or any combination of these. The gaseous anneal pressure in the anneal chamber or process chamber may be between about 10-8 torr and about 1000 psi (approx 52,000 torr). In some implementations, vacuum is the preferred anneal ambient to keep the substrate clean. If Nickel is used for the sacrificial diffusion layer, it is well known to absorb many different gases very quickly if given a chance; however, at this step, it may be covered enough by the carbon source layer, depending on C density and thickness, to mitigate this Ni contamination process. This anneal may be performed in the same machine as the previous (carbon source layer) deposition, which is called an in-situ anneal; and/or this anneal may be performed in a machine/equipment other than the deposition equipment used for the sacrificial diffusion layer deposition. This is called an ex-situ anneal.

The gaseous anneal pressure in the anneal chamber or process chamber may include about 10⁻⁸ torr, about 5×10⁻⁸ torr, about 10⁻⁷ torr, about 5×10⁻⁷ torr, about 10⁻⁶ torr, about 5×10⁻⁶ torr, about 10⁻⁵ torr, about 5×10⁻⁵ torr, about 10⁻⁴ torr, about 3×10⁻⁴ torr, about 5×10⁻⁴ torr, about 8×10⁻⁴ torr, about 10⁻³ torr, about 3×10⁻³ torr, about 5×10⁻³ torr, about 8×10⁻³ torr, about 10⁻² torr, about 3×10⁻² torr, about 5×10⁻² torr, about 8×10⁻² torr, about 10⁻¹ torr, about 3×10⁻¹ torr, about 5×10⁻¹ torr, about 8×10⁻¹ torr, about 1 torr, about 3 torr, about 5 torr, about 8 torr, about 10¹ torr, about 3×10¹ torr, about 5×10¹ torr, about 8×10¹ torr, about 10² torr, about 3×10² torr, about 5×10² torr, about 8×10² torr, about 10³ torr, about 3×10³ torr, about 5×10³ torr, about 8×10³ torr, about 10⁴ torr, about 2×10⁴ torr, about 3×10⁴ torr, about 4×10⁴ torr, or about 5×10⁴ torr. Note, any pressures above 1 atm, the anneal chamber must be configured and adapted to contain the high pressure safely. Please see incorporated by reference U.S. application Ser. No. 19/221,427 and U.S. Pat. No. 12,368,061.

The anneal temperature may be between 20 °C and 500 °C. The nominal anneal temperature may range from about 20 °C to about 500 °C. For example, the anneal temperature may be about 20 °C, about 30 °C, about 40 °C, about 50 °C, about 60 °C, about 80 °C, about 100 °C, about 120 °C, about 140 °C, about 160 °C, about 180 °C, about 200 °C, about 220 °C, about 240 °C, about 260 °C, about 280 °C, about 285 °C, about 290 °C, about 295 °C, about 300 °C, about 305 °C, about 310 °C, about 315 °C, about 320 °C, about 325 °C, about 330 °C, about 335 °C, about 340 °C, about 345 °C, about 350 °C, about 355 °C, about 360 °C, about 365 °C, about 370 °C, about 375 °C, about 380 °C, about 385 °C, about 390 °C, about 395 °C, about 400 °C, about 405 °C, about 410 °C, about 415 °C, about 420 °C, about 425 °C, about 430 °C, about 435 °C, about 440 °C, about 445 °C, about 450 °C, about 455 °C, about 460 °C, about 480 °C, about 500 °C. It is preferred for CMOS compatibility to keep this temperature below 400 °C, certainly a hard stop at about 500 °C.

The anneal time may be 0 minutes or up to 24 hours, depending on the engineering and production issues identified previously herein. The anneal time may include about 0 minutes, about 5 minutes, about 10 minutes, about 15 minutes, about 20 minutes, about 25 minutes, about 30 minutes, about 40 minutes, about 45 minutes, about 50 minutes, about 60 minutes, about 1.2 hours, about 1.4 hours, about 1.6 hours, about 1.8 hours, about 2 hours, about 2.2 hours, about 2.4 hours, about 2.6 hours, about 2.8 hours, about 3 hours, about 3.2 hours, about 3.4 hours, about 3.6 hours, about 3.8 hours, about 4 hours, about 4.2 hours, about 4.4 hours, about 4.6 hours, about 4.8 hours, about 5 hours, about 5.5 hours, about 6.0 hours, about 6.5 hours, about 7.0 hours, about 7.5 hours, about 8 hours, about 8.5 hours, about 9.0 hours, about 9.5 hours, about 10.0 hours, about 10.5 hours, about 11.0 hours, about 11.5 hours, about 12.0 hours, about 12.5 hours, about 13.0 hours, about 13.5 hours, about 14.0 hours, about 14.5 hours, about 15.0 hours, about 15.5 hours, about 16.0 hours, about 16.5 hours, about 17.0 hours, about 17.5 hours, about 18.0 hours, about 18.5 hours, about 19.0 hours, about 19.5 hours, about 20.0 hours, about 20.5 hours, about 21.0 hours, about 21.5 hours, about 22.0 hours, about 22.5 hours, about 23.0 hours, about 23.5 hours, or about 24.0 hours.

In some implementations, it is preferred to not break vacuum to now perform the graphene (or ‘MLG’) formation/synthesis processing. Accordingly, following the anneal, then the prepared device substrate may be kept under vacuum in transition to a formation/synthesis chamber, or quickly, preferred less than 5 minutes, transition to a separate formation/synthesis machine. A FOUP may be utilized, best with a dry non-oxygen containing purge active. This exemplary process flow utilizes a stand-alone formation/synthesis machine to take the prepared device substrate and form/synthesize MLG at the interface between the dielectric/oxide top surface and the bottom of the sacrificial diffusion layer. Again, if Ni is used as the sacrificial diffusion layer, it is best to keep the prepared device substrate in a vacuum, due to the extreme absorbance sensitivity of Ni to most gas species.
455 If a dummy substrate is required, perform the following steps. If not, skip to ‘Load the prepared device substrate’ step 460. It is preferred not to use a dummy substrate but may be necessary for uniformity concerns depending on the equipment and specific details, such as wafer/substrate diameter, and so on.

A dummy cleaning protocol may include: Rinse the dummy substrate with deionized (DI) water to remove surface contaminants and visible particles. Subject the dummy substrate to a dehydration bake at 150 °C for 3 minutes. Place the dummy substrate in an RIE system and perform Ar, oxygen, or combination gas plasma surface cleaning for about 1 to 2 minutes.

The graphene formation/synthesis machine utilized in this example can be a GT300 built by Destination 2D Inc. Machine details are in at least U.S. Patents 11,976,369, 12,286,710, 12,281,388, the disclosures of which are incorporated by reference herein. Note: The carbon source deposition machine and the graphene formation machine may be within the same piece of equipment.
460 Purge the system chamber and load lock with argon or nitrogen for at least 60 seconds. Heat bottom and top platens/pedestals to degas temperature setpoint(s). An in-situ degas bake may be performed or not depending on device substrate and/or dummy wafer conditions at this step, and other engineering considerations. It is important to not have ‘competing’processes occurring during the graphene/MLG formation/synthesis step.

The substrate degas temperature may range from 100 °C to 350 °C, preferably 250 °C. The degas time may vary from about 0 minutes to about 120 minutes, depending on the cleanliness of the prepared device substrate(s) and type of transfer to the graphene formation machine. For example, the degas temperature may include about 100 °C, about 120 °C, about 140 °C, about 150 °C, about 170 °C, about 180 °C, about 200 °C, about 220 °C, about 240 °C, about 250 °C, about 260 °C, about 280 °C, about 300 °C, about 310 °C, about 320 °C, about 330 °C, about 340 °C, or about 350 °C. The degas time may include about 0 minutes (skipped), or about 5 minutes, or about 20 minutes, or about 30 minutes, or about 40 minutes, or about 50 minutes, or about 60 minutes, or about 70 minutes, or about 80 minutes, or about 90 minutes, or about 100 minutes, or about 110 minutes, or about 120 minutes. The degas pressure in the process chamber may be from may include about 10-8 torr, about 5×10⁻⁸ torr, about 10⁻⁷ torr, about 5×10⁻⁷ torr, about 10⁻⁶ torr, about 5×10⁻⁶ torr, about 10⁻⁵ torr, about 5×10⁻⁵ torr, about 10⁻⁴ torr, about 3×10⁻⁴ torr, about 5×10⁻⁴ torr, about 8×10⁻⁴ torr, about 10⁻³ torr, about 3×10⁻³ torr, about 5×10⁻³ torr, about 8×10⁻³ torr, about 10⁻² torr, about 3×10⁻² torr, about 5×10⁻² torr, about 8×10⁻² torr, about 10⁻¹ torr, about 3×10⁻¹ torr, about 5×10⁻¹ torr, about 8×10⁻¹ torr, about 1 torr, about 3 torr, about 5 torr, about 8 torr, about 10¹ torr, about 3×10¹ torr, about 5×10¹ torr, about 8×10¹ torr, about 10² torr, about 3×10² torr, about 5×10² torr, or about 8×10² torr. The anneal ambient may include; for example, such as, vacuum (10³ torr to 10⁻⁸ torr), Ar, H2, N2, or forming gas, or any combination of these.

Load the prepared device substrate (and the dummy substrate, if chosen, on top of the device substrate) into the load lock vacuum chamber and pump down to at least 10⁻² torr. Equalize pressures between the load lock chamber and the process chamber.

Transfer the device substrate/dummy wafer-if applicable into the process chamber and degas bake the prepared device substrate as described previously herein. The degas time will of course be set depending on the condition of the prepared device substrate (and dummy substrate if needed). The pump may be at max output and set to achieve the base pressure or within a decade of the nominal base pressure. This step may be skipped, depending on the condition of the prepared device substrate, as well as the condition of the substrate backside and edges. The top heated platen position may be at least 5 mm or more away from the top of the prepared device substrate (or the back of the dummy wafer placed face-down on top of the prepared device substrate), so that it is essentially having little effect on the substrate(s).
465 After the optional degas bake, heat the bottom and top heated platens to the formation/synthesis process temperature, which may be about 20 °C to about 500 °C, depending on many engineering and scientific factors and considerations. For example, the formation/synthesis process temperature may be about 20 °C, about 30 °C, about 40 °C, about 50 °C, about 60 °C, about 80 °C, about 100 °C, about 120 °C, about 140 °C, about 160 °C, about 180 °C, about 200 °C, about 220 °C, about 240 °C, about 260 °C, about 280 °C, about 285 °C, about 290 °C, about 295 °C, about 300 °C, about 305 °C, about 310 °C, about 315 °C, about 320 °C, about 325 °C, about 330 °C, about 335 °C, about 340 °C, about 345 °C, about 350 °C, about 355 °C, about 360 °C, about 365 °C, about 370 °C, about 375 °C, about 380 °C, about 385 °C, about 390 °C, about 395 °C, about 400 °C, about 405 °C, about 410 °C, about 415 °C, about 420 °C, about 425 °C, about 430 °C, about 435 °C, about 440 °C, about 445°C, about 450 °C, about 455 °C, about 460 °C, about 480 °C, about 500 °C. It is preferred for CMOS compatibility to keep this temperature below 400 °C, certainly a hard stop at about 500 °C. The preferred formation temperature may be about 350-400 °C but depends greatly on machine characteristics and surface preparation. The top heated platen and the bottom heated platen may be set to different temperatures, to encourage the MLG formation.

The top heater platen position may now be moved to be about 1 to 5 mm away from the top of the device prepared wafer (or the back of the dummy wafer placed face-down on top of the prepared device substrate), so that it is now having an effect on the device substrate(s), which may include thermal radiation effects. The top heater platen position may be about 0.5 mm away, about 1.0 mm away, about 1.5 mm away, about 2.0 mm away, about 2.5 mm away, about 3.0 mm away, about 3.5 mm away, about 4.0 mm away, about 4.5 mm away, about 5.0 mm away, or farther, depending on equipment design and process considerations, and the platen temperature. The bottom and top heater platens may be designed to provide a consistent distance in some implementations.

Process for 1-60 minutes, depending on engineering and scientific factors and considerations, in addition to the specific structure of the prepared device wafer. The graphene formation/synthesis process time may be about 0 minutes, about 1 minute, about 5 minutes, about 8 minutes, about 10 minutes, about 15 minutes, about 20 minutes, about 25 minutes, about 30 minutes, about 40 minutes, about 50 minutes, or about 60 minutes, or more, depending on engineering or production considerations and thickness requirements. The top heated platen position may be 0 mm (touching), about 0.1 mm, about 0.2 mm, about 0.3 mm, about 0.4 mm, about 0.5 mm, about 0.6 mm, about 0.7 mm, about 0.8 mm, about 0.9 mm, about 1.0 mm, about 1.2 mm, about 1.4 mm, about 1.6 mm, about 1.8 mm, about 2.0 mm, or greater, from the top of the prepared device substrate (or the back of the dummy wafer placed face-down on top of the prepared device substrate), such that the heat from the top heated platen, which may include thermal radiation effects, affects the C solid-state diffusion from the carbon source layer thru the sacrificial diffusion layer and the Ni dewetting phenomena. When slightly touching, the mechanical pressure control system may indicate a pressure of 0, 5, 10, 15 psi, or negative values. When touching, a mechanical pressure of 0 -1000 bar may be applied to the prepared device substrate to accelerate the formation of the MLG in a greater manner than merely using temperature acceleration depending on whether the synthesis or dewetting mechanism is dominating the MLG formation. In some implementations, the chamber pressure is generally the equipment base vacuum pressure; for example, such as about 10⁻⁸ torr, about 5×10⁻⁸ torr, about 10⁻⁷ torr, about 5×10⁻⁷ torr, about 10⁻⁶ torr, about 5×10⁻⁶ torr, or about 1×10⁻⁵ torr.

Note: the set point temperatures for top and bottom heated platens may be equal or intentionally set to differing temperatures, to precisely control the C solid-state diffusion from the carbon source layer through the sacrificial diffusion layer as well as the Ni dewetting preference.

It will be appreciated that if the top heated platen is moved far enough away from the top of the prepared substrate, such as, for example, about 200 mm, or does not even exist, then, when under a vacuum the top of the prepared substrate may suffer radiative loss of heat. If the bottom platen is set at, for example, 400 °C, which for Aluminum results in a heat flux of about 10,000 W/m² , then the top of the prepared substrate would predominantly only suffer a radiative loss in vacuum (IR due to vacuum) of about 0.1 °C using the Stefan-Boltzmann Law and the prepared substrate material characteristics such as emissivity, etc. A larger temperature drop can happen at the Aluminum-Silicon interface, the backside of the prepared substrate where there is not a direct material contact substrate to the Aluminum bottom platen/heating device. As surfaces only touch at microscopic peaks due to surface roughness, contact conductance and the heat transfer in vacuum is important. For a substrate/wafer simply “sitting” on a chuck, being held down only by gravity, in equilibrium the temperature at the top of the prepared substrate will be less than the nominal temperature of the heated chuck, for example, in the case of the chuck heated to 400 °C, the temperature at the top of the prepared substrate may be only about 350 °C.

If an Aluminum disk, such as a top platen, is now placed above the prepared substrate, even if unheated such will act as a radiation shield, reflecting the IR being emitted from the prepared substrate and the bottom heated platen, thus bringing the temperature of the top of the prepared substrate up, for example, to about 396 °C in the present example. Without the upper heated platen in place, the prepared wafer is emitting about 10,000 W/m² . The reflection of the IR is about 90%, and thus the prepared substrate nearly reaches the target 400 °C. If the top heated platen is heated to 400 °C, the exemplary target prepared substrate temperature will be 400 °C, since the prepared substrate is between two heat sources at 400 °C. Kinetic calculations show that the thermal equilibrium is obtained within about 50 mS, as most of the materials in this system are quite thermally conductive. Calculations show that the top heated platen, when within about 30 mm or less from the top of the prepared substrate, an estimated about 1,100 W/m² of heat needs to be either reflected or supplied by the top platen. This would approximately maintain the 400 °C prepared substrate temperature when in equilibrium. Thus, the range of heat needed to be supplied by the top platen at a reasonable distance is about 300 W/m 2 to about 1,000W/m 2 . This topside heat may be supplied, for example, by lamps of various frequencies, IR emissive materials when heated and/or electrified, pre-heated gasses, and so on.

After the graphene formation/synthesis process time is complete, the top heated platen heater may be turned off and immediately raised to at least 5 mm away from the processed prepared device substrate. The processed prepared device substrate may then be lifted off the bottom heated platen using lifter pins, to stop the graphene formation/synthesis processes and start the processed device substrate cooling process. The bottom heated platen heater may or may not be powered off, depending on the cooling rate control desired, and may be partially powered for a controlled cool-down of the processed device wafer. The top heated platen heater may or may not be powered off, depending on the cooling rate control desired, and may be partially powered for a controlled cool-down of the processed device wafer.
470 The processed device substrate is now controllably cooled. This cooling process may be controlled in various ways: for example, such as purging with high flow nitrogen or helium, cooling water platen in the load lock, partially heating and changing that heat amount over time of either or both the top heated platen and bottom heated platen, etc. The cooling rate may be from 3 °C/minute to about °30 C/minute, in some implementations, preferably about 20 °C/minute. The cooling rate may include about 3 °C/minute, about 4 C/minute, about 5 °C/minute, about 6 °C/minute, about 7 °C/minute, about 8 °C/minute, about 9 °C/minute, about 10 °C/minute, about 11 C/minute, about 12 C/minute, about 13 °C/minute, about 14 °C/minute, about 15 °C/minute, about 16 C/minute, about 17 °C/minute, about 18 C/minute, about 19 °C/minute, about 20 C/minute, about 21 °C/minute, about 22 °C/minute, about 23 °C/minute, about 24 C/minute, about 25 °C/minute, about 26 °C/minute, about 27 °C/minute, about 28 C/minute, about 29 °C/minute, or about 30 C/minute.

Close all vacuum valves, transfer the processed device substrate to the load lock (if it has not been already), and bring the load lock pressure to atmosphere before opening the load lock and unloading the processed device substrate (and dummy substrate if utilized). The dummy substrate may include monocrystalline silicon, glass, graphite, or quartz or some combination thereof.
475 The unused (leftover) carbon of the carbon source layer may be removed. An oxygen plasma may be used as well as wet chemistry methods, for example, such as hydrogen peroxide, and so on. An RIE O2 or Ar plasma at 200 W and about 300 mtorr for example, may be employed, and generally for short times; such as, for example, about 5 sec, about 10 sec, about 15 sec, about 20 sec, about 25 sec, about 30 sec, or about 45 sec, depending on thickness and form of carbon being removed.

The unused (leftover) carbon of the carbon source layer may alternatively be removed by exposing the substrate surface to an oxygen-containing gas at elevated temperatures. This may be done at above atmospheric pressures, at about atmospheric pressure, or sub-atmospheric pressures, and may use both substrate temperature and partial pressure oxygen containing gases to adjust carbon oxidation rate and minimize sacrificial catalyst (e.g. Ni) oxidation.

Then the sacrificial diffusion layer may be removed, preferably utilizing a chemistry which does not significantly etch the graphene below. For example, if Ni is utilized for the sacrificial diffusion layer, a 1:60 FeCl3 solution to DI water etchant may be utilized to strip the Ni and not harm the formed MLG.

Standard semiconductor processing may ensue, to form subtractive-etched MLG interconnect lines, and so on, thus saving costs over the current dual damascene BEOL methodology.

Other configurations of the reactor that apply other forms of heat and pressure on the substrate are now discussed. It is noted that the aforementioned configuration is just one of many. Alternate configurations could include, inter alia:
Heated membrane subject to high pressure (either pneumatic or hydraulic for example);
Clamshell configurations with high temperature and high pressure heated N2, Ar, other such gases;
Large batch reactors with the same characteristics as discussed supra;
Clamshell in which combinations of the previously detailed approaches to heating and applying pressure to the substrates may be used. For example, high temperature and pressure gas could be fed in; high pressure could be fed in with the bottom heater being used to heat the substrate, bottom heater heats high temperature gas to accomplish the pressure function and maintain temperature, and so on;
Quartz body with substrate placed on a susceptor and inductively heated and pressure loading accomplished using high pressure gas; and
May also include an array of lamps in a quartz body for final temp control.

By way of example, the reactors outlined above facilitate the deposition of materials through diffusion couples, as in the use of deposition of graphene onto a silicon wafer across a nickel layer. The deposition method using diffusion couples can be applied to a wider range of deposition materials and diffusion materials.

The following sections provide certain ranges of operation for the system, as well as parameter ranges for desired material structures, composition, and the like for optimal process results.

As noted earlier the use of this method to permit migration of one material across a diffusion couple permits deposition of a material on substrate where it may previously not have been possible through other traditional deposition methods (e.g., graphene is difficult to grow directly on Si or SiO2). The systems described here facilitate the growth of graphene on Si/SiO2 by application of pressure and temperature on the carbon source deposited on a Ni layer that is in turn deposited on the Si wafer, etc.).

It is noted that the reactor can be implemented as a batch reactor and/or single substrate (wafer) reactor. It is noted that in general, single substrate configurations tend to provide finer substrate to substrate process control than batch reactors. A method of creating a batch process with a single wafer architecture can also be realized by employing a stack of wafers between the two heaters.

### Prepared Substrate Types

FIGS. 5A, 5B, and 5C illustrate the three types of prepared substrates: source-up 508, source-down 528, and dual-source 538, respectively. The source-up prepared substrate 508 includes a device substrate/wafer 500, a sacrificial catalyst layer 510, and a carbon source layer 514. The source-down prepared substrate 528 includes a device substrate/wafer 500, a sacrificial catalyst layer 520, and a carbon source layer 524. The dual-source prepared substrate 538 includes a device substrate/wafer 500, a sacrificial catalyst layer 530, a first carbon source layer 534, and a second carbon source layer 536. These illustrations show the layer-by-layer structures and the order of deposition for each configuration. All three configurations support graphene synthesis via the processes described in this application, with different process windows and potential graphene quality characteristics.

### Examples Of Defect And Porosity Engineering In Single-, Few-, nd Multilayer-Graphene

Graphene is a two-dimensional (2D) material composed of a single layer (a.k. a monolayer or 1L) of carbon atoms arranged in a hexagonal lattice, connected via sp2 hybridized covalent bonds, making it exceptionally thin and strong, while also being flexible, transparent, and an excellent conductor of electricity and heat. Few-layer (FL) and multilayer (ML) graphene (MLG) also exhibit excellent properties along with ultra-thinness, flexibility, and mechanical strength.

Pristine or “defect-free” graphene is theoretically impermeable to most elements and molecules, in gaseous or liquid form, including even small molecules such as, for example, helium. This is due to the strong sp2 hybridization of carbon atoms and the high energy barriers required for atoms or molecules to pass through the 2D hexagonal mesh. The only exception is protons (or hydrogen ions), which show some permeation. This imperviousness of graphene makes it an excellent coating material for a wide range of substrate materials (including metals and insulators) in many applications to prevent corrosion and/or prevent reactions with other chemical species.

However, 1L/FL or ML graphene are substantially never defect-free. This is particularly true for synthesized graphene that are necessary in practical applications that require large-area flakes/films. Such large area graphene films typically have many grains and therefore grain boundaries that can allow permeation. In addition, various other defects (including vacancies and pores) can significantly reduce the energy barriers for permeation, allowing certain molecules to pass through more easily. The size and shape of the permeating molecules, as well as the temperature and pressure conditions, can also influence graphene permeation rates.

Such imperfect 1L/FL/ML graphene with defects and pores can be intentionally created to enable and enhance a number of applications including bio/gas/chemical sensing, intercalation, filtration, catalysis, electronic property (including transport) tuning, and in energy storage applications including batteries, etc. These defects and pores can range from atomic vacancies to nanoscale holes, and their creation involves both top-down and bottom-up methods. Engineering of such defects and pores in 1L/FL/ML graphene films and coatings to control the rate and degree of permeation is crucial to realize or enhance many applications.

A variety of chemical, physical, and other methods, processes, and techniques are now described as embodiments to deliberately introduce such defects or defect-like structures, including pores and islands, in a well-regulated manner to control the type, form, rate, and chemistry of permeation through the 1L/FL/ML graphene films. These techniques are also applicable to other 2D materials including 2D semiconductors such as molybdenum-disulphide (MoS 2) and 2D insulators such as hexagonal boron nitride (h-BN).

### Chemical Methods

Plasma Treatment: For example, oxygen, argon, nitrogen, helium, hydrogen, carbon containing gases such as CF4, C2F6, etc., or a combination thereof, plasma treatment during or after graphene formation may introduce vacancies, holes, and functional groups. These can be tuned for pore size and defect density by adjusting time and power as well as the species or concentration of ionic species of the plasma.

Oxidation: Produces graphene oxide (GO) with various oxygen-containing functional groups and vacancies. Further reduction yields reduced graphene oxide (rGO), retaining structural defects and pores. This may be accomplished with high temperature (>500 C) or low temp (<500 C) processing.

Chemical Etching: Use of acidic (e.g., FeCl3, HNO₃, H₂SO₄) or oxidizing agents (e.g., KMnO₄, O₃) to introduce vacancies and nano-/micropores. This is generally done after graphene formation.

Electrochemical Etching and/or injection of defects: Controlled etching using a voltage bias in an electrolyte to create nanopores or defects. This technique may also be utilized in MLG to control which layers have defects/pores and what do not. This allows a fine tuning of total MLG permeability via engineering the vertical (thru the thickness of the MLG) defect distribution, population, and size.

Functionalization with Reactive Species: Covalent attachment of functional groups (e.g., amines, diazonium salts) disturbs the sp2 network, introducing point defects or vacancies. This may be accomplished via chemical and electrochemical processes.

### Physical Methods

Ion or Electron Beam Irradiation: Focused Ion Beam (FIB) or Electron Beam (e-beam) creates vacancies, divacancies, or nanopores with atomic precision. They enable patterning of regular arrays of defects. Ion implantation and PLAD processes may accomplish the same.

Thermal Annealing in Reactive Atmospheres: High-temperature treatment under H₂, NH₃, or Ar can promote vacancy formation or restructure existing defects.

Laser Ablation or Laser Irradiation: Pulsed or continuous lasers can drill nanopores or induce thermal decomposition to create defects.

Ball Milling/Mechanical Exfoliation: Mechanical processes introduce edge defects, vacancies, and disorder, especially in few-or multi-layer graphene.

### Bottom-Up and Template-Assisted Methods

Chemical Vapor Deposition (CVD) with Controlled Parameters: Adjusting gas ratios, temperature, and substrate conditions during CVD growth can create grain boundaries, point defects, or porosity. Use of metal templates or growth on nanostructured substrates can influence porosity.

Pressure-Assisted Solid-Phase Diffusion Enabled Graphene/MLG growth: Apart from pressure, temperature, and time, the thickness and microstructure of the metal catalyst (such as nickel or cobalt) aiding the diffusion and segregation of carbon through the catalyst film can be engineered to create and control the number and size of vacancies, pores, and/or islands formed in the grown graphene/MLG film.

The deposition method of the catalyst metal (sputtering, E-beam, thermal evaporation, etc.) and the carbon source (including amorphous carbon) film can also be judiciously exploited to create defects. Intentional gradient or non-uniformity in the microstructure of the catalyst metal can also be used to create and control the defects and pores. For example, the grain size of a nickel catalyst layer may be generally within a range of about 50 nm to about 100 nm, or within a range of about 100 nm to about 150 nm, or within a range of about 150 nm to about 200 nm, or within a range of about 200 nm to about 250 nm, or within a range of about 250 nm to about 300 nm, or within a range of about 300 nm to about 350 nm, or within a range of about 350 nm to about 400 nm, or within a range of about 400 nm to about 450 nm, or within a range of about 450 nm to about 500 nm, or within a range of about 500 nm to about 550 nm, or within a range of about 550 nm to about 600 nm, or within a range of about 600 nm to about 700 nm, or within a range of about 700 nm to about 800 nm, or within a range of about 800 nm to about 900 nm, or within a range of about 900 nm to about 1000 nm, or within a range of about 1000 nm to about 1500 nm, or within a range of about 1500 nm to about 2000 nm, or within a range of about 2000 nm to about 3000 nm, or about greater than 3000 nm, or about 2.54 cm, or within a range of about 50 nm to about 150 nm, or within a range of about 150 nm to about 300 nm, or within a range of about 300 nm to about 450 nm, or within a range of about 450 nm to about 600 nm. A catalyst layer may also be called or known herein as a sacrificial diffusion layer.

Moreover, the metal catalyst film and/or the carbon source film can be pre-patterned into any shape (including arrays of squares, rectangles, etc.) before the graphene/MLG growth via application of pressure and temperature. All of the above may be accomplished by changing the substrate/wafer stack of carbon source layer, and/or the catalyst layer, in the disclosed herein diffusion-couple synthesis method, which may be accelerated by temperature and pressure.

Template-Assisted Etching: Use of block copolymers, nanoparticles, or lithographic masks to define pore positions and sizes, followed by selective etching may introduce controlled defects and pores in the SLG, FLG, MLG material.

Self-Assembly of Porous Graphene Frameworks: Molecular self-assembly or bottom-up synthesis from designed organic precursors can yield graphene-like structures with inherent pores.

### Other Techniques

Lithography (e.g., Electron Beam Lithography): High-resolution patterning as well as lift-off and multiple patterning techniques may be utilized to define defect geometries or nanopores, especially in device applications.

Intercalation and Exfoliation: Intercalants can disrupt interlayer bonding in few-/multi-layer graphene and may leave defects or pores upon deliberate and engineered removal.

Strain Engineering: Mechanical stretching or bending can influence defect formation energetics, aiding selective vacancy generation.

Polishing: Mechanical Polishing (MP) or Chemical Mechanical Polishing (CMP) may be employed to create and control surface defects in a top layer of the 2D film.

A summary of types of defects and pores that can be engineered includes the following, for example: Vacancies-Missing single or multiple carbon atoms. Stone-Wales Defects-Bond rotations creating 5-7 rings. Grain Boundaries-Interface between graphene domains. Nanopores-Nanoscale holes (1-100 nm). Micropores-Larger pores (>100 nm). Edge Defects-Irregularities at graphene sheet boundaries. Substitutional Defects Replacement of C atoms with other atoms (e.g., N, B). Extra C atoms or functional groups

Defect effects on MLG film properties are summarized as follows. In-plane thermal conductivity (kip ~1500-2500 W/mK pristine) is reduced primarily by grain boundaries (inversely with grain size), vacancies (20-30% per 0.1% concentration), and porosity; out-of-plane conductivity (kop ~3-10 W/mK) is only modestly affected. In-plane CTE (alpha_ip ~-7 ppm/K pristine) shifts toward zero or positive as grain size decreases or vacancy density increases, reducing mismatch with adjacent substrates. Young's modulus (~1 TPa pristine in-plane) decreases with vacancies, grain boundary density, and porosity (Gibson-Ashby scaling). Adhesion to SiO2 (0.3-0.5 J/m2 pristine) increases substantially at vacancies, edges, and with polar substitutional dopants (N, O). Film stress, dielectric strength, optical properties, thermal boundary resistance, and substrate warpage are each tunable through the same defect parameters. The key design principle is that localized defect distributions (e.g., small pore arrays at 1-10% fill factor, grain-boundary-selective treatments) preserve in-plane thermal and electrical performance while enabling the desired interface or nucleation function; uniform bulk treatments distribute damage across the basal plane and trade proportionally more native performance.

### Defect-Engineering Techniques: Knobs and Effects on MLG

Various defect-engineering techniques are contemplated in relation to defect types and resultant film properties. Tunable parameters (materials, settings, and geometries), the defects those parameters produce, and the resulting shifts in film properties are described.

A low-temperature regime (at or below approximately 400-500 °C; BEOL/flexible/polymer stacks) is used when integrating over processed CMOS, on polymer or flexible substrates, or when growing graphene directly on Si/SiO₂ adjacent to temperature-sensitive layers. Compatible techniques include plasma treatment, ion and electron beam irradiation, laser ablation, electrochemical etching, wet chemical etching, lithographic patterning, ball milling, strain engineering, functionalization, template etching, self-assembly, and solid-phase diffusion enabled graphene growth.

A high-temperature regime (above 500 °C; standalone films, III-V overgrowth substrates, bulk wafers) is available when graphene is grown or processed before integration, when it sits on a refractory substrate (sapphire, SiC, or bare Si without processed devices), or when it serves as a buffer or release layer for high-temperature overgrowth such as GaN MOCVD at approximately 1000-1100 °C, AIN at approximately 1100-1200 °C, or thermal SiO₂ above 800 °C. In this regime, additional techniques become accessible: CVD at 900-1050 °C, thermal reduction of graphene oxide, reactive-atmosphere annealing at 800-1000 °C, ammonia doping, and higher-temperature solid-phase diffusion for closer-to-pristine film quality.

Solid-phase diffusion enabled graphene growth is attractive in both regimes: it can be run within the 400-500 °C BEOL window for direct growth on Si/SiO₂, or at higher temperature when the thermal budget is unconstrained and pristine-like film quality is desired.

The application of graphene as a substrate for semiconductor overgrowth is particularly described further below.

Plasma Treatment (O₂, Ar, N₂, H₂)

Low-pressure RF or inductively coupled plasma (ICP) bombards the MLG surface with a tunable mixture of reactive radicals, ions, and UV photons. Independent control parameters are gas chemistry, applied power, exposure time, chamber pressure, plasma configuration (direct vs. remote downstream), and substrate temperature.

Gas chemistry determines the dominant reaction pathway. Oxygen plasma etches the surface and introduces oxygen functional groups (hydroxyl, carbonyl, epoxy), creating vacancies, nanopores, and micropores depending on dose. Argon plasma (chemically inert) creates clean vacancies by sputtering. Nitrogen or ammonia plasma introduces substitutional nitrogen in pyridinic, pyrrolic, and graphitic configurations together with some vacancies. Hydrogen plasma preferentially etches edge and defect sites and terminates dangling bonds, making it suitable for opening pores from existing seed vacancies without introducing excessive oxygen.

Applied power (typically 5-200 W): below approximately 20 W, treatment predominantly functionalizes the surface; above approximately 100 W, it etches and perforates the film. Exposure time controls defect density roughly linearly at low doses, transitioning to a pore-growth regime at higher doses-seconds-scale exposures produce isolated vacancies; minute-scale exposures produce visible micropores. Lower chamber pressure increases ion mean free path, producing more directional, higher-energy impact that favors vacancies and sharper pore features; higher pressure promotes radical chemistry, tending to produce functionalization and rounder pores. The choice between direct plasma (aggressive, fast) and remote downstream plasma (gentler, suited to functionalization without perforation) provides additional control. Substrate temperature (25-200 °C, within the BEOL budget) affects the balance between etching and functionalization; in-situ annealing at elevated temperature during exposure can convert epoxy groups to ether-bridged vacancies.

Vacancies are the dominant defect produced, accompanied by substitutional nitrogen or oxygen, nanopores, and edge defects at pore rims; Stone-Wales defect density increases modestly as a byproduct of ion impact.

κ_ip decreases substantially with increasing dose; IR transmittance decreases; E_bd decreases markedly at higher doses as new leakage paths are created. Adhesion to SiO₂ increases because dangling bonds and polar groups bond to surface silanols. Nitrogen doping via N₂ or NH₃ plasma shifts the Fermi level, modulating ε_op and producing measurable Raman G-band changes that serve as diagnostic indicators.

Temperature regime: low (chuck 25-200 °C; bulk plasma temperature well below 500 °C). Plasma treatment plays a key enabling role for ALD of oxides and nitrides on graphene and for III-nitride MOCVD nucleation; see Application section.

### Oxidation (Graphene Oxide/Reduced Graphene Oxide)

Liquid-phase oxidation using the Hummers, modified Hummers, or Tour process converts graphene to graphene oxide (GO); subsequent reduction restores partial sp² character to give reduced graphene oxide (rGO). This technique is relevant to MLG films via post-growth oxidation of flakes or of the deposited film.

Oxidant chemistry strongly influences the degree of oxidation. Potassium permanganate combined with sulfuric acid (Hummers method) gives high oxygen content (approximately 50 at. %) and a heavy defect load. Modified Hummers with phosphoric acid gives lower sulfur residual content and cleaner basal planes. The Tour method (KMnO₄ with H₂SO₄ and H₃PO₄) gives the highest C/O ratio with fewer through-holes. Oxidation time and temperature provide further tunability. In-situ oxidation of a continuous CVD MLG film is much gentler than the solution-phase Hummers route, primarily introducing epoxy and hydroxyl groups at grain boundaries and on the top surface with minimal pore creation.

Reduction pathway determines rGO character. Chemical reduction (hydrazine, NaBH₄, HI, or ascorbic acid), photothermal, or flash reduction are preferred when the thermal budget requires staying below 500 °C. Thermal reduction at 600-1000 °C (when the budget permits) yields the cleanest rGO with the highest C/O ratio. Electrochemical reduction is a low-temperature, very clean option.

Defects produced: substitutional oxygen in epoxy, hydroxyl, carbonyl, and carboxyl configurations; vacancies; 1-5 nm nanopores; residual sp³ sites and small holes persist after reduction.

Chemical Etching (FeCl₃, HNO₃, H₂SO₄, KMnO₄, O₃)

Liquid-or vapor-phase acids and oxidants attack the MLG film preferentially at grain boundaries, edges, and existing defect sites. Independent parameters: etchant chemistry, concentration, temperature, and whether the basal plane is protected by a top passivation layer.

Ferric chloride (FeCl₃) is mild and preferentially enlarges existing vacancies while delaminating graphene from copper. Nitric acid (HNO₃) is more aggressive, adding carboxylic edge groups and etching preferentially at grain boundaries. Sulfuric acid combined with oxidants attacks basal planes. Potassium permanganate (KMnO₄) is aggressive and creates many new pores. Ozone is a clean vapor-phase etchant with preferential grain-boundary and edge attack. Dilute solutions and short exposures produce selective grain-boundary decoration and small nanopores; concentrated solutions and extended treatments produce micron-scale holes and loss of film continuity. Operating temperature (RT to approximately 100 °C) is within the BEOL budget. A thin top passivation layer (sputtered oxide or photoresist) can limit etching to defined windows and enable patterned pore arrays.

Defects produced: nanopores and micropores concentrated at grain boundaries and edges; edge-functionalized vacancies; substitutional oxygen.

Selective grain-boundary attack markedly decreases κ_ip (by increasing the functional grain-boundary density in the conducting area) and decreases E_bd due to new leakage pathways. Gas permeability increases substantially (desirable for membrane applications). E_ip decreases in proportion to porosity (Gibson-Ashby scaling), and film stress relaxes. See Application section for use as a self-aligned pore network for overgrowth nucleation.

### Electrochemical Etching

The MLG is biased as an electrode in an electrolyte, and oxidation or reduction at the graphene surface introduces controlled pores or functional groups. This approach offers high dose control and may be operated at room temperature throughout.

Electrolyte chemistry determines the dominant reaction pathway: acidic electrolytes (H₂SO₄, Na₂SO₄) favor pore opening via C-to-CO₂ oxidation; basic electrolytes (NaOH) provide milder hydroxylation; ionic liquids are another option. Voltage bias and waveform are primary knobs—DC sets a steady-state etching rate; pulsed bias (1-100 Hz, 1-5 V) gives finer control over pore size and density; higher voltage produces more and larger pores. Total charge transferred (time x current) scales essentially linearly with pore volume at low charge, providing quantitatively predictable dose control.

Defects produced: nanopores of uniform, bias-selectable size; substitutional oxygen; some edge defects; minimal bulk lattice damage.

High selectivity for pore placement means that decreases in κ_ip and E_bd are more controlled than with plasma treatment. This technique is particularly suitable for controlled permeation without sacrificing in-plane mechanical continuity, since damage is concentrated at pore sites rather than distributed across the basal plane.

### Functionalization With Reactive Species (Amines, Diazonium Salts, and Related Chemistry)

Covalent attachment of organic groups to the basal plane converts sp² sites to sp³, locally breaking π-conjugation and introducing point defects. Principal tuning parameters are the choice of reactive species, concentration and reaction time, activation method, and the identity of the functional group attached.

Aryl diazonium salts (such as 4-nitrobenzene-diazonium) react with the basal plane at room temperature and attach aryl groups. Amines attach preferentially at defects and edges. Azides give nitrene insertions. Friedel—Crafts acylation attaches acyl groups. Concentration, time, and pH set the coverage density; typical operations are conducted at room temperature over minutes to hours in solution. Activation can be photoactivation through a mask, mild thermal, or electrochemical. The choice of functional group determines which property is primarily tuned: polar groups increase adhesion and ε_op; bulky groups disrupt inter-layer π-stacking; charged groups create local doping.

Defects produced: sp³ substitutional sites (no pores unless a subsequent etching step is applied); Stone-Wales defect density may increase slightly at high coverage.

κ_ip decreases with increasing sp³ coverage; elastic modulus decreases modestly; adhesion increases substantially for polar groups; UV transmittance decreases; ε_op increases for polar groups; E_bd decreases moderately.

Temperature regime: low (predominantly room-temperature chemistry; thermal activation at or below 200 °C). Organic functional groups typically desorb or decompose above approximately 400-600 °C, so this technique is not compatible with subsequent high-temperature processing unless the functionalization is intentionally sacrificial—used only to seed nucleation then burned off during overgrowth. See Application section for the sacrificial functionalization strategy in III-nitride MOCVD and for use in enabling ALD of high-k dielectrics.

### Ion or Electron Beam Irradiation (FIB, E-Beam)

Focused beams of ions or electrons knock out or displace carbon atoms with near-atomic spatial precision. Ion beams using helium, gallium, or neon FIB instruments, or broad argon ion sources, are the heavier perturbation; electron beams at 30-200 keV in a TEM or SEM can generate isolated vacancies and, at higher dose, nanopores.

Beam species and energy are the primary knobs. Helium FIB provides clean, sub-5-nm pores with minimal damage outside the target zone. Gallium FIB creates larger features and also introduces gallium implantation as a substitutional defect. Neon FIB falls between the two extremes. For electron-beam irradiation, 80 kV is approximately the knock-on threshold for clean graphene; 200 k V produces vacancies readily. Dose and dwell time set vacancy density and determine final pore size. The scan pattern is fully programmable, enabling arrays of nanopores, stripes, or porosity gradients. Multi-pass strategies add further control: low-dose multi-pass produces many isolated vacancies; single-pass high-dose produces single large holes; multi-pass with rotated scan lines homogenizes edge roughness.

Defects produced: vacancies and divacancies (e-beam at moderate dose); nanopores (ion beam or high-dose e-beam); substitutional Ga (Ga FIB only); controlled pore edge geometries.

Within irradiated regions, κ_ip, E_bd, and mechanical strength follow standard defect-density scaling; the surrounding film remains pristine. Because pore placement is programmable and the fill factor can be kept at a few percent, the graphene interlayer retains most of its κ_ip and σ_ip for its thermal and electrical role in the final device stack. Scan patterning enables independent control of nucleation density (through pore pitch) and the preserved-function fraction of the graphene (through the complement of the fill factor).

Temperature regime: low (room-temperature stage; local beam heating transient and microscopic). Optional irradiation at elevated temperature (300-700 °C) provides in-situ annealing of damage as it forms, yielding larger, cleaner pores with less collateral disorder useful when pristine-quality pore arrays are required for remote-epitaxy templates or precision sensors. See Application section.

Thermal Annealing in Reactive Atmospheres (H₂, NH₃, Ar)

Heating graphene under a reactive gas restructures existing defects in a controlled manner. Hydrogen gas etches outward from vacancies to produce size-controlled pores; ammonia both adds nitrogen dopants and enlarges defects; argon is inert and primarily anneals Stone-Wales defects and point defects toward lower-energy configurations. This is generally a high-temperature technique (classical practice at 800-1000 °C). RTA may be employed to minimize thermal exposure.

Gas choice is the dominant variable: H₂ provides a clean way to convert a damaged film into a porous one with well-defined round pores; NH₃ produces N-doped MLG with vacancy generation; Ar drives restructuring and healing without introducing new defects; mixtures such as H₂/Ar or N₂/H₂ give intermediate outcomes. Temperature: 800-1000 °C gives fast kinetics, well-defined pore geometry, and clean doping; effects are slower but still productive at 600-800 °C; below approximately 500 °C only weak Stone-Wales relaxation and slow defect migration occur. Treatment time determines how far the annealing or etching proceeds. Pressure: low pressure (Torr range) speeds kinetics; atmospheric operation is slower but more spatially uniform. Ramp rate influences whether defects migrate and annihilate (slow ramps) or are frozen in with their as-formed distribution (fast ramps).

At high temperature under H₂: seed vacancies enlarge into size-controlled pores. Under Ar: Stone-Wales and small vacancies heal. Under NH₃: substitutional nitrogen is inserted. At low temperature: dominant effects are defect migration and Stone-Wales relaxation.

When healing dominates (Ar atmosphere), κ_ip and E_bd recover toward pristine values. When pore growth dominates (H₂ atmosphere), permeability increases while mechanical strength and E_bd decrease in a predictable manner. Ammonia doping shifts the Fermi level and changes optical transparency and ε_op.

Temperature regime: primarily high (800-1000 °C for full effectiveness; some effects at 600-800 °C; limited below ~500 °C). See Application section for Ar pre-cleaning before MOCVD, controlled H₂ annealing to open nanopore arrays from ion-beam seed vacancies (yielding round, uniform pores while inter-pore regions are simultaneously healed), and NH₃ pre-treatment for improved III-nitride nucleation density.

### Laser Ablation/Irradiation

Pulsed or continuous-wave (CW) lasers deliver focused optical energy that ablates, drills, or thermally decomposes graphene. Very high local temperatures are reached within the laser spot, but the bulk substrate remains near room temperature, making this technique compatible with low-temperature thermal budget constraints.

Wavelength selection determines how strongly the laser couples to the graphene: UV wavelengths (248 nm excimer, 355 nm Nd: YAG 3ω) couple strongly and ablate cleanly; visible (532 nm) is common for direct-write patterning; IR (1064 nm) relies on thermal absorption and is less spatially precise. Pulse duration strongly influences the mechanism: femtosecond pulses deliver a thermal ablation with atomically clean edges; nanosecond pulses produce thermal ablation with a heat-affected zone at the rim; CW drives annealing and defect rearrangement rather than drilling. Laser fluence is a critical dose variable: below the ablation threshold (approximately 50 mJ/cm² for fs pulses), treatment produces annealing; above threshold, it produces pore formation. Repetition rate and cumulative dose control total material removed and heat buildup. Processing atmosphere adds further control: vacuum or inert environments give clean ablation; O₂ promotes oxidative etching that enlarges pores at lower fluence; N₂ produces mild N doping at the ablation rim. Beam shaping and scanning enable arbitrary pore arrays by direct-write laser lithography; interference lithography produces regular 2D pore patterns across large areas.

Defects produced: nanopores to micropores (fluence-dependent); edge defects and sp³ halos around each pore; substitutional oxygen at pore rims under O₂ atmosphere.

κ_ip, E_bd, and mechanical strength collapse at pore sites; the continuous film between pores is largely unaffected. This confinement of damage to specific locations is an advantage over global plasma or chemical treatments when localized porosity at specific coordinates is the goal. Laser-induced mild surface oxidation (O₂ atmosphere, sub-ablation fluence) is an effective way to spatially pattern ALD functionalization of graphene. Temperature regime: low (bulk substrate near room temperature; local heating transient and microscopic). See Application section for use as remote-epitaxy templates.

### Ball Milling/Mechanical Exfoliation

Mechanical impact from milling media (typically stainless steel or zirconia balls) or shear during liquid-phase exfoliation breaks bonds and exfoliates flakes. This technique is relevant to producing MLG powders and flakes assembled into films, rather than to post-processing of an already-grown continuous film.

Milling media material determines severity of impact: harder balls (zirconia) deliver more damage; softer or Teflon-coated options give gentler exfoliation with fewer in-plane vacancies. Ball-to-powder ratio and rotation speed are primary dose controls. Atmosphere: inert (Ar)→predominantly mechanical damage; reactive (O₂, H₂)→concurrent functionalization of flake surfaces; wet processing in solvents or surfactants (NMP, DMF) favors shear exfoliation with minimal lattice damage. Duration: short milling (minutes)→mainly flake-size reduction; extended periods (hours)→extensive disorder, many edge defects. Additives (solvents, surfactants, melamine, salts) act as intercalants or exfoliation aids.

Defects produced: edge defects (high edge-to-area fraction of small flakes creates a large proportion of edge sites), vacancies, and Stone-Wales defects; substitutional defects when a reactive gas atmosphere is used.

### CVD With Controlled Parameters

Classical chemical vapor deposition (CVD) flows a hydrocarbon precursor (methane, acetylene, or ethylene) over a heated metal catalyst (copper, nickel, or platinum) at 900-1050 °C. This is a high-quality route for grain-size and grain-boundary engineering and is useful for producing graphene used in high-temperature overgrowth applications; graphene buffers for GaN and AIN are generally CVD-grown. Because classical CVD requires a metal catalyst, it typically produces graphene on a foreign substrate (copper foil or nickel film on a carrier) and relies on a downstream polymer-assisted transfer to the final device wafer; that transfer introduces tears, wrinkles, and polymer residues that degrade the graphene's in-stack thermal and electrical performance. Metal-free direct CVD on SiO₂/Si requires either very high temperature (at or above 1000 °C), long growth times, or plasma assistance, and produces smaller grains and higher defect density than metal-catalyzed CVD. For BEOL integration, plasma-enhanced CVD (PECVD, 300-450 °C, directly on SiO₂/Si) or solid-phase diffusion enabled growth serve as alternatives.

Catalyst metal is a primary control variable. Copper favors surface-reaction-limited growth, giving self-limiting monolayer formation with fewer grain boundaries and larger domain sizes, but is difficult to use for MLG production. Nickel and cobalt favor carbon-dissolution-limited growth with segregation on cooling, naturally giving MLG but with more grain boundaries and thickness non-uniformity. Alloys such as Cu—Ni or Ni—Mo allow the growth mode to be tuned between these regimes. The hydrocarbon-to-hydrogen ratio in the feed gas determines the balance between growth and in-situ etching: higher H₂ content promotes etching during growth, reducing defects but slowing growth; lower H₂ content accelerates growth but increases grain-boundary and point-defect density. Chamber pressure: low-pressure CVD gives uniform single-layer growth and cleaner films; atmospheric CVD gives easier MLG formation but with more point defects. Cooling rate after growth (for Ni): fast quenching produces few-layer graphene with small grains and many grain boundaries; slow cooling gives thicker films with larger grains. Substrate pre-treatment (electropolishing of Cu, O₂ passivation) enlarges domain sizes and reduces nucleation site density.

Temperature regime: high (≥900C for classical CVD; incompatible with BEOL). PECVD at 300-450 °C is BEOL-accessible directly on SiO₂/Si but delivers smaller grains, higher defect density, and poorer in-plane properties. Two main process flows are used for overgrowth: (1) CVD on copper foil followed by polymer-assisted transfer onto the device wafer, giving the highest-quality graphene but with transfer-induced defects; (2) direct CVD growth on the overgrowth substrate (sapphire, SiC), with parameters tuned to produce graphene with a controlled density of wrinkles, ridges, and bilayer patches that each act as nucleation features for the subsequent semiconductor layer-this eliminates the transfer step but is limited to refractory substrates. See Application section.

### Solid-Phase Diffusion Enabled Graphene/MLG Growth

In a solid-phase diffusion process for direct-on-Si/SiO₂ integration, the catalyst metal may be deposited directly on the final Si/SiO₂ wafer, the carbon source is deposited on top (or beneath, in bottom-segregation variants), the stack is heated to drive solid-state diffusion of carbon through the catalyst, and carbon segregates as graphene or MLG at the catalyst/SiO₂ or catalyst/Si interface. After segregation, the catalyst metal is selectively wet-etched (FeCl₃ for nickel; HCl-based etchants for cobalt), leaving the graphene in place on the Si/SiO₂ wafer. No polymer-assisted transfer from a foreign substrate is required, eliminating the wrinkles, tears, and polymer-residue degradation associated with transfer. Because the rate-limiting step is solid-state diffusion rather than gas-phase decomposition, the process can operate within the BEOL thermal budget of approximately 400-500 °C. Essentially every element of the stack is a tunable parameter for defect and pore engineering, as described below.

### Catalyst Metal Composition

Nickel has the highest carbon solubility among the common options at moderate temperature and gives fast MLG growth with controllable thickness via cooling rate. Cobalt has lower carbon solubility and finer grains, tending to produce smaller graphene grains but thinner, more uniform films. Fe—Ni alloys show promise for low-temperature growth. Ni-Mo and Ni—Cu alloys suppress thickness non-uniformity. The alloy ratio provides a fine adjustment on carbon solubility and grain size: nickel-rich compositions give thicker films, larger grains, and fewer pores; cobalt-rich compositions give thinner films, smaller grains, and more nucleation sites leading to more pores. Trace impurities by design (oxygen in the catalyst→larger grains; sulfur→suppresses nucleation) offer additional control. cl Catalyst Metal Microstructure

Catalyst grain size determines graphene grain size: larger catalyst grains provide long diffusion paths, fewer surface nucleation sites, and therefore larger graphene grains; conversely, small-grained, high-grain-boundary-density catalyst films create many fast diffusion paths and more nucleation sites, leading to smaller graphene grains, more point defects, and more pores. Crystallographic texture matters: (111) texture (characteristic of FCC Ni and Co) provides the lowest-mismatch substrate for graphene and the largest grains; random or mixed texture gives higher graphene grain-boundary density. Intentional microstructural gradients (achieved by depositing a catalyst with a thickness or grain-size gradient) create a spatial gradient in graphene defect density, pore density, or thickness across the wafer—useful for combinatorial optimization or in-device property grading.

### Catalyst Deposition Method

Sputter deposition typically gives small-grained, high-grain-boundary-density films with some tensile stress; this promotes fast diffusion and more graphene nucleation, resulting in smaller grains and more pores unless a post-deposition anneal is applied to coarsen the catalyst. Electron-beam evaporation gives a columnar microstructure with lower stress and moderate grain size. Thermal evaporation produces the largest catalyst grains, resulting in the largest graphene grains and fewest pores. Electroplating and electroless plating give thick films with tailored stress and grain size. Atomic layer deposition of the catalyst gives very uniform thickness but typically amorphous or nanocrystalline microstructure, creating many diffusion paths and nucleation sites and resulting in many small graphene grains and many pores.

### Carbon Source Film

The type of carbon source determines the uniformity and chemical character of the carbon supply. Sputtered or e-beam-deposited amorphous carbon provides uniform composition and tunable thickness. Spin-coated polymer precursors (PMMA, polystyrene, SU-8) are easy to pattern and have different H/C and O/C ratios, giving different degrees of oxygen decoration in the resulting graphene. Self-assembled monolayers (aromatic thiols, silanes) provide sub-nanometer thickness for single-layer graphene. Spin-coated precursors such as sucrose, glucose, and polyacrylonitrile (PAN) are mass-manufacturable.

Carbon source thickness is the principal control variable for the number of graphene or MLG layers produced: thin sources give monolayer to 2-3 layer graphene; thicker sources give up to ten or more layers. The carbon-to-metal thickness ratio provides further control: a thicker catalyst for a given carbon thickness slows segregation by lengthening diffusion paths and smooths thickness fluctuations, leading to larger grains and fewer pores. Heteroatom content matters: hydrogenated amorphous carbon gives cleaner graphene (H is volatile and exits the stack); polymers with high oxygen content tend to give oxidized graphene with more vacancies; nitrogen-bearing precursors (PAN, melamine) automatically dope the resulting graphene with nitrogen. Multi-layer C/catalyst sandwiches (e.g., C/Ni/C/Ni stacks) give multi-layer graphene with thickness and defect density set layer by layer.

### Pre-Patterning of the Stack

Pre-patterning of the catalyst or carbon source (or both) before the diffusion step provides a particularly powerful and clean method for engineering the geometry of the resulting graphene. A pre-patterned catalyst layer (defined by photolithography, nanoimprint lithography, or EBL into arrays of squares, stripes, circles, or more complex shapes) confines graphene growth to the catalyst-covered areas; around the pattern boundaries, the resulting edges are well-defined engineered edge defects created without any post-growth plasma, ion, or chemical damage to the film interior. Pre-patterning the carbon source instead produces patches of graphene with defined size and spacing, where the gaps between patches are pre-designed pores at the micron scale. Pattern pitch and fill factor directly set the graphene grain size (each isolated patch acts as one nucleation-limited grain) and the porous-area fraction, which in turn controls transmittance, modulus, and adhesion trade-offs. Hybrid lithographic templates combining a pre-patterned metal with a separately patterned carbon source enable complex layouts such as pore arrays embedded within continuous graphene regions, spanning the full design space of patterned MLG with nanometer-to-micron resolution.

### Process Conditions

In the low-temperature regime, nickel/amorphous-carbon stacks can be run at approximately 300-500 °C for reliable solid-state diffusion and BEOL compliance; below 300 °C, diffusion slows and films may remain partial or amorphous. In the high-temperature regime (600-900 °C), the technique produces larger graphene grains, fewer point defects, and cleaner films approaching classical CVD quality.

Mechanical pressure is an optional process parameter. When applied, it compresses the carbon into the catalyst, shortens effective diffusion paths, and promotes graphene formation at temperatures that may be lower than would otherwise be required (ranges span from a few MPa to greater than 1 GPa). Lower applied pressures produce fewer but larger graphene grains, though with more pores; higher pressures produce smaller grains and more islands or bilayer patches. Pressure can serve as a complement to temperature, allowing a lower-temperature run to achieve film quality comparable to that of a higher-temperature, lower-pressure process. The process also operates effectively without applied pressure.

Dwell time sets how far segregation proceeds: short dwell times give partial graphene films with many pores and vacancies; long dwell times give continuous films with larger grains but also grown-in wrinkles and stress. Fast quenching of nickel-based stacks gives thinner MLG with more grain boundaries; slow cooling gives thicker MLG with fewer grain boundaries. The processing ambient influences film cleanliness: vacuum→cleanest films; inert Ar→sufficient for most applications; low H₂ content→etches vacancies closed during growth; trace O₂→creates pores at grain boundaries.

### Defects Produced and How Each Parameter Steers Them

Vacancies arise from C supply-to-demand imbalance (too-thin carbon source, too-fast cooling, or small-grained catalyst); corrected by increasing carbon source thickness, reducing cooling rate, or increasing catalyst grain size. Stone—Wales defects are elevated at sub-optimal (too low) growth temperature or shortened dwell time. Grain boundaries and grain size are directly set by catalyst grain size and texture, carbon supply uniformity, and cooling rate; larger catalyst grains combined with slow cooling and a uniform carbon source give larger graphene grains and fewer grain boundaries. Nanopores and micropores are tuned primarily by pre-patterning (the primary control), by carbon-source thickness non-uniformity (a local control), and by catalyst grain-boundary topology (a secondary influence); intentional catalyst thickness or grain-size gradients create spatial gradients in pore density across the wafer. Edge defects are engineered via pre-patterned stacks, creating well-defined edges without post-growth plasma or ion damage to the film. Substitutional doping is achieved by using a nitrogen-or boron-bearing carbon source (PAN, melamine, or boron-nitride-mixed precursors) or by introducing nitrogen or ammonia into the processing ambient; dopant concentration is tunable with source stoichiometry.

### Property Effects Summary

κ_ip is dominated by grain size, with catalyst grain size and the cooling profile as the master control variables. The CTE shifts less negatively when grain size is small, which is often advantageous as it reduces CTE mismatch with silicon. Elastic modulus and mechanical strength follow grain size (Hall—Petch regime) and porosity (Gibson—Ashby scaling), with pre-patterning as the primary porosity control. Adhesion to SiO₂ is improved by smaller grains and polar substitutional dopants sourced from the carbon precursor. Film stress and warpage are directly influenced by process conditions: when mechanical pressure is optionally applied, higher pressure stores more compressive stress; slow depressurization before cool-down allows that stress to relax; combined with smaller grains (less-negative CTE), stress and warpage can be actively managed. Optical n and transmittance track the porous-area fraction (set primarily by pre-patterning) and the dopant identity from the carbon source. ε_op is increased by polar carbon sources. E_bd is set by grain-boundary density and porosity; large catalyst grains and the absence of pre-patterned pores are preferred for high E_bd. TBR is reduced when the carbon source contains oxygen or nitrogen that forms chemical bonds to the SiO₂ or Si substrate during segregation; furthermore, because the graphene is grown in place on Si/SiO₂ without a transfer step, the graphene-to-substrate interface is naturally cleaner and more conformal than in a transferred CVD film. See Application section for the use of pre-patterning for overgrowth templates.

### Template-Assisted Etching

Template-assisted etching uses a patterned mask applied on top of the MLG followed by etching through the mask openings to create a periodic pore array. Suitable mask materials include block copolymers (BCPs), colloidal nanoparticles, lithographic resist, and anodic alumina, each offering different pore size and density ranges.

Template type determines the accessible pore geometry. BCP templates produce 10-50 nm pores at high density, suited for filtration and sensing applications. Colloidal self-assembly gives hexagonal close-packed nanopore arrays from 10 nm to 1 μm. Nanosphere lithography is quick and low-cost. Lithographic resist templates are flexible in geometry but resolution-limited unless EBL is used. Anodized alumina templates give ultra-high-density ordered pore arrays. Etching chemistry through the template openings determines pore quality and rim functionalization: O₂ plasma gives clean vertical walls; wet chemistry (FeCl₃, HNO₃) gives gentler rim-functionalized pores; ion milling gives deep anisotropic pores. Template removal is by solvent lift-off, thermal decomposition (300-450 °C, within BEOL budget), or wet etching (HF or KOH for alumina). Residues from template removal can act as dopants or edge functionalization agents.

Defects produced: nanopores of highly regular size and pitch; edge defects around each pore; substitutional defects from template residues; negligible bulk lattice damage between pores.

κ_ip, elastic modulus, mechanical strength, and E_bd all decrease in proportion to the porous area fraction and can be predicted analytically using Gibson—Ashby and Griffith scaling. Visible transmittance in the visible range increases at high porosity. Template removal by thermal decomposition at or below 450 °C is BEOL-compatible. See Application section for BCP/nanosphere templates as remote-epitaxy routes (10-50 nm diameter pores at 109-1011 cm⁻², retaining ≥90% of pristine κ_ip and σ_ip), anodized alumina for periodic overgrowth seed geometry useful in photonic-crystal integration, and colloidal templates for production-scale throughput.

### Self-Assembly of Porous Graphene Frameworks

Rather than starting from existing graphene and introducing defects, this approach builds graphene from the molecular level upward using designed aromatic precursors (hexabenzocoronenes, polyphenylenes, and similar molecules) that polymerize and undergo cyclodehydrogenation to form a graphene-like sheet with built-in pores. This approach can be applied on Au(111), Ag(111), or Cu(111) surfaces under ultra-high vacuum (UHV).

Precursor molecule design determines pore size and shape at the molecular design stage (e.g., cyclohexa-m-phenylene gives approximately 0.8 nm hexagonal pores; different molecular symmetries give different pore lattice geometries). The substrate catalyzes cyclodehydrogenation and sets the orientation of the resulting framework; Au(111) is the classical substrate, while Cu and Ag alternatives work at slightly different temperatures.

Precursor surface coverage determines whether isolated oligomers (sub-monolayer) or edge-fused polymeric sheets (full monolayer, after annealing) form. Annealing proceeds in two stages: polymerization at approximately 200 °C followed by cyclodehydrogenation at approximately 350-450 °C, with both stages fitting within the BEOL budget for most precursor families. UHV gives the cleanest frameworks; ambient-condition methods produce more vacancies and edge defects.

Defects produced: designed periodic pores; incomplete cyclodehydrogenation sites (sp³ defects); domain boundaries between self-assembled patches; vacancies at mis-linked sites.

### Lithographic Patterning (e.g., EBL)

Lithographic patterning involves defining a mask (photoresist, HSQ, or PMMA) over the MLG and then transferring the pattern into the graphene by oxygen plasma or ion etching. Resolution is determined by the lithography tool: EBL achieves features at or below 10 nm, extreme-UV lithography at or below 13 nm, deep-UV lithography at 38-90 nm, and i-line lithography at 365 nm.

The resolution of the selected lithography tool determines the accessible pore sizes and spacings. Resist chemistry determines resolution and residue levels after stripping; HSQ is a negative-tone, high-resolution resist; PMMA is the standard positive-tone EBL resist; ZEP provides higher contrast as a PMMA replacement. Low-residue resists should be chosen for clean films, as residue after stripping can be a contamination source. The etch recipe determines pore character: O₂ plasma gives clean vertical pores; CF₄/O₂ allows simultaneous pattern transfer into underlying SiO₂; wet etches produce sloped walls. Multi-level lithography enables hierarchical patterning, combining a coarse mask for device-level features with a fine mask for sub-100-nm pore arrays, enabling full-wafer remote-epitaxy-based integration with graphene as a functional interlayer.

Defects produced: engineered micro- and nanopores with programmable geometry; edge defects at pore rims; potentially resist residue acting as substitutional or edge functionalization.

### Intercalation and Exfoliation

Guest species (such as lithium, potassium, FeCl₃, bromine, or ionic liquids) are inserted between graphene layers. On removal by solvent, heat, or evacuation, defects, pores, or expanded interlayer spacing remain.

The choice of intercalant chemistry determines the severity of the effect. Alkali metals (Li, K) are strong intercalants that leave high defect density on removal. Metal halides (FeCl₃, AlCl₃) are moderate and retain ordered intercalated structure. Ionic liquids give gentle and reversible intercalation. Halogens (Br₂, I₂) are mild and generate low defect density. The driving force for intercalation may be thermal (100-400 °C), electrochemical (0.1-3 V), or vapor-phase, with electrochemical intercalation giving the finest dose control. Removal method determines defect outcome: rapid thermal desorption causes explosive expansion and generates many defects; solvent rinsing gives slower, cleaner removal with fewer defects; vacuum pumping gently removes the intercalant while retaining the pore structure. Stage control (whether every gallery is filled [stage-1] or only every n-th gallery [stage-n]) determines the post-removal inter-layer defect distribution.

Defects produced: expanded interlayer spacing; wrinkles; layer-to-layer misalignment; vacancies on violent removal; residual substitutional species (Fe, Cl) when removal is incomplete.

Out-of-plane properties are most affected: ε_op changes (upward or downward depending on whether pores form); κ_op decreases due to disordered stacking; TBR increases; optical birefringence is altered. In-plane properties are preserved or improved, as doping from residual intercalant can raise σ_ip. Most intercalation routes proceed at or below 400°C; electrochemical and solvent routes are at room temperature. Higher-temperature thermal desorption (600-1000°C) after intercalation gives faster and more complete removal and produces more uniform inter-layer expansion.

### Strain Engineering

Mechanical strain—biaxial or uniaxial, tensile or compressive—applied during or after other processing steps biases defect-formation energetics. Defect formation energies depend on local strain: a tensile-strained patch preferentially nucleates vacancies on irradiation; a compressed patch nucleates Stone-Wales rearrangements. Strain engineering does not produce a primary defect type on its own; rather, it biases the distribution and density of whatever defects are produced by a paired technique, with engineered spatial gradients.

Strain magnitude and sign are the primary variables; up to a few percent strain is achievable with flexible substrates or piezo-actuated substrates. Tensile strain favors vacancy formation; compressive strain favors buckling and Stone-Wales defect formation. Strain geometry determines the spatial character of the defects: uniaxial strain produces directional defects and ribbon-like structures; biaxial strain produces radially symmetric pore distributions. Substrate choice determines what strain levels are practically accessible: PDMS and other polymers allow high flexural strain; piezoelectric substrates (PZT, ZnO) enable dynamic strain; CTE-mismatched rigid substrates impart permanent strain through thermal excursions. Useful combinations: irradiation under applied strain→spatially biased vacancy arrays; patterned strain via substrate surface corrugation→patterned defect density.

### Application: Graphene as a Substrate for Semiconductor Overgrowth

One principal application for defect-engineered MLG is its use as a nucleation substrate for subsequent three-dimensional semiconductor overgrowth. Target materials span III-nitrides (GaN, AlN, InN), group-IV semiconductors (Ge, Si), and oxide and nitride dielectrics (SiO₂, Al₂O₃, HfO₂, Si₃N₄).

A key design principle is that the graphene is generally a permanent layer in the final substrate stack—included for its thermal properties (in-plane heat spreading, κ_ip≈1500-2500 W/mK) or its electrical properties (buried high-conductivity interlayer, interconnect, or Fermi-level control)—not as a sacrificial release layer. Optimization therefore aims for the minimum perturbation that enables continuous, well-registered overgrowth while preserving as much as possible of the graphene's native κ_ip, σ_ip, and mechanical role in the stack. Localized-defect techniques (remote-epitaxy pore arrays, grain-boundary-selective etching) are strongly preferred over uniform basal-plane treatments (broad plasma, heavy functionalization, bulk oxidation).

A second consideration specific to the baseline direct-on-Si/SiO₂ process concerns what lies beneath the graphene. When the graphene is on thermal or deposited SiO₂, the underlying material is amorphous, so through-pore remote epitaxy cannot seed single-crystal overgrowth; the operative nucleation mechanisms in this geometry are covalent bonding at vacancies, polar interaction at substitutional or functionalized sites, and line nucleation at grain boundaries or patterned edges. When the graphene is grown directly on single-crystal Si (with no oxide beneath, or with a pre-patterned SiO² that has windows to bare Si), pores in the graphene expose Si and through-pore epitaxy can register the overgrowth to Si, which is well-suited for Si or Ge homo-and heteroepitaxy. For III-nitride remote epitaxy at the highest quality, graphene is grown on SiC or sapphire by a separate high-temperature route.

### Why Pristine Graphene is a Poor Growth Substrate

The sp² basal plane of pristine graphene offers no dangling bonds, no polar sites, and uniformly weak van der Waals interaction with most precursors. MOCVD, MBE, CVD, ALD, and evaporation-deposited precursors therefore either desorb before they can bond or nucleate as isolated three-dimensional islands (Volmer-Weber growth) rather than continuous films. Wetting is poor, and films dewet on any subsequent thermal cycle. For many target materials, direct deposition on pristine graphene is essentially impossible to make uniform across a wafer.

### How Defects Enable Overgrowth

Four distinct mechanisms operate in enabling graphene to serve as an effective overgrowth substrate, often in combination. Each is activated by selecting an appropriate defect type and the technique that produces it.

### Mechanism 1: Covalent Nucleation at Vacancies

A missing carbon atom exposes two to three dangling bonds that are highly reactive toward most precursors. Sub-percent vacancy density is typically sufficient to seed a continuous film. Appropriate techniques: plasma treatment, ion and electron beam irradiation, and reactive-atmosphere annealing (when high temperature is available). This mechanism is well-suited to germanium, silicon, metal films, and ALD of oxides and nitrides where the precursor chemistry is reactive.

### Mechanism 2: Polar Nucleation at Substitutional and Functionalized Sites

Substitutional nitrogen, oxygen, or functional groups (hydroxyl, carboxyl, amino) introduce polar sp² or sp³ sites that chemisorb polar precursors. A few seconds of oxygen plasma converts an otherwise unusable pristine-graphene ALD substrate into one that produces continuous, pinhole-free dielectric films. Appropriate techniques: plasma treatment (O₂, NH₃, or N₂), oxidation, functionalization with reactive species, and solid-phase diffusion enabled graphene growth using a dopant-containing carbon source.

### Mechanism 3: Line Nucleation at Grain Boundaries and Edges

Atoms at grain boundaries and at exposed edges are chemically more reactive than basal-plane atoms and act as one-dimensional nucleation fronts. Overgrown films preferentially nucleate along these lines and then spread laterally to form a continuous layer. Appropriate techniques: CVD with controlled parameters (for grain-size tuning), solid-phase diffusion enabled graphene growth (with catalyst microstructure control), and pre-patterned edges produced by lithographic patterning or template-assisted etching. This mechanism is well-suited to germanium and metal deposition where continuous coverage matters more than crystallographic lattice registration.

### Mechanism 4: Remote and Pinhole Epitaxy Through Nanopores

Small (5-50 nm), well-spaced (50-500 nm pitch) nanopores allow the overgrown crystal to bond directly to the underlying single-crystal substrate through the pore; the overgrown material inherits its orientation and lattice constant from that substrate despite most of its area resting on top of the graphene. Because defect damage is concentrated at small, well-spaced pore sites, the inter-pore graphene remains pristine, preserving most of its in-plane thermal conductivity, electrical conductivity, and mechanical integrity for its role in the final device stack-for example as a buried heat spreader beneath a GaN HEMT.

What lies beneath the graphene determines whether this mechanism is operative. On single-crystal Si (the baseline direct-on-Si process, or SiO₂ pre-patterned with Si windows): pores expose bare Si and the geometry is suitable for Si and Ge homo-and heteroepitaxy and for low-temperature III-nitride sputtering where lattice match is not critical. On SiO₂ (the baseline direct-on-SiO₂ process): the underlying material is amorphous; remote epitaxy cannot produce single-crystal overgrowth; if single-crystal overgrowth is required from this architecture, the SiO₂ must be pre-patterned with windows to bare Si before catalyst deposition so that the resulting graphene has its pores aligned to silicon openings. On SiC or sapphire (high-temperature route): pores expose a refractory single-crystal substrate with lattice constants close to GaN and AlN, which is the ideal geometry for III-nitride MOCVD at 1000-1200 °C-the best architecture when highest overgrowth quality is required and BEOL compatibility is not a constraint.

Film thickness significantly affects the practical effectiveness of this mechanism. For monolayer and few-layer graphene, the pore is effectively zero-depth and the substrate is immediately accessible. For substantially thicker films (e.g., approximately 40 nm, or 115-120 layers), the pore becomes a high-aspect-ratio channel: a 10 nm pore through a 40 nm film has a depth-to-diameter ratio of approximately 4:1, which reduces the solid angle subtended by the substrate as seen from the top of the pore and attenuates the substrate's electric field at the overgrowth surface. In this geometry, crystallographic registration via remote epitaxy may be diminished, and Mechanisms 1-3 become relatively more important as primary drivers of continuous overgrowth. When remote epitaxy is a priority on a thick film, wider pores (toward the upper end of the 5-50 nm design range, or beyond) may be used to reduce the aspect ratio, at the cost of a higher fill factor and proportionally greater reduction in the graphene's in-plane thermal and electrical properties.

### Design Rules for Remote-Epitaxy Templates

The following design rules apply regardless of the underlying substrate. Pore diameter should be 5-20 nm for GaN and AIN to achieve tight lattice registration, and up to 50 nm for less stringent overgrowth materials. For thicker MLG films (tens of nanometers), pore aspect ratio (depth-to-diameter) should be considered alongside pore diameter; at approximately 40 nm film thickness, pore diameters toward the larger end of the preferred range help maintain adequate solid angle to the substrate and reduce aspect-ratio-induced field attenuation. Pore pitch should be smaller than the adatom diffusion length at the growth temperature, typically 50-500 nm. Round pore shapes are preferred, as sharp edges can nucleate extended defects in the overgrown crystal. Fill factor should typically be 1-10% porous area—large enough to ensure uniform nucleation while small enough to preserve most of the graphene's thermal and electrical function; per Gibson-Ashby and effective-medium scaling, approximately 10% porosity costs only approximately 15-20% of κ_ip. Fill factor should be increased above 10% only when high nucleation density is essential for the target material. Hierarchical lithography (combining coarse device-level patterns with fine pore arrays) enables full-wafer remote-epitaxy-based three-dimensional semiconductor integration with graphene as a functional interlayer.

Techniques for producing remote-epitaxy templates, in order of placement accuracy:

(1) Helium FIB—highest precision, sub-5-nm pores, perfect placement, applicable to any underlying substrate. (2) EBL combined with etching—programmable, sub-30 nm, works equally on graphene-on-Si/SiO₂ and graphene-on-refractory stacks. (3) Block-copolymer and nanosphere templates—wafer-scale, less spatially uniform; anodized alumina gives ultra-regular arrays suited to periodic overgrowth seed geometry (e.g., photonic-crystal integration); colloidal templates offer full-wafer throughput at low cost for production-scale remote-epitaxy templating. (4) Pre-patterned solid-phase diffusion enabled graphene growth—grows graphene with built-in pore arrays directly on Si/SiO₂ with no post-growth damage, making it the natural fit for the baseline process described in this disclosure. (5) Laser-drilled nanopore arrays—an alternative to ion beam irradiation and lithographic patterning offering lower equipment cost and wafer-scale throughput potential; resolution is coarser than helium FIB (approximately 100 nm minimum feature), best suited for overgrowth materials tolerating larger pores such as GaN and Ge.

It is noted that the lift-off and release-layer use case for remote-epitaxy graphene is also well-established: by dissolving or mechanically peeling at the graphene interlayer, the overgrown crystalline film can be transferred to a different substrate. Nothing in the defect-engineering approach needs to change for this use case; the same pore-array design that enables remote epitaxy also serves a permanent-graphene-interlayer architecture.

Technique-Material Map for Graphene Overgrowth Substrates The appropriate defect-engineering route depends strongly on the target overgrowth material and its process temperature. The following paragraphs describe one or more possible implementations for each major material system.

### Gan (MOCVD, 1000-1100C)

The dominant nucleation mechanism for GaN MOCVD is remote epitaxy, which requires a crystalline underlayer beneath the graphene pores. One possible implementation involves graphene grown on SiC or sapphire via CVD with controlled parameters or high-temperature solid-phase diffusion enabled graphene growth, with pores introduced by helium FIB, EBL combined with etching, or block-copolymer template etching. A second possible implementation is direct CVD growth on the overgrowth substrate (SiC, sapphire) with parameters tuned to produce graphene with a controlled density of wrinkles, ridges, and bilayer patches that act as nucleation features for the subsequent GaN layer, eliminating the transfer step. On the baseline graphene-on-Si/SiO₂ stack, an alternative uses SiO₂ pre-patterned with Si windows aligned to the pore array; remote-epitaxy quality in this geometry is lower than on SiC or sapphire due to the Si—GaN lattice mismatch. Graphene survives MOCVD temperature on refractory substrates. Argon annealing at 900-1000 °C before MOCVD removes residual transfer polymer and heals small lattice defects, leaving a cleaner surface and improving the graphene's thermal and electrical function in the final stack. A sacrificial functionalization strategy is also available: mild functionalization seeds a continuous MOCVD nucleation front, thermally evaporates during the MOCVD temperature ramp (above 600 °C), and leaves behind graphene close to its pristine thermal performance-useful when graphene serves as a heat spreader beneath III-nitride HEMTs.

### AlN (MOCVD at 1050-1200 °C; Sputter at 300-500 °C)

The dominant mechanisms for AIN are remote epitaxy and line nucleation at grain boundaries. For MOCVD, the same approach as GaN applies. For low-temperature sputter deposition (300-500 °C), a possible implementation that is BEOL-compatible and works directly on graphene-on-Si/SiO₂ combines grain-boundary density tuning through CVD grain-size control with nitrogen plasma treatment, requiring no refractory substrate. Ammonia doping in-situ before AIN growth improves nucleation density and leads to denser, smoother III-nitride films, at the cost of substitutional nitrogen throughout the graphene (which modestly reduces κ_ip and shifts σ_ip via Fermi-level doping—an effect that may be beneficial or detrimental depending on the electrical role of the graphene interlayer). Controlled hydrogen annealing at 700-900 °C can be used to open nanopore arrays from ion-beam seed vacancies, so that pore size is set thermally rather than by the initial dose; this produces very round, uniform pores well-suited for remote epitaxy, while the inter-pore regions are simultaneously healed by the anneal.

### InN/InGaN (MOCVD at 500-800 °C)

Remote epitaxy is the dominant mechanism for InN and InGaN overgrowth, following the same general approach as GaN and AlN. The lower overgrowth temperature reduces thermal stress on the graphene. One possible implementation uses a graphene-on-Si/SiO₂ stack at the lower end of the temperature range, making this compatible with a wider range of substrate architectures than the higher-temperature III-nitrides.

Germanium (CVD or MBE at 300-600 °C) For germanium overgrowth, the operative mechanisms are vacancy and polar nucleation, line nucleation at grain boundaries, and remote epitaxy through SiO₂ windows to Si. A possible implementation for direct overgrowth on graphene-on-Si/SiO₂ uses mild oxygen plasma treatment or oxidation to provide uniform nucleation sites. A second possible implementation uses lithographic patterning combined with etching, with the SiO₂ pre-patterned to expose Si, enabling single-crystal Ge-on-Si through-pore registration. Both implementations are fully BEOL-compatible. Chemically etched graphene (selective grain-boundary attack) provides a self-aligned pore network well-suited when the target pore pitch matches the graphene grain size (0.1-10 82 m), with inter-pore basal-plane regions retaining most of their pristine κ_ip. Electron-beam-generated vacancy arrays and laser-drilled nanopore arrays are additional implementation options, each providing uniform nucleation while leaving most of the basal plane intact for electrical and thermal function.

### Silicon (CVD or LPCVD at 450-650 °C)

Vacancy nucleation and remote epitaxy to the Si underlayer are the dominant mechanisms for silicon overgrowth. One possible implementation uses plasma treatment or ion beam irradiation on graphene-on-Si/SiO₂ to create the necessary vacancies; polar functionalization additionally aids CVD precursor (silane) adhesion. The direct-on-Si stack (without SiO₂ beneath the graphene) is the ideal geometry, as pores directly expose the epitaxial silicon seed.

SiO₂ (PECVD at 300-450 °C; Thermal Oxide at 800-1100 °C) Polar nucleation is the dominant mechanism for silicon dioxide overgrowth. A possible implementation for PECVD-compatible conditions uses oxygen plasma treatment, which is fully compatible with the graphene-on-Si/SiO₂ baseline stack. For thermal oxide deposition, a possible implementation uses pre-oxidation of the graphene surface followed by thermal reduction in a controlled oxygen atmosphere, with the constraint that the graphene must survive the elevated temperature.
Al₂O₃ and HfO₂ (ALD at 200-300 °C)

Polar nucleation is the dominant mechanism for ALD of high-k dielectrics on graphene. A possible implementation uses mild oxygen plasma treatment-the classical enabler for ALD of these oxides on graphene—which works directly on graphene-on-Si/SiO₂. An alternative uses diazonium-based functionalization when plasma-induced damage is unacceptable. A lightly oxidized graphene top surface, or mild functionalization with polar groups (carboxyl, hydroxyl, or amino), is substantially better as an ALD substrate for Al₂O₃ and HfO₂ than pristine graphene. A carbon source with engineered nitrogen or oxygen content (polymer, PAN, sucrose) in solid-phase diffusion growth produces substitutionally doped graphene that serves as a polar nucleation surface for ALD with no post-growth functionalization needed. Laser-induced mild surface oxidation (O₂ atmosphere, sub-ablation fluence) is an effective way to spatially pattern ALD functionalization. Dose control should be configured to provide the minimum exposure that achieves continuous ALD nucleation in order to preserve κ_ip and σ_ip of the graphene layer beneath. Crucially, only the top one to two graphene layers need polar nucleation sites; engineering so that only the topmost layer is functionalized preserves κ_ip and σ_ip of the underlying layers for their thermal and electrical role.

Si₃N₄ (PECVD at 300-400 °C; LPCVD at 700-800 °C)

Polar and vacancy nucleation are the dominant mechanisms for silicon nitride overgrowth. A possible implementation uses ammonia or nitrogen plasma functionalization to introduce nitrogen-containing polar sites and vacancies. An alternative uses solid-phase diffusion enabled graphene growth with a nitrogen-doped carbon source to incorporate substitutional nitrogen directly during graphene synthesis. The PECVD variant is BEOL-compatible on graphene-on-Si/SiO₂.

### Metals (Al, Ti, W, Ni; Room Temperature to Approximately 400 °C)

Vacancy and line nucleation are the dominant mechanisms for metal film deposition on graphene. A possible implementation uses argon plasma treatment to create clean vacancies without introducing oxygen or nitrogen contamination. An alternative uses solid-phase diffusion enabled graphene growth with selective pore-patterning for directional nucleation. All such implementations are BEOL-compatible on graphene-on-Si/SiO₂.

### Trade-Offs Specific to Overgrowth Applications

The most fundamental trade-off is between defect density and the graphene's in-stack function. Every defect that aids overgrowth nucleation also degrades κ_ip and σ_ip of the graphene layer itself. Since graphene is typically included in the stack for its thermal conductivity (heat spreading under a high-power device) or its electrical conductivity (buried interconnect or ground plane), the defect-engineering target is the minimum perturbation that enables continuous overgrowth, not the maximum.

A closely related trade-off is between localized and uniform defect distributions. Concentrated defects (small pores, grain-boundary-selective etching, patterned edges) preserve the bulk basal plane for thermal and electrical function. Uniform treatments (broad plasma, bulk oxidation, heavy functionalization) distribute damage across the entire basal plane and trade proportionally more of the graphene's native performance. Localized distributions are therefore strongly preferred when preserving κ_ip and σ_ip is a design requirement. This trade-off can be quantified: fill-factor-based pore-array designs at 1-10% porosity typically reduce κ_ip by less than 20% (Gibson—Ashby scaling) and reduce σ_ip by a comparable fraction—often an acceptable cost for enabling III-V integration. In contrast, a uniform 1 at. % vacancy plasma treatment can reduce κ_ip by 30-50%.

At the graphene-substrate and graphene-overgrowth interfaces, defects can reduce thermal boundary resistance (TBR) by creating covalent or polar bonds across the interface. This represents a genuine win-win for the graphene-as-heat-spreader use case, since lower TBR improves heat extraction from the overgrown device without necessarily degrading in-plane thermal conductance.

Defects also change the in-plane CTE of graphene: smaller-grain or more-defective graphene has a less-negative α_ip, which can reduce CTE mismatch with the overgrown semiconductor and improve yield of the overgrown layer. This effect couples directly to warpage analysis.

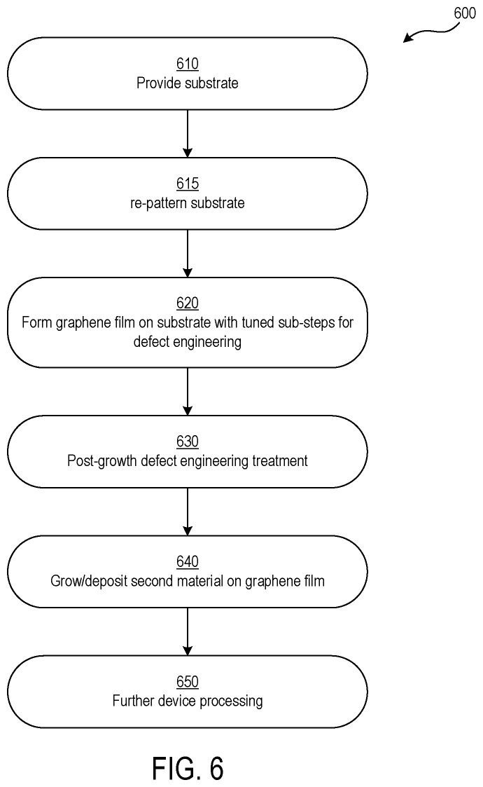

FIG. 6 is a flowchart of an example process 600 according to implementations of the disclosure. The reference numerals introduced below are used in the drawing. The process 600 forms a graphene film on a substrate, optionally engineers defects in the graphene film by tuning the growth or by post-growth treatment, and grows or deposits a second material on the engineered graphene film. Steps shown in dashed outline in the drawing are optional in implementations of the disclosure.

At step 610, a substrate is provided. The substrate is, by way of example, a silicon wafer, a silicon-on-insulator wafer, a silicon dioxide layer (thermal or deposited) on silicon, a previously processed CMOS wafer, a flexible polymer substrate, a sapphire wafer, or a silicon carbide wafer. At optional step 615, the substrate is pre-patterned, by way of example by photolithography and etching to define windows in a silicon dioxide layer that expose underlying single-crystal silicon at locations that will register subsequent through-pore epitaxy of the second material.

At step 620, a graphene or multi-layer graphene film is formed on the substrate. In implementations, step 620 is a sub-process implementing the solid-phase diffusion route described above. In other implementations, step 620 uses chemical vapor deposition on a foreign substrate followed by polymer-assisted transfer to the substrate provided at step 610, plasma-enhanced chemical vapor deposition directly on the substrate, or another graphene formation technique.

In implementations, defect engineering of the graphene film is performed by tuning sub-steps of the in-situ growth, including by way of example: selecting the catalyst metal composition (nickel, cobalt, iron, or alloy such as nickel-cobalt, nickel-molybdenum, or nickel-copper); selecting the catalyst grain size to lie within a chosen range, such as about 50 to 1000 nanometers, or any of the sub-ranges set forth herein, including ranges greater than 3000 nanometers and ranges of about 50 to 150 nanometers, 150 to 300 nanometers, 300 to 450 nanometers, or 450 to 600 nanometers; selecting the catalyst deposition method to set catalyst microstructure; pre-patterning the catalyst layer or the carbon source film to define engineered pore arrays, engineered edges, and engineered grain sizes; selecting the type, thickness, and heteroatom content of the carbon source film (for example, an amorphous carbon, a polymer such as polyacrylonitrile or melamine to introduce nitrogen, or a boron-containing precursor) to set thickness, vacancy density, and substitutional dopant content of the resulting graphene film; selecting the heating temperature, time, ramp profile, cool profile, and ambient (vacuum, argon, low-hydrogen, or trace oxygen); and where pressure is applied, selecting the pressure value (for example, from a few megapascals to greater than 1 gigapascal), the pressure waveform (uniaxial or isostatic), and the timing of pressurization and depressurization relative to heating and cooling. In implementations in which mechanical pressure is not applied, the same set of growth knobs other than pressure is available, and dewetting of the catalyst (for example, of the nickel catalyst) provides an additional knob for the population, size, and spatial distribution of vacancies, pores, and islands in the resulting film.

At optional step 630, a post-growth defect engineering treatment may be performed on the graphene film. The post-growth treatment is, by way of example, plasma treatment (oxygen, argon, nitrogen, ammonia, or hydrogen plasma); oxidation followed by reduction; chemical etching (for example, with ferric chloride, nitric acid, sulfuric acid, potassium permanganate, or ozone); electrochemical etching; covalent functionalization with a reactive species (for example, a diazonium salt, an amine, an azide, or an acyl group); ion or electron beam irradiation; thermal annealing in a reactive atmosphere where the thermal budget allows; laser ablation; lithography followed by etching to define a pore array; template-assisted etching (using a block-copolymer, colloidal, nanosphere, or anodized-alumina template); intercalation followed by removal; or strain engineering, alone or in combination. The post-growth treatment is selected to introduce a chosen distribution of vacancies, Stone-Wales defects, grain boundaries, nanopores, micropores, edge defects, or substitutional sites, and to leave a target nucleation surface on the graphene film for the second material that will be grown at step 640. In implementations directed to BEOL integration, the post-growth treatment is selected from those compatible with a thermal budget of less than or equal to about 400 to 500 degrees Celsius.

At step 640, a second material may be grown or deposited on the graphene film. The second material is, in implementations, a III-nitride semiconductor (for example, gallium nitride, aluminum nitride, indium nitride, indium gallium nitride, or aluminum gallium nitride), a group-IV semiconductor (for example, germanium or silicon), a III-V semiconductor (for example, gallium arsenide), an oxide or nitride dielectric (for example, silicon dioxide, aluminum oxide, hafnium oxide, or silicon nitride), a metal, or a two-dimensional material. The second material is grown or deposited by metal-organic chemical vapor deposition, chemical vapor deposition, low-pressure CVD, plasma-enhanced CVD, molecular beam epitaxy, atomic layer deposition, sputtering, or evaporation. The second material nucleates on the graphene film by one or more of: covalent nucleation at vacancies; polar nucleation at substitutional or functionalized sites; line nucleation at grain boundaries or engineered edges; and remote or pinhole epitaxy through nanopores in the graphene film. At optional step 650, further device processing is performed, including by way of example contact metallization, additional dielectric layers, or, where desired, release or lift-off of the second material at the graphene interlayer.

In implementations, a single process 600 includes both growth-time defect engineering at step 620 and post-growth defect engineering at step 630, in any combination. By way of example, a pre-patterned solid-phase diffusion at step 620 establishes a coarse engineered pore array, and a brief oxygen-plasma exposure at step 630 introduces a sub-percent density of polar sites in the inter-pore regions to support both remote epitaxy registration through the pores and polar nucleation across the inter-pore basal plane.

### Synthesis and Application Of Single (SLG), Few (FLG) or Multilayer Graphene (MLG) Films on Battery Separator Materials

Some implementations relate to battery technology and, more particularly, to the synthesis and application of few-layer (FL) or multilayer graphene (MLG) films on separator materials, including garnet-type ceramics such as lithium lanthanum zirconium oxide (LLZO), to protect surface, enhance interfacial compatibility, mechanical integrity, improve solid-electrolyte interfacial (SEI) resistance, and processing versatility.

Electrochemical energy storage systems—such as alkaline, lithium-ion, sodium-ion, magnesium and aluminum-ion, nickel-metal hydride (NiMH), lead-acid, zinc-based, redox flow, lithium-sulfur, hydrogen fuel cells, graphene and silicon-carbon, seawater, glass, airflow and other types of batteries—play a crucial role in modern life. Their performance, safety, and longevity are heavily influenced by the properties of internal components. One essential component is the separator, which electrically isolates the anode from the cathode while enabling ionic transport through the electrolyte.

However, separators also present challenges, including: high interfacial resistance with electrolytes or cathode materials; poor mechanical compliance during cycling; difficulty in achieving intimate contact with electrodes during assembly; sensitivity to moisture and oxygen during processing and handling; and formation of gaseous phases during cycling or formation of solid-electrolyte interface (SEI), etc.

FLG/MLG, chemically inert and highly impermeable, is known for its excellent chemical and thermal stability, low surface energy, and non-stick characteristics.

Accordingly, a method is provided for applying ultra-thin MLG films on battery separators (e.g., LLZO) to serve as a surface interlayer, improving interfacial contact, reducing dendrite penetration, and enabling easier processing of battery cells, including solid-state and non-solid-state battery cells.

Methods are provided for depositing thin MLG films—on the order of nanometers to low micrometers—onto battery separators such as LATP, LLZO, or another separator material. The coating serves as a functional interlayer to: reduce interfacial resistance at the cathode-electrolyte-separator interfaces; provide a flexible mechanical buffer between lithium metal and rigid ceramics; mitigate dendrite formation and penetration; improve moisture resistance and shelf stability; allow reduction in thickness of the separators; and allow easier lamination during cell assembly without high temperature or high pressure.

For one embodiment, the battery is a solid-state lithium-ion battery. For another embodiment, the battery can be another type of solid-state battery. For another embodiment, the battery can be a non-solid-state battery.

The use of single/few-layer/multi-layered graphene (1LG/FLG/MLG)/functionalized graphene is contemplated, with or without intrinsic and/or intentional defects/discontinuities, with or without intercalation doping, that is grown/transferred on the battery separator materials (with possible addition of adhesive Li-ion conductive glue) to bind the cathode to the separator. For example, the configuration for one embodiment is Separator/MLG/Lithium Polyacrylate/Cathode.

For one embodiment, the battery is a solid-state lithium-ion battery. For another embodiment, the battery can be another type of solid-state battery. For another embodiment, the battery can be a non-solid-state battery.

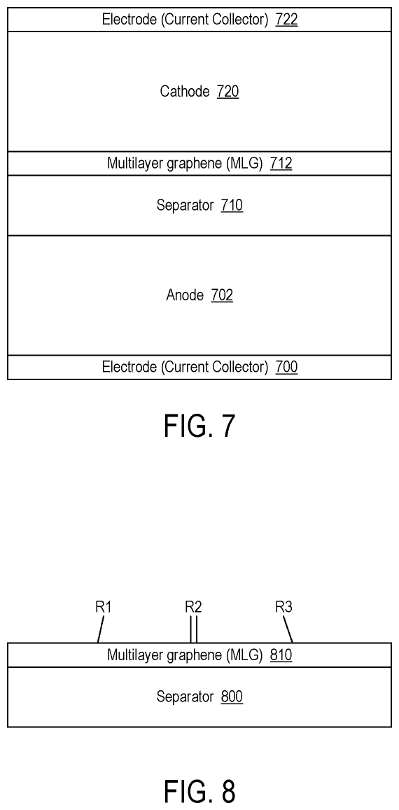

FIG. 7 is a schematic representation of a battery layout with MLG grown/transferred onto a separator (a list of possible separators is provided below). FIG. 7 illustrates a representative battery cell assembly in which the graphene-based interlayer (712) is disposed on the cathode-side major surface of the separator or solid electrolyte (710). An anode active material layer (702) is supported on an anode current collector (700). The separator (710) electrically isolates the anode from the cathode while conducting lithium ions through its bulk. The graphene-based interlayer (712) is positioned between the cathode-facing surface of the separator (710) and the cathode composite (720), which is in turn supported on a cathode current collector (722). An optional lithium-ion-conductive adhesive layer may be interposed between the graphene-based interlayer (712) and the cathode composite (720), serving to mechanically and ionically bind those layers during assembly. The graphene-based interlayer (712) reduces interfacial resistance, provides mechanical compliance during cycling, and suppresses dendrite penetration.

FIG. 8 is a schematic representation of MLG with possible functional groups (listed further below) relative to the separator. FIG. 8 illustrates the surface chemistry of the graphene-based interlayer at the separator interface. The separator bulk (800) and its cathode-facing surface are shown in relation to one or more graphene sheets (810) disposed thereon. A variety of covalent and non-covalent functional groups (represented as “R1,” “R2,” “R3”), including hydroxyl, carboxyl, sulfonic acid, amine, and pyrene-based modifiers, may be present on the graphene surface. These functional groups tune the wettability, adhesion, and ionic compatibility of the graphene-based interlayer with adjacent electrode and electrolyte materials.

### Substrate Material:

The substrate is a thin film of material, serving as a separator between cathode and anode of battery, and may be in the states of glass, crystal or polycrystalline sintered or tape-cast ceramic solid-state electrolyte, including: LATP (Li_{1.3}Al_{0.3}Ti_{1.7}(PO₄)₃); LAGP (Li_{1.5}Al_{0.5}Ge_{1.5}(PO₄)₃); Cubic or tetragonal LLZO (Li₇La₃Zr₂O₁₂), doped with Al, Ta, or Ga; Polyethylene oxide (PEO); Polypropylene (PP); Polyvinyl chloride (PVC); or other polymers, polymer composite materials, oxide or phosphate-based inorganic solid electrolytes.

### MLG Coating Methods:

1. Low temperature direct synthesis of MLG on separator: An ultra-thin layer of a carbon source material (such as amorphous carbon) deposited on top of a sacrificial metal layer (such as nickel) is subjected to pressure and temperature to allow diffusion of carbon atoms into the metal layer and subsequent segregation forming high-quality graphene or FLG/MLG directly on top of the separator substrate. Any remaining carbon source material and the sacrificial metal layer are removed via etching.
2. Solvent Dispersion Coating: A dilute MLG dispersion (0.1-2 wt %) in water or alcohol is spray-cast or dip-coated onto the ceramic surface. Post-treatment at 200-250 °C ensures film adhesion and partial sintering of the MLG particles.
3. RF Plasma Polymerization: A vapor-phase MLG-like film is deposited via plasma-enhanced chemical vapor deposition (PECVD) using fluorocarbon gases (e.g., CF₄ or C₂F₆) under controlled radio frequency (RF) conditions. This method creates a pinhole-free, ultrathin film (<200 nm) with uniform coverage.
4. Langmuir-Blodgett or Spin-Coating: For high uniformity, MLG is suspended in an amphiphilic solvent and applied via spin-coating, followed by a drying and annealing step at moderate temperature.
5. Roll-to-roll MLG transfer: Polymer film with MLG is pressed onto the ceramic surface at room or elevated temperatures with subsequent peeling or dissolution of the polymer film.
6. CVD synthesis of MLG on battery separator: Direct growth of MLG on the separator substrate is performed using low or high temperature Chemical Vapor Deposition (CVD) synthesis methods, including Plasma Enhanced CVD.
7. Other MLG synthesis methods with MLG transfer on the cathode side of battery separator.

### Film Thickness and Properties:

Thickness: 0.3 nm to 1 μm.

Surface energy lowered, enabling improved lithium wetting.

### Performance Improvements:

Electrochemical Impedance: Interfacial resistance reduced by up to 80%.

Battery cycling: Reduced area-specific resistance (ASR) growth and capacity fade related to the cathode/separator delamination.

Battery Assembly: Lower stack pressure required for interfacial contact.

Dendrite Suppression: Coated LLZO shows no short-circuiting in symmetric Li cells over 1000 hours at 0.5 mA/cm².

### Covalent Functionalization

These groups form strong covalent bonds with graphene (typically via defects, edges, or through reactions with graphene oxide or reduced graphene oxide).
1. Oxygen-containing Groups (common in graphene oxide): Hydroxyl (—OH), Epoxide (—O—), Carbonyl (C═O), Carboxyl (—COOH).
2. Nitrogen-containing Groups: Amine (—NH₂), Imine (—C═NH), Amide (—CONH₂), Nitrile (—C≡N), Azide (—N₃) (used in click chemistry).
3. Sulfur-containing Groups: Thiol (—SH), Sulfonic acid (—SO₃H), Sulfide (—S—).
4. Halogens: Fluoro (—F), Chloro (—Cl), Bromo (—Br), Iodo (—I).
5. Aromatic or π-systems: Aryl diazonium salts (—ArN₂⁺) (react via radical addition to graphene's-system).

### Non-Covalent Functionalization

These groups interact via π-π stacking, hydrogen bonding, or van der Waals forces (no disruption of graphene's conjugated structure):
6. π-π Interacting Groups: Pyrene derivatives (e.g., 1-pyrenebutyric acid), Porphyrins, Phthalocyanines.
7. Surfactants/Polymers: Polyethylene glycol (PEG), Polystyrene sulfonate (PSS), Polyaniline, Polyvinylpyrrolidone (PVP).
8. Biomolecules: DNA/RNA, Proteins/Peptides, Carbohydrates, Lipid molecules.

Functionalization Techniques Often Involve: Click chemistry (azide-alkyne cycloaddition), Amidation or esterification, Radical addition (from diazonium salts or thermal treatment), Nucleophilic substitution

Battery Separator materials

Oxide-Based Solid Electrolytes—These are ceramic materials with high electrochemical stability and good mechanical strength.
a. Garnet-Type Oxides (Li⁺ conductors): Li₇La₃Zr₂O₁₂ (LLZO), Li_{6.5}La₃Zr_{1.5}Ta_{0.50}O₁₂ (LLZTO), Li₇La₃Zr_{1.5}Nb_{0.50}O₁₂ (LLZNO).
b. Perovskite-Type Oxides: Li₃xLa(⅔)—xTiO₃ (LLTO), Li_{1/2-3/4}La_{1/4-1/2}TiO_{3.}
c. NASICON-Type Oxides: Li₁+xAlxTi₂−x(PO₄)₃ (LATP), Li₁+xAlxGe₂−x(PO₄)₃ (LAGP).
2. Sulfide-Based Solid Electrolytes—These have very high Li⁺ conductivity but can be sensitive to moisture and reactive with lithium metal.
a. Argyrodite-Type Sulfides: Li₆PS₅Cl, Li₆PS₅Br, Li₆PS₅I.
b. Thio-LISICON-Type Sulfides: Li₁₀GeP₂S₁₂ (LGPS), Li₁₀SnP₂S₁₂ (LSPS), Li₁₁Si₂PS₁₂.
c. Glassy Sulfides: Li₂S—P₂S₅ glass, Li₂S—-SiS₂—P₂S₅ systems.
3. Halide-Based Solid Electrolytes—These are emerging materials with good electrochemical stability, especially for high-voltage cathodes. Examples include: Li₃InCl₆, Li₃YCl₆, Li₃ErCl₆, Li₃ScCl₆, Li₃YBr₆.
4. Polymer-Based Solid Electrolytes—Used often in quasi-solid or hybrid solid-state batteries; they are flexible and processable.
a. PEO-Based Electrolytes: Polyethylene oxide (PEO)+Li salts (e.g., LiTFSI).
b. PMMA, PAN, PVDF-HFP-based Electrolytes. Often blended with ceramic fillers (e.g., LLZO, LATP) for better performance.
c. Ionogel or Gel Polymers: Polymers incorporating ionic liquids or liquid plasticizers.
5. Composite Electrolytes—These are combinations of ceramics+polymers to combine the best properties of both. Examples include: LLZO+PEO, LATP+PVDF, Sulfide glass +polymer blends.

In some implementations, a method of using an MLG film on a battery separator cathode side comprises: (a) providing a solid ceramic separator substrate selected from a group consisting of LATP, LAGP, LLZO, or LLTO; (b) synthesizing an MLG coating via low temperature BEOL compatible MLG synthesis directly on the substrate to form a thin conformal MLG film having a thickness from 0.3 nm to 1 μm; (c) thermally and chemically treating the coated substrate to modify MLG surface improving resistivity, adhesion, wettability, and roughness. In some implementations, the battery is a (e.g. lithium-ion) solid-state battery or a non-solid-state battery.

In some implementations, a method of using an MLG film on a battery separator cathode side comprises: (a) providing a solid ceramic separator substrate selected from a group consisting of LATP, LAGP, LLZO, or LLTO; (b) applying an MLG coating via roll-to-roll transfer, solution-based dispersion, radio frequency (RF) plasma polymerization, chemical vapor deposition (CVD) synthesis, spin-coating, or another MLG synthesis method with MLG transfer; (c) thermally and chemically treating the coated substrate to modify MLG surface improving resistivity, adhesion, wettability, and roughness, the film having a thickness from 0.3 nm to 1 μm. In some implementations, the battery is a (e.g. lithium-ion) solid-state battery or a non-solid-state battery.

A method is disclosed for the synthesis and application of thin multilayer graphene (MLG) films onto battery separator materials, including LATP, LAGP, LLZO, LLTO, and other ceramic electrolytes. The types of batteries can include solid-state, lithium-ion solid state, and non-solid state. The MLG coating—applied through low temperature synthesis, roll-to-roll transfer, solution-based dispersion, radio frequency (RF) plasma polymerization, chemical vapor deposition (CVD) synthesis, spin-coating, or another MLG synthesis method with MLG transfer—forms a conformal interfacial layer that reduces interfacial resistance with cathode materials and lithium metal; enhances mechanical compliance, cycling performance, and adhesion of the separator to the cathode; and improves environmental stability. Batteries using the coated separators exhibit reduced area-specific resistance (ASR) growth and capacity fade related to the cathode-separator delamination; improved assembly compatibility; and extended cycle life.

### Defect-Engineered Multilayer Graphene for Battery Separator Applications

### Battery Functions and Defect Engineering

The MLG layer of this disclosure can be configured to perform at least six functions within the cell. Each function corresponds to one or more film-property targets set by selecting defect types and densities within the MLG. Defects need not be uniform across the film. In some implementations, defects are concentrated at the bottom face for adhesion to the separator, at sparse engineered locations within the basal plane for lithium-ion transport, and at the top face for adhesion to the overlying binder or cathode; the basal plane is otherwise left close to pristine. Also, the in-plane versus out-of-plane performance can be optimized for cell function. For example, the MLG can be configured to be a good in-plane electronic conductor (for lateral current homogenization across the separator face), a poor out-of-plane electronic conductor (high through-thickness dielectric strength, preventing cathode-to-anode leakage), a controlled lithium-ion permeator only at engineered defect sites, and a good in-plane heat spreader. Defect-engineering levers that boost the in-plane response without proportionally degrading the out-of-plane response—or vice versa—are the localized, top-surface-only, and buried-only treatments described herein.

### Interfacial Resistance Reduction

In one implementation, the MLG layer is configured to reduce interfacial resistance at the cathode/electrolyte and electrolyte/anode interfaces. The relevant property targets are adhesion to the oxide separator surface, thermal boundary resistance, in-plane sheet resistance, and lithium-ion permeability through engineered defects.

Sub-percent vacancy density at the bottom (separator-facing) face is the primary lever. Vacancy-decorated MLG bonds covalently to LLZO surface lattice oxygen, surface hydroxyl groups, or surface lithium cations; covalent contact patches lower thermal boundary resistance by approximately an order of magnitude relative to a purely van der Waals interface. Vacancies are also the simplest mechanism for lithium-ion permeability: pristine basal graphene presents a barrier of approximately 10 eV; a divacancy lowers this to approximately 0.7-1.0 eV; a hexavacancy or larger void is essentially transparent. A sparse, uniform vacancy decoration at sub-percent area density—limited to small clusters of missing atom—provides sufficient lithium-ion flux for typical current densities without compromising mechanical or electronic-spreading function.

Substitutional nitrogen and oxygen dopants (1-2 atomic percent) are secondary levers. Nitrogen's lithium affinity and polar character lower interface impedance further than vacancies alone, with combined nitrogen and oxygen substitutional content capable of reducing interfacial impedance by 50-80 percent relative to pristine MLG. Edge defects at pore rims provide additional polar anchor sites.

Vacancy density must be kept in the sub-percent, small-cluster regime. Vacancy clustering, produced by heavy plasma or graphene-oxide reduction routes, degrades in-plane modulus and yield strength and provides through-thickness electronic conduction paths.

Process recipes producing isolated vacancies (low-dose plasma, low-temperature solid-phase diffusion with a controlled carbon-to-nickel ratio) are preferred.

### Flexible Mechanical Buffer

In a further implementation, the MLG layer is configured to provide a flexible mechanical buffer between a lithium metal anode and a rigid ceramic separator. The relevant property targets are in-plane Young's modulus, yield strength, in-plane coefficient of thermal expansion (CTE), intrinsic film stress, and substrate warpage. The directional targets are a controlled reduction of in-plane modulus, reduction of thermal-expansion mismatch with the separator, and controlled compressive stress.

LLZO has a Young's modulus of approximately 150 GPa and a CTE of approximately 13-15 ppm/K. Pristine large-grain MLG has an in-plane modulus of approximately 1000 GPa and a CTE of approximately—7 ppm/K. MLG grain size is the master lever for reducing both mismatches. Under Hall-Petch-like scaling, in-plane modulus drops toward 400-600 GPa at nanocrystalline grain sizes; CTE shifts toward zero or slightly positive at grain sizes below approximately 100 nm; and yield strength peaks at moderate grain sizes near 1 μm before falling at nanocrystalline sizes where grain-boundary sliding dominates. Mild controlled porosity (Gibson-Ashby scaling) and substitutional doping provide further independent levers for modulus reduction without requiring a change in grain size.

Smaller grains reduce both thermal-expansion mismatch and in-plane modulus, which is favorable for mechanical buffering, but simultaneously increase grain-boundary area (degrading the moisture barrier) and through-thickness grain-boundary stacking statistics (degrading dendrite resistance). A moderate grain size of approximately 1 μm is the recommended optimum: meaningful thermal-expansion-mismatch reduction and Hall-Petch strengthening while preserving moisture-barrier and dendrite-resistance function.

### Dendrite Mitigation

In a further implementation, the MLG layer is configured to mitigate dendrite formation and penetration. The relevant property targets are in-plane yield strength, out-of-plane dielectric strength, pore-size distribution, and in-plane current-homogenization capability. The directional targets are increased yield strength and out-of-plane dielectric strength, with no through-thickness electronic short, and sufficient in-plane conductivity for lateral current spreading.

The primary lever is avoiding large pores and suppressing vertically stacked grain-boundary paths, which constitute the dominant through-thickness electronic breakdown mechanism. Through-thickness grain-boundary leakage is the dominant breakdown mechanism in CVD-style MLG, and a through-thickness electronic path is functionally equivalent to a dendrite-mediated failure. A Hall-Petch-optimal grain size of approximately 1 μm—large enough that grain boundaries in successive layers are unlikely to align—provides the best balance. MLG thickness is a secondary lever: in a thicker film, the probability of a fully through-thickness grain-boundary path falls exponentially with layer count.

Sparse isolated vacancies (sub-percent area density, non-overlapping across layers) do not significantly degrade in-plane modulus or yield strength and do not provide an electronic short. The critical failure mode is vacancy clustering; process recipes producing isolated vacancies are therefore preferred over recipes producing vacancy networks (heavy plasma, graphene-oxide reduction routes, ball-milled flake assembly).

Catalyst microstructure directly sets MLG grain size and boundary registration. Small-grain sputter-deposited nickel produces high-grain-boundary-density MLG with vertically stacked boundaries—worst case for dendrite resistance. Large-grain thermally evaporated nickel produces the best case.

Grain size, grain-boundary stacking, and film thickness are jointly optimized. The recommended operating point is approximately 1 μm grain size, 50-500 nm film thickness, and catalyst pre-annealing to suppress stacked boundaries. Any implementation requiring sub-100 nm grain sizes for mechanical buffering must compensate with increased film thickness to maintain acceptable through-thickness dielectric strength.

### Moisture and Oxygen Barrier

In a further implementation, the MLG layer is configured to provide a moisture and oxygen barrier and extend cell shelf stability. The relevant property targets are in-plane porosity, grain-boundary network connectivity, and substitutional dopant content (oxygen heteroatoms are reactive with ambient moisture).

This function calls for fewer defects overall: large MLG grains, healed vacancies, and minimal porosity. Large-grain MLG (grain size>>1 μm) is qualitatively a much better moisture barrier than nanocrystalline MLG, as grain-boundary networks provide diffusion paths for small molecules. This trade-off points in the same direction as the dendrite-mitigation trade-off and is the strongest single argument for tuning the catalyst toward large grains.

Where vacancies are intentionally populated for lithium-ion transport, they can be passivated for shelf stability: in one implementation by a low-temperature hydrogen anneal; in a further implementation by aryl diazonium functionalization with a stable organic group; in a still further implementation by an aluminum oxide overcoat.

The moisture-barrier function pulls against the interfacial-resistance function (which calls for more vacancies) and the mechanical-buffer function (which calls for smaller grains). These tensions are resolved by the localized-defects principle: vacancy concentration at the faces only, not uniformly through the bulk, and by the grain-size sweet spot at approximately 1 μm.

### Thinner Separator Enablement

In a further implementation, the MLG layer assumes a substantial fraction of the dendrite-blocking and mechanical-support duty otherwise performed by a thicker separator, enabling use of a thinner separator. The relevant property targets are in-plane yield strength, out-of-plane dielectric strength, in-plane modulus, and pore-size distribution.

This function has the most demanding property targets, since every defect that degrades dielectric strength or opens a pore pathway is directly relevant. The recommended recipe is a film at the thicker end of the disclosed range (50-500 nm) with a moderate grain size (~1 μm), healed native vacancies (hydrogen-anneal post-treatment), and only sub-nanometer vacancy-class defects for lithium-ion permeability. Hall-Petch tuning of grain size provides the yield-strength lever; suppression of large pores and through-thickness grain-boundary paths provides the dielectric-strength lever.

### Lamination Facilitation

In a further implementation, the MLG layer is configured to permit lower-temperature and lower-pressure cell lamination during stack assembly. The relevant property targets are adhesion to the oxide separator on the bottom face and adhesion to the next layer (lithium polyacrylate, a lithium-ion-conductive adhesive, or a cathode binder) on the top face.

On the bottom face, the vacancy and substitutional-dopant population used for interfacial resistance reduction (Section 3.1) also provides the adhesion lever; no additional treatment is required. On the top face, the dominant levers are top-surface substitutional dopants or covalent functional groups installed by post-growth treatment. A brief oxygen-plasma treatment (5-20 W RF, approximately 10-20 seconds) is the production-scale process: it installs surface hydroxyl and carboxyl groups that hydrogen-bond to lithium polyacrylate and other polymer binders without perforating the underlying bulk. Edge defects at pore rims provide supplementary adhesion where engineered pores are present.

Plasma dose on the top face must be kept short (≤30 seconds at low power) to avoid film perforation. Where the MLG is very thin (monolayer to trilayer), aryl diazonium functionalization is preferred over plasma because it installs organic groups without generating through-film vacancies.

### Solid-Phase Diffusion

Solid-phase diffusion is contemplated as a tunable technique. The substrate is LLZO, or alternatively LATP, LAGP, or LLTO. Every defect class is addressable through process knobs, so defect engineering is integrated into synthesis rather than added as post-processing.

Nickel is the recommended baseline catalyst metal: high carbon solubility, fast MLG growth, and MLG thickness controllable through cooling rate. Nickel-molybdenum and nickel-copper alloys reduce thickness-uniformity variance and are useful where separator uniformity is a manufacturing constraint. Catalyst etchants must be compatible with the separator: iron(III) chloride for nickel is largely benign on LLZO; hydrochloric-acid-based etchants for cobalt can leach lithium from LLZO surface layers and require separate qualification.

Catalyst microstructure is a knob for MLG grain size. Thermally evaporated nickel produces the largest grains (approximately 1 μm or larger) and lowest defect density and is preferred, yielding large-grain MLG that matches the mechanical-buffer and moisture-barrier optimum. Sputter-deposited nickel produces small, high-grain-boundary-density grains, maximizing both the through-thickness leakage failure mode and the moisture-barrier failure mode; it is to be avoided as a primary catalyst form. A pre-anneal of a sputtered or e-beam nickel film at 400-500 °C in an inert atmosphere before carbon segregation grows the nickel grains to near-thermally-evaporated quality without the more expensive deposition equipment; this is the recommended production-scale route.

Pure amorphous carbon (sputter or e-beam deposited) as the carbon source is the baseline and produces undoped MLG; post-growth plasma is then required for nitrogen or oxygen doping, introducing additional vacancies as a side effect. Polyacrylonitrile and melamine introduce nitrogen during segregation in one step and are recommended where interface impedance is the dominant figure of merit. Sucrose, glucose, and other oxygen-containing precursors introduce oxygen during segregation and are recommended where binder adhesion is the bottleneck. Self-assembled aromatic monolayers produce monolayer or bilayer graphene useful for the thinnest end of the disclosed range, but defect density is typically high; suitable only where the MLG is overcoated by a compensating layer.

Temperature: for example 450 °C is within LLZO's thermal-stability envelope (stable to approximately 600 °C in dry inert atmosphere). LATP and LAGP tolerate 400-450 °C Polymer separators (polyethylene oxide, polypropylene) limit process temperature to 100-200 °C, requiring an alternative method.

Pressure: a few MPa is routine and compensates for lower temperature. Higher pressures (up to approximately 1 GPa) require specialized equipment but enable still-lower process temperatures.

Dwell: 30-60 minutes at 450 °C and a few MPa yields a continuous film with sparse vacancy decoration, depending on the catalyst-and-precursor combination. A short dwell gives incomplete segregation (vacancies, partial pores, Stone-Wales defects); a long dwell gives a continuous film with larger grains.

Atmosphere: vacuum or inert (argon) for the cleanest result. A low hydrogen partial pressure during dwell etches vacancies closed, producing near-defect-free MLG useful when post-growth plasma is to install the defects.

Plasma treatment and chemical functionalization are important complementary techniques: both operate at or near room temperature and are production-mature.

Mild oxygen plasma applied to the top surface after segregation (5-20 W RF, approximately 10-20 seconds) installs surface vacancies and hydroxyl or carboxyl groups for binder adhesion. Doses above approximately 30 seconds begin to perforate the film and are avoided.

Brief nitrogen or ammonia plasma after segregation installs surface nitrogen where the Method 1 carbon source is generic amorphous carbon.

Aryl diazonium functionalization installs designed organic groups on the basal plane at room temperature, with no associated through-film pores. Preferred where plasma damage is unacceptable (very thin MLG) or where atomic-layer-deposition compatibility at 200-300°C is required.

### MLG as a Substrate for Subsequent Battery Materials

The MLG of this disclosure can be a buried interlayer beneath one or more additional battery-material layers. Pristine MLG's sp2 basal plane offers no chemisorption sites, resulting in polymer binder dewetting, filamentary lithium plating, island-mode atomic-layer deposition nucleation, and poor cathode-slurry wetting. The corrective action in each case is to install the right defect type at the right density to convert the MLG into a designed nucleation surface.

Various nucleation mechanisms are available: (1) covalent nucleation at monovacancies or divacancies; (2) polar nucleation at substitutional or functionalized sites (nitrogen, oxygen, hydroxyl, carboxyl, amino groups); (3) line nucleation at grain boundaries and edges; and (4) remote or pinhole epitaxy through nanopores of 5-50 nm. Remote epitaxy requires pores that fall in the dendrite-shorting failure regime and is largely incompatible with the disclosed stack. The dominant mechanism for the stack as disclosed (polymer binder above the MLG, cathode above the binder) is polar nucleation. Where lithium metal contacts the MLG directly, covalent nucleation is required.

### 5.1.1 Lithium Polyacrylate (Disclosed Binder)

Lithium polyacrylate has pendant carboxylate-lithium groups on every monomer and is the disclosed binder between the MLG and the cathode. The defect-engineering target is a uniform polar MLG surface with a high density of carboxyl or hydroxyl groups ready to hydrogen-bond with the polyacrylate.

In a first implementation, a brief oxygen-plasma exposure (5-20 W RF, approximately 10-20 seconds) is applied to the top surface immediately before deposition. A few atomic percent of surface oxygen is installed without measurably affecting the buried bulk.

In a second implementation, aryl diazonium chemistry using carboxyl-terminated aryl groups is used where plasma perforation risk is unacceptable (e.g., very thin MLG).

In a third implementation, the MLG is grown one or two layers thicker than the functional target, and the top layers are aggressively functionalized while the buried layers remain pristine; this gives the best bulk-property retention and is preferred for highest-performance implementations.

### Cathode Active Material (NMC, LFP, LCO)

Where the cathode active material contacts the MLG directly (without an intervening binder), the dominant nucleation mechanisms are polar nucleation (metal-oxygen-carbon bonds at substitutional or functionalized sites) and line nucleation (cathode-particle adhesion at grain boundaries or edges). A brief oxygen plasma installs polar sites; a moderate grain size of approximately 100 nm to 1 μm provides line-nucleation density while remaining within the moisture-barrier optimum.

### Lithium Metal (Anode Side)

Lithium metal nucleates covalently (covalent at vacancies). Vacancies without polar decoration are required: polar groups (hydroxyl, carboxyl) form solid-electrolyte-interphase components (lithium oxide, lithium hydroxide, lithium carbonate) that raise impedance over cycle life.

In a first implementation, mild argon plasma at low RF power for several seconds installs clean vacancies without polar functionalization.

In a second implementation, solid-phase diffusion (Method 1) with a sub-optimal carbon-to-nickel ratio produces as-grown sparse vacancy decoration without post-treatment. This is the cleanest process-flow option and a strong argument for Method 1 as the integrated defect-engineering route: the same growth step that produces the MLG also produces the anode-friendly vacancy decoration.

### Atomic-Layer-Deposition Oxide and Nitride Protective Layers

In a first implementation, a brief oxygen plasma immediately before atomic-layer deposition—dose calibrated per precursor (approximately 5 seconds for trimethyl aluminum; approximately 10 seconds for tetrakis(dimethylamido)hafnium)—ensures continuous nucleation in the first few cycles, eliminating pinhole admission of electrolyte to lithium metal beneath.

In a second implementation, hydroxyl-bearing aryl diazonium functionalization is used where plasma damage to the MLG is unacceptable. The atomic-layer-deposited film then provides a chemically robust barrier between the lithium metal and the MLG, resolving the polar-group-lithium-metal incompatibility noted in Section 5.1.3.

### Solid Polymer Electrolyte (PEO, PVDF-HFP)

The recipe is the same brief oxygen-plasma top-surface treatment as for lithium polyacrylate. For polyethylene oxide, a higher polar-group density improves adhesion and interface integrity at a modest cost to lithium-ion mobility in the first few nanometers near the interface; this trade-off generally favors a higher density.

### Sulfide Electrolytes

Polar oxygen doping or hydroxyl functionalization is counterproductive for sulfide electrolytes: the oxide-like surface chemistry reacts with the sulfide, producing hydrogen sulfide and degrading the electrolyte. The target is clean vacancies installed by argon plasma or as-grown from covalent nucleation with no polar dopants; adhesion is mediated by carbon-sulfur bonds at vacancy sites.

### Stratified Defect Profile

The three-zone stratified profile is an integrating implementation. On the bottom face (facing the separator), vacancies plus polar substitutional dopants are installed during segregation, bonding the MLG covalently or polarly to the oxide separator. In the middle bulk, the basal plane is left pristine with at most sparse vacancies for lithium-ion transport. On the top face (facing the binder or cathode), polar substitutional dopants or a post-segregation oxygen-plasma treatment anchors the overlying layer. This stratified profile produces a three-layer functional gradient within a single MLG film, with each face engineered for its specific adhesion partner while the bulk preserves in-plane thermal conductivity, electronic conductivity, moisture-barrier function, and out-of-plane dielectric strength.

The estimated property cost of the combined three-zone treatment is less than approximately 20 percent of bulk in-plane thermal conductivity and less than approximately 10 percent of bulk strength, while satisfying substantially all six functions. A top-only oxygen-plasma treatment on a ten-layer film, for example, reduces whole-stack-averaged in-plane thermal conductivity by less than approximately 5 percent-negligible relative to the adhesion function gained.

### Quantitative Trade-Off Framework

Three functions pull on defect density in opposing directions. The lithium-ion permeability target requires vacancies or sub-nanometer pores, pulling toward higher defect density. The moisture and dendrite barrier target requires few large pores and limited grain-boundary connectivity, pulling toward lower defect density (particularly for pores >1 nm). The interfacial adhesion target requires polar or covalent anchor sites at the MLG faces, pulling toward more substitutional, functionalized, edge, and vacancy sites.

These targets are reconcilable because they pull on different defect classes. Lithium-ion permeability is satisfied by sub-nanometer vacancies and small substitutional dopants, with no pores beyond mono-vacancy to hexavacancy size. The moisture and dendrite barrier is satisfied so long as no pores larger than approximately 1 nm are present, no through-thickness grain-boundary stacks are present, and no large flake-to-flake junctions are present. Adhesion is satisfied by vacancies, substitutional dopants, and edge defects, all at sub-nanometer scale. The defect classes that satisfy all three simultaneously are sub-nanometer vacancies, substitutional dopants, and edge defects. The defect classes to avoid are large pores (>1 nm), large through-thickness grain-boundary networks, and aggressive functionalization that perforates the basal plane.

The pore-size design rule that follows is to maximize the density of sub-nanometer vacancy-class defects and suppress the density of all pores beyond hexavacancy size. The target is approximately 0.1 to 1 percent vacancy area fraction with no larger pores.

The disclosed MLG thickness range (0.3 nm to 1 μm) covers approximately four orders of magnitude. At the thinnest end (monolayer to trilayer), defect-engineering trade-offs are sharper because there is no bulk to compensate for surface treatment; every defect class trades sharply against function. A recommended practical regime is 50-500 nm, where stratified defect engineering is straightforward, the trade-offs between defect classes are minimal, and a top-only plasma treatment has negligible whole-stack-averaged property cost. The thinnest regime (one to three layers) can be recommended where thinness is itself an essential design requirement.

### Property-Cost Summary

Top-monolayer oxygen-plasma treatment for binder adhesion (5-20 seconds, 5-20 W RF, on a ten-layer MLG film): no more than approximately 5 percent of film-averaged in-plane thermal conductivity, no more than approximately 5 percent of strength, negligible out-of-plane dielectric strength reduction. Gain: two to five times the pristine MLG adhesion to lithium polyacrylate.

Sparse vacancy decoration at 0.1-1 percent area density: 10-20 percent of in-plane thermal conductivity, 5-10 percent of strength, 10-20 percent of out-of-plane dielectric strength. Gain: lithium-ion flux for battery operation, interfacial impedance reduction, and lithium-metal adhesion.

Uniform nitrogen or oxygen substitutional doping at 1-2 atomic percent (polyacrylonitrile or sucrose carbon source in Method 1): 20-30 percent of in-plane thermal conductivity, approximately 5 percent of strength, 20-30 percent of out-of-plane dielectric strength. Gain: 50-80 percent reduction in interfacial impedance; uniform binder and atomic-layer-deposition adhesion.

Moderate grain size (approximately 1 μm, thermally evaporated or pre-annealed nickel catalyst): 10-20 percent of in-plane thermal conductivity, slight Hall-Petch strength gain, modest out-of-plane dielectric strength reduction. Gain: the identified sweet spot—meaningful mechanical buffering and moisture-barrier preservation simultaneously.

Small grain size (approximately 100 nm, sputter-deposited nickel): 50-70 percent of in-plane thermal conductivity, strength variable under Hall-Petch and grain-boundary weakest-link effects, at least 50 percent of out-of-plane dielectric strength (from grain-boundary shorts). Not recommended as a primary design point; but useful where CTE matching is the overriding constraint, compensated by increased film thickness.

Heavy plasma treatment (60 seconds or more at high power, installing 1-10 nm pores): 50-80 percent of in-plane thermal conductivity, approximately 50 percent of strength, 70-90 percent of out-of-plane dielectric strength—a cell-operation failure mode. To be avoided.

Aryl diazonium top-surface functionalization (1-2 percent coverage): no more than approximately 5 percent of in-plane thermal conductivity, no more than approximately 5 percent of strength, negligible out-of-plane dielectric strength reduction. Gain: two to three times the pristine adhesion to acrylate-class polymers.

In summary, top-only or sparse treatments have negligible property cost. Uniform bulk treatments have moderate and generally tolerable property cost. Aggressive treatments (heavy plasma, small grain size without thickness compensation) are either strictly damaging or introduce trade-offs that must be explicitly justified by function requirements.

### Application: Defect-Engineering for MLG-to-MLG Wafer Bonding

A bonded wafer configuration (e.g. thermal spreader) described herein comprises a first silicon substrate carrying a first MLG film of approximately 40 nm thickness (approximately 120 atomic layers), optionally on a silicon dioxide buffer layer, and a second silicon substrate carrying a corresponding second MLG film, the two films being brought face-to-face and bonded under elevated temperature (typically 200-600 °C) and pressure (e.g. megapascal range). The resulting bonded sandwich comprises approximately 240 internal van der Waals layer-to-layer interfaces distributed across the two films, and one new carbon-carbon bond plane located between them.

In the absence of surface modification, the carbon-to-carbon contact at the bond plane is theoretically held together by van der Waals forces only, with adhesion energy of approximately 0.30-0.40 J/m² and thermal boundary resistance (TBR) of approximately 10-8 to 10-7 m² K/W. Such bonds resist cyclic shear poorly because graphitic layers slide against one another with low friction, and are accordingly inadequate for shear-bearing or thermally-cycled thermal-spreader applications. Two further consequences of the approximately 40 nm thickness inform the embodiments described below: (a) the internal cross-plane thermal resistance per film is comparable to or greater than the bond-plane TBR, particularly in turbostratic films, so the total cross-plane resistance of the bonded stack is not dominated by the bond plane alone; and (b) basal cleavage within either film competes with bond delamination as a failure mode under cyclic shear loading.

A defect-engineering treatment confined to the topmost approximately one to three atomic layers of each 120-layer film modifies approximately 2.5% of the film volume, leaving the bulk in-plane thermal conductivity of the film substantially unchanged. Surface-confined modification is accordingly preferred over bulk modification for any treatment whose purpose is to improve properties of the bond plane.

In one embodiment, each bonding surface is exposed prior to bonding to a brief, low-energy oxygen plasma or ultraviolet-ozone treatment of duration and power calibrated to introduce a surface oxygen content of approximately 1-3 atomic percent confined to the topmost approximately one to three atomic layers of the film. The two activated surfaces are subsequently brought into face-to-face contact and bonded at a temperature of approximately 300-500 °C under a pressure in the megapascal range. Without wishing to be bound by theory, surface oxygen species (hydroxyl, epoxide, and related functional groups) on the two opposing surfaces condense during bonding to form C-O-C ether bridges across the interface. The resulting bond exhibits adhesion energy substantially exceeding the pristine van der Waals baseline, bond-plane TBR reduced by approximately a factor of three to ten relative to van der Waals-only contact, and resistance to cyclic-shear fatigue, because the covalent bridges are not subject to the slip mechanisms that govern van der Waals interface fatigue. The temperature range cited is compatible with typical CMOS back-end-of-line thermal budgets.

The volume argument of the foregoing paragraph presumes confinement of the surface activation to the topmost one to three atomic layers. Plasma treatments at elevated power or extended duration may drive oxygen and vacancies to greater depth within the film, eroding the preservation of bulk in-plane thermal conductivity that motivates surface-confined modification. The plasma chemistry, power, and dose are calibrated for the specific film to maintain the intended surface-confined character of the activation.

In some embodiments, surface activation is performed by brief ion bombardment or low-energy inert-gas plasma rather than by oxygen plasma, introducing point vacancies at densities of approximately 10\hat{ }13 to 10\hat{ }14 cm−2 confined to the topmost approximately one to three layers of each film. Unsaturated bonds at the resulting vacancy sites pair across the interface during bonding under temperature and pressure to form covalent C-C bridges between the two films. Bond adhesion and TBR improvements analogous to those of the oxygen-mediated embodiment are achieved, with the bridges being all-carbon rather than oxygen-mediated. The oxygen-mediated and vacancy-mediated surface activations may be employed independently or in combination.

In some embodiments, controlled inter-layer oxygen incorporation is performed during CVD film growth or by mild post-growth oxidation to distribute sp3 cross-linkers between adjacent basal planes throughout the volume of each film. The resulting inter-layer covalent bridges (a) increase inter-layer phonon coupling, reducing internal cross-plane thermal resistance from turbostratic values of approximately 4−40×10−8 m² K/W toward AB-stacked values of approximately 4−8×10−9 m² K/W, and (b) increase basal cleavage resistance of the film by covalently connecting adjacent basal planes. A single oxygen-incorporation strategy directed at the inter-layer regions of the film therefore addresses both the dominant cross-plane thermal resistance contribution in turbostratic films and the in-film basal cleavage failure mode. This embodiment is combinable with the surface activation embodiment described above, in which case bond plane adhesion, bond-plane TBR, internal cross-plane resistance, and in-film cleavage resistance are addressed simultaneously by oxygen incorporation in two distinct spatial regions of the film.

In some embodiments, each film is subjected prior to bonding to a high-temperature anneal in an inert atmosphere sufficient to promote conversion of turbostratic inter-layer stacking to AB-stacked ordering in at least a portion of the film volume. Increased AB-stacking fraction reduces internal cross-plane thermal resistance toward the AB-stacked range and increases inter-layer cohesion, reducing basal cleavage propensity. Trade-off: the temperatures required to drive substantial turbostratic-to-AB conversion may exceed CMOS back-end thermal budgets; the inter-layer oxygen approach described above proceeds at lower temperatures and may be selected when thermal-budget constraints apply, or used in combination with a limited AB-stacking anneal where thermal budget permits.

For turbostratic films in the approximately 40 nm thickness regime, the internal cross-plane resistance per film is the dominant series contribution to the total cross-plane resistance of the bonded stack, and is comparable to or greater than the bond-plane TBR. Defect-engineering interventions directed at the bond-plane TBR in isolation therefore provide a smaller fractional improvement to total stack cross-plane thermal performance than interventions directed at the internal inter-layer coupling of the films. Inter-layer cross-linking and AB-stacking promotion as described above are accordingly preferred over bond-plane interventions alone when total cross-plane thermal performance is the optimization target. For applications in which mechanical bond strength or shear-cycling reliability is the primary requirement, the surface activation of the bonding interface remains the principal embodiment.

In some embodiments, surface preparation is performed immediately prior to bonding to reduce the density of pores that intersect the bonding surface of either film, including removal of surface adsorbates and particulate contaminants. The surface preparation may be performed within the bonding environment without intervening atmospheric exposure to prevent re-adsorption of contaminants between preparation and bonding. A surface pore at the bond plane eliminates contact area locally, presents an effectively infinite local TBR within the pore (thermal conductivity of air being approximately 0.025 W/mK), and constitutes a Griffith-type flaw whose presence reduces interfacial fracture strength approximately as 1√a, where a is a characteristic flaw dimension.

In the approximately 40 nm thickness regime, pore-related failure separates into two distinct modes addressed by distinct process steps. A surface pore at the bond plane in either film impairs bond adhesion, bond-plane TBR, and bond fracture strength as described above. An inter-layer pore localized between two atomic layers within the interior of a film does not reach the bond plane and does not affect bond properties; however, such an inter-layer pore constitutes a nucleation site for basal cleavage cracks under cyclic shear loading. Inter-layer pore control is addressed by growth-recipe optimization or post-growth annealing directed at reducing internal voids within the film volume, and is performed independently of the surface preparation described above. A single process intervention does not simultaneously address both the bond-plane surface and the interior of the film.

Pore content reduces the effective elastic modulus of the film and the σ×h product that drives bonded-stack warpage according to Stoney's relation, providing warpage relief. However, pore content also increases bond void fraction (surface pores) and basal cleavage initiation density (inter-layer pores). Pore content is therefore not a free design variable; warpage reductions achieved via increased porosity must be weighed against the corresponding adhesion and in-film reliability penalties.

Stoney's relation gives bonded-stack curvature proportional to σ_f×h_f/(E_s×h_s²); at film thickness of approximately 40 nm, the σ×h driving force is approximately one order of magnitude greater than for thin few-layer graphene films at equivalent intrinsic stress. For the symmetric silicon/film-film/silicon sandwich described herein, net curvature is governed by the difference in σ×h between the upper and lower halves of the stack. In some embodiments, CVD growth recipe, post-growth thermal history, surface treatment chemistry, and bonding conditions are applied identically to both wafers of the pair; further, wafers are paired from the same growth run, and pre-bond curvature measurements are optionally used to select wafer pairs with matched pre-bond curvature, so as to minimize residual σ×h asymmetry between the two halves. CTE mismatch with silicon is approximately 1.5 ppm/K for thick graphitic films (in-plane CTE approximately +1 ppm/K), substantially smaller than the approximately 10 ppm/K mismatch characteristic of thin few-layer graphene; defect-driven CTE-modification strategies are accordingly of reduced consequence at the thicknesses described herein.

Patterned graphitic spreader features comprise edges at which basal-plane terminations are exposed to a free surface; these edges constitute initiation sites for fatigue cracks at the bond plane and for basal cleavage cracks within the film. In some embodiments, patterned-feature boundaries are formed with rounded or tapered edge geometry to reduce stress concentration at re-entrant corners. In some embodiments, exposed edge sites are functionalized with hydroxyl or carboxyl groups prior to bonding; functionalized edges form covalent or hydrogen-bonded anchors with the opposing film and with the underlying silicon dioxide surface, providing local adhesion energies of approximately 2-5 J/m² in edge-adjacent bonding regions and simultaneously reducing cleavage initiation propensity at exposed edge basal-plane terminations.

Reduced average in-plane grain size increases the density of grain boundaries and edge sites per unit film area, providing additional reactive sites for cross-bond formation at the bond plane. However, in-plane thermal conductivity scales approximately as 1/grain-size in the small-grain limit, and basal cleavage propensity correlates with turbostratic stacking character that tends to increase as grain size decreases. Bulk grain-size reduction as a primary adhesion-enhancement strategy is therefore not preferred. In embodiments employing the surface activation technique, adhesion enhancement is provided by surface chemistry, allowing bulk grain size to be optimized for in-plane thermal conductivity and for low basal cleavage propensity without competing constraints arising from bond-adhesion requirements.

In some embodiments, the bonded thermal spreader is fabricated by the following process flow applied identically to two silicon wafers of a matched pair: (a) growth of a MLG film of approximately 20-70 nm thickness on a silicon dioxide buffer layer, with grain size selected to favor in-plane thermal conductivity; (b) optionally, a high-temperature anneal in inert atmosphere to promote AB stacking, and/or a controlled mild oxidation to introduce inter-layer sp3 cross-linkers; (c) pre-bond surface preparation to remove adsorbates and minimize the density of surface-intersecting pores; (d) surface activation by brief oxygen plasma or ultraviolet-ozone treatment to introduce approximately 1-3 atomic percent surface oxygen confined to the topmost approximately one to three atomic layers; and (e) bonding of the two wafers face-to-face at approximately 300-500 °C under sub-megapascal to megapascal-range pressure to drive C—O—C bridge formation across the interface. The combined process simultaneously addresses bond adhesion, bond-plane TBR, internal cross-plane resistance, basal cleavage resistance, and bonded-stack warpage.

In a pristine bonded stack, failure under cyclic shear or thermomechanical loading occurs first by interfacial slip and progressive delamination at the bond plane. After surface activation as described above, the bond plane is no longer the weakest interface; the failure mode shifts to the weakest internal van der Waals layer interface within either film, manifested as in-film basal cleavage. After inter-layer cross-linking or AB-stacking promotion as described above, internal cleavage resistance is increased and the relative likelihood of each failure mode shifts accordingly. Reliability optimization for thermal-spreader applications at the thicknesses described herein therefore considers both bond-plane and in-film failure modes, with the dominant mode determined by which combination of the foregoing interventions has been applied.

### Process Integration and Equipment Flexibility

It should be understood that the process operations described herein may be carried out, in whole or in part, by one or more process tools, processing equipment, or apparatus situated in a semiconductor fabrication facility (e.g., a cleanroom environment). Each such process tool may include one or more process chambers, load locks, transfer chambers, factory interfaces, equipment front end modules (EFEMs), and associated hardware and software configured to carry out one or more of the described operations. Examples of such equipment can include, without limitation: deposition equipment (e.g. PVD equipment (e.g. sputter, e-beam thermal evaporation, arc, pulsed laser), CVD equipment (including PECVD, LPCVD, MOCVD), ALD equipment (including thermal, spatial, plasma-assisted, photo-assisted, metal)), etch and removal equipment, thermal and anneal equipment, cleaning and surface preparation equipment, lithography and patterning equipment, ion implantation and doping equipment, wafer and substrate handling equipment, metrology and inspection equipment, etc.

The process tools described herein may each, for example, include one or more of the following subsystems, components, or devices: vacuum pumps (including turbomolecular pumps, cryogenic pumps, dry roughing pumps, and mechanical booster pumps); throttle valves, gate valves, isolation valves, pendulum valves, and pneumatic or piezoelectric valves; pressure gauges and controllers (including capacitance manometers, Pirani gauges, ionization gauges, and baratrons); gas delivery systems (including gas panels, mass flow controllers (MFCs), pressure regulators, gas purifiers, and abatement systems); liquid precursor delivery systems (including direct liquid injection (DLI), vaporizer, and bubbler systems); RF generators and RF matching networks (including 13.56 MHz, 2 MHz, 60 MHz, 27 MHz, 400 kHz, and other frequency generators); DC power supplies and pulsed-DC power supplies; microwave generators; electrostatic chucks (ESCs) and associated DC or AC clamping power supplies; substrate heating systems (including resistive heaters, lamp heaters, and fluid-based heating/cooling systems); backside gas delivery systems (e.g., helium backside cooling); exhaust and abatement systems (including scrubbers, burn boxes, and catalytic abatement); facility connections for process gases, purge gases (e.g., N2, Ar), deionized (DI) water, cooling water, compressed dry air (CDA), and waste treatment; and one or more controllers, processors, or computer systems (including programmable logic controllers (PLCs), microprocessors, and host computers) configured to execute machine-readable instructions for controlling one or more of the foregoing subsystems.

The operations described herein may be controlled by one or more controllers or computer systems associated with the process tools. Such controllers may include one or more processors (e.g., central processing units (CPUs), graphics processing units (GPUs), digital signal processors (DSPs), field-programmable gate arrays (FPGAs), or application-specific integrated circuits (ASICs)), memory (e.g., random access memory (RAM), read-only memory (ROM), flash memory, or non-volatile storage), and input/output (I/O) interfaces. The controller may execute machine-readable instructions, including software, firmware, or programmable logic, stored on one or more non-transitory computer-readable storage media (e.g., hard disks, solid-state drives, optical disks, or flash memory), to cause one or more process tools to carry out the described operations.

In some embodiments, the controller may be communicatively coupled to the process tool or to individual subsystems thereof via one or more wired or wireless communication interfaces (e.g., Ethernet, RS-232, EtherCAT, PROFINET, SECS/GEM, or proprietary protocols). The controller may further be communicatively coupled to a manufacturing execution system (MES), an equipment engineering system (EES), a factory host, an advanced process control (APC) system, a fault detection and classification (FDC) system, or other factory-level computing infrastructure.

A non-transitory computer-readable storage medium, as used herein, may include any tangible medium that is capable of storing instructions for execution by a processor. Examples include magnetic storage media (e.g., hard disk drives and magnetic tape), optical storage media (e.g., CD-ROMs and DVDs), semiconductor storage media (e.g., flash memory, EEPROM, and solid-state drives), and any equivalents thereof.

The individual process steps described herein may be integrated in any suitable order and may be performed in a single process tool, in a cluster tool comprising multiple process chambers served by a common transfer chamber, in a sequence of standalone tools connected by automated substrate transport, or in any combination thereof. In some embodiments, multiple operations may be performed in situ (i.e., within the same process chamber without breaking vacuum or without exposing the substrate to an ambient environment between operations). In some embodiments, a substrate may be transferred between chambers of a cluster tool under vacuum or under an inert atmosphere. In other embodiments, a substrate may be transferred between standalone tools via a factory automation system.

In some embodiments, the described process operations may be performed in a different order than that explicitly described, or certain operations may be omitted, combined, or replaced with alternative operations, without departing from the scope of the invention. Where a sequence of operations is described, it should be understood that intermediate operations not explicitly described (e.g., cleaning, inspecting, measuring, aligning, cooling, or queuing steps) may be performed between the described operations. Where a particular process chemistry, temperature, pressure, flow rate, power level, duration, or other process parameter is described, it should be understood that such parameter may be varied as appropriate for a given application, tool configuration, or substrate type, and that the specific values described are exemplary rather than limiting.

Although the present embodiments have been described with reference to specific example embodiments, various modifications and changes can be made to these embodiments without departing from the broader spirit and scope of the various embodiments. Accordingly, the specification and drawings are to be regarded in an illustrative rather than a restrictive sense.

1. A method, comprising:
forming a graphene film on a first substrate;
engineering defects in the graphene film, the engineered defects comprising at least one of vacancies, Stone-Wales defects, grain boundaries having an engineered grain size, nanopores, micropores, edge defects, and substitutional heteroatoms; and
performing at least one of:
(a) growing a second material on the graphene film, wherein the second material nucleates on the graphene film at locations defined by the engineered defects and forms a substantially continuous film on the graphene film; and
(b) bonding the first substrate to a second substrate or a die via the graphene film or via a material grown on the graphene film, wherein the engineered defects serve as reactive sites to form chemical bonds across a bonding interface established between the graphene film and the second substrate or the die.

2. The method of claim 1, wherein engineering defects in the graphene film comprises tuning the formation or deposition of the graphene film, and wherein tuning the formation or deposition of the graphene film comprises at least one of:
selecting a deposition technique from the group consisting of: chemical vapor deposition (CVD), plasma-enhanced chemical vapor deposition (PECVD), atomic layer deposition (ALD), metal-organic chemical vapor deposition (MOCVD), molecular beam epitaxy (MBE), solid-phase diffusion techniques performed with or without the application of mechanical pressure, sputtering, evaporation, and liquid-phase deposition;
selecting an operation parameter of a deposition or growth step, the operation parameter comprising at least one of: precursor composition, precursor flow rate, plasma power, plasma frequency, substrate temperature, deposition time, heating ramp profile, cooling profile, ambient gas composition, and operating pressure;
modifying a growth-surface or deposition-surface of the first substrate, comprising at least one of: selecting a catalyst metal composition; selecting a catalyst grain size;
selecting a catalyst deposition method; pre-patterning a catalyst layer; and treating a non-catalytic substrate surface with a physical or chemical modification; and
selecting a solid-state carbon source parameter, comprising at least one of: a thickness of a carbon source film, a spatial pattern of a carbon source film, a heteroatom dopant content of a carbon source film, and an applied mechanical pressure during a thermal transformation step.

3. The method of claim 1, wherein engineering defects in the graphene film comprises a post-growth treatment of the graphene film, the post-growth treatment comprising at least one of:
a plasma treatment;
an oxidation;
a chemical etching;
an electrochemical etching;
a covalent functionalization with a reactive species;
an ion or electron beam irradiation;
a thermal annealing in a reactive atmosphere;
a laser ablation;
a lithography followed by an etching;
a template-assisted etching;
an intercalation followed by a removal of an intercalant; and
a strain engineering.

4. The method of claim 1, wherein each step of forming the graphene film, engineering the defects, and at least one of growing the second material and bonding the first substrate is performed at a process temperature of less than or equal to about 450 degrees Celsius such that the method is compatible with a back-end-of-line (BEOL) thermal budget of a previously processed complementary metal-oxide-semiconductor (CMOS) wafer featuring active circuitry.

5. The method of claim 1, wherein forming the graphene film utilizes a solid-phase diffusion technique comprising:
depositing a catalyst metal layer comprising nickel on the first substrate;
depositing a carbon source film;
heating the first substrate, the catalyst metal layer, and the carbon source film to a process temperature of less than or equal to about 450 degrees Celsius such that carbon atoms diffuse through the catalyst metal layer, the catalyst metal layer dewets during the heating, and the carbon atoms segregate as the graphene film at an interface between the catalyst metal layer and the first substrate; and
removing the catalyst metal layer to expose the graphene film on the first substrate;
wherein the heating is optionally performed without applying an external mechanical pressure to the first substrate, the catalyst metal layer, and the carbon source film.

6. The method of claim 5, wherein the dewetting of the catalyst metal layer during the heating tunes at least one of a population, a size, and a spatial distribution of pores or islands in the graphene film, and wherein the engineering of defects in the graphene film comprises selecting a grain size of the catalyst metal layer, prior to the heating, to lie within a range selected from:
about 50 to 100 nanometers; about 100 to 150 nanometers; about 150 to 200 nanometers; about 200 to 250 nanometers; about 250 to 300 nanometers; about 300 to 350 nanometers; about 350 to 400 nanometers; about 400 to 450 nanometers; about 450 to 500 nanometers; about 500 to 600 nanometers; about 600 to 800 nanometers;
about 800 to 1000 nanometers; about 1000 to 1500 nanometers; about 1500 to 2000 nanometers; about 2000 to 3000 nanometers; greater than about 3000 nanometers;
about 50 to 150 nanometers; about 150 to 300 nanometers; about 300 to 450 nanometers; and about 450 to 600 nanometers.

7. The method of claim 1, wherein the second material comprises at least one of a III-nitride semiconductor, a group-IV semiconductor, a III-V semiconductor, an oxide dielectric, a nitride dielectric, a metal, and a two-dimensional material; and wherein growing the second material comprises at least one of metal-organic chemical vapor deposition (MOCVD), chemical vapor deposition (CVD), plasma-enhanced chemical vapor deposition (PECVD), molecular beam epitaxy (MBE), atomic layer deposition (ALD), sputtering, and evaporation.

8. The method of claim 1, wherein the engineered defects comprise an array of nanopores having a pore diameter in a range of about 5 to 50 nanometers, a pore pitch in a range of about 50 to 500 nanometers, and a fill factor in a range of about 1 to 10 percent, and wherein the second material is grown on the graphene film at least in part by remote or pinhole epitaxy through the array of nanopores.

9. The method of claim 8, wherein the first substrate comprises a single-crystal underlayer at locations beneath the array of nanopores in the graphene film, and wherein the second material registers to the lattice structure of the single-crystal underlayer through the array of nanopores while substantially residing on the graphene film, and wherein an inter-pore region of the graphene film between the nanopores remains substantially pristine to provide at least one of a heat-spreading function, a buried-conductor function, and a mechanical-support function in a final device stack that comprises the first substrate, the graphene film, and the second material.

10. The method of claim 1, wherein bonding the first substrate to the second substrate or the die further comprises forming a second graphene film featuring engineered defects on a surface of the second substrate or the die prior to the bonding step, and arranging the first substrate and the second substrate or the die in a face-to-face alignment.

11. The method of claim 1, wherein bonding the first substrate to the second substrate or the die comprises a low-temperature direct fusion bonding process performed at a process temperature between about 150 degrees Celsius and about 450 degrees Celsius.

12. The method of claim 1, wherein the engineered defects comprise functional groups including at least one of hydroxyl (—OH), carboxyl (—COOH), and amine (—NH₂) groups, and wherein bonding forms interfacial hydrogen bonds or covalent oxide bridges across the bonding interface.

13. The method of claim 1, wherein the chemical bonds formed across the bonding interface comprise covalent silicon-carbide (Si—C) bonds, silicon-oxide-carbon (Si—O—C) bonds, or metal-carbide bonds.

14. The method of claim 1, wherein the second substrate or the die comprises a material whose Coefficient of Thermal Expansion (CTE) mismatches a CTE of the first substrate, and wherein the graphene film acts as a compliant layer that yields to accommodate interfacial shear stress between the first substrate and the second substrate or the die.

15. The method of claim 1, wherein the graphene film comprises a non-horizontally oriented multilayer graphene morphology having graphene basal planes oriented at an angle relative to a horizontal plane of the first substrate surface.

16. The method of claim 1, wherein the multilayer graphene film functions as an atomic-scale strain-relief buffer layer that absorbs lateral thermomechanical shear stresses via internal interlayer sliding, thereby minimizing structural warpage of the bonded device stack during post-bonding thermal cycling.

17. The method of claim 1, wherein the first substrate, the second substrate, or the die comprises a material selected from the group consisting of: silicon, glass, sapphire, gallium arsenide (GaAs), indium phosphide (InP), silicon carbide (SiC), gallium nitride (GaN), aluminum nitride (AIN), quartz, organic packaging substrates, and polymers.

18. A bonded device stack, comprising:
a first substrate;
a second substrate or a die; and
at least a first graphene film disposed at an interface between the first substrate and the second substrate or the die, the first graphene film comprising engineered defects selected from at least one of vacancies, Stone-Wales defects, grain boundaries having a chosen grain size, nanopores having a chosen diameter and pitch, micropores, edge defects, and substitutional heteroatoms;
wherein the bonded device stack is secured via chemical bonds established directly or indirectly between the engineered defects and at least one of the first substrate and the second substrate or the die.

19. The bonded device stack of claim 18, wherein bonding the first substrate to the second substrate or the die comprises a low-temperature direct fusion bonding process performed at a process temperature between about 150 degrees Celsius and about 450 degrees Celsius.

20. The bonded device stack of claim 18, wherein the engineered defects comprise functional groups including at least one of hydroxyl (—OH), carboxyl (—COOH), and amine (—NH₂) groups, and wherein bonding forms interfacial hydrogen bonds or covalent oxide bridges across the bonding interface.

21. The bonded device stack of claim 18, wherein the chemical bonds formed across the bonding interface comprise covalent silicon-carbide (Si—C) bonds, silicon-oxide-carbon (Si—O—C) bonds, or metal-carbide bonds.

22. The bonded device stack of claim 18, wherein the second substrate or the die comprises a material whose Coefficient of Thermal Expansion (CTE) mismatches a CTE of the first substrate, and wherein the graphene film acts as a compliant layer that yields to accommodate interfacial shear stress between the first substrate and the second substrate or the die.

23. The bonded device stack of claim 18, further comprising a first material grown on the first graphene film prior to bonding, wherein the first material is interposed between the first graphene film and the second substrate or the die.

24. The bonded device stack of claim 18, further comprising a second graphene film comprising engineered defects, wherein the second graphene film is disposed on a surface of the second substrate or the die prior to bonding.

25. The bonded device stack of claim 24, wherein the bonding interface is a symmetric face-to-face configuration comprising at least one of:
(a) a direct bond between the first graphene film and the second graphene film; and
(b) a direct bond between a first material grown on the first graphene film and a second material grown on the second graphene film.

26. The bonded device stack of claim 24, wherein the bonding interface is an asymmetric configuration comprising a direct bond established between a surface of the first graphene film and an exposed surface of a material grown on the second graphene film.

27. The bonded device stack of claim 18, wherein the graphene film comprises a non-horizontally oriented multilayer graphene morphology having graphene basal planes oriented at an angle relative to a horizontal plane of the first substrate surface.

28. The bonded device stack of claim 27, wherein the angle of the non-horizontally oriented multilayer graphene morphology is selectively configured to form an anisotropic thermal dissipation path that preferentially conducts heat out-of-plane away from the die or the first substrate, mitigating localized hot spots within a heterogeneous, three-dimensionally stacked artificial intelligence (AI) chiplet architecture.

29. The bonded device stack of claim 18, wherein the multilayer graphene film functions as an atomic-scale strain-relief buffer layer that absorbs lateral thermomechanical shear stresses via internal interlayer sliding, thereby minimizing structural warpage of the bonded device stack during post-bonding thermal cycling.

30. The bonded device stack of claim 18, wherein the first substrate, the second substrate, or the die comprises a material selected from the group consisting of: silicon, glass, sapphire, gallium arsenide (GaAs), indium phosphide (InP), silicon carbide (SiC), gallium nitride (GaN), aluminum nitride (AlN), quartz, organic packaging substrates, and polymers.
